(19) United States
(12) Patent Application Publication
(10) Pub. No.: US 2025/0240923 A1
(43) Pub. Date: Jul. 24, 2025

(54) SYSTEMS AND METHODS FOR SAFE TWO-PHASE COOLING

(71) Applicant: INNOVATOR ENERGY LLC, Houston, TX (US)

(72) Inventor: Ethan Novek, Houston, TX (US)

(21) Appl. No.: 19/035,502

(22) Filed: Jan. 23, 2025

Related U.S. Application Data
(60) Provisional application No. 63/623,963, filed on Jan. 23, 2024.
(60) Provisional application No. 63/667,897, filed on Jul. 5, 2024.

(51) Int. Cl. H05K 7/20

(52) U.S. Cl. CPC H05K 7/20327

(57) ABSTRACT

The present application pertains to, for example, processes for installing a two phase fluid into a heat transfer loop. The processes may comprise adding an at least partially insoluble fluid into the heat transfer loop to displace at least a portion of a gas from the heat transfer loop. A two phase fluid is then added into the heat transfer loop to displace at least a portion of the partially insoluble fluid from the heat transfer loop. At least a portion of the displaced at least partially insoluble fluid is separated from the two phase fluid. The at least partially insoluble fluid is at least partially insoluble in the two phase fluid.

### CROSS-REFERENCE TO RELATED APPLICATIONS

This application claims priority to U.S. Ser. No. 63/623,963 filed Jan. 23, 2024 and U.S. Ser. No. 63/667,897 filed on Jul. 5, 2024, each of which is incorporated herein by reference.

### BACKGROUND AND SUMMARY

Two-phase (gas-liquid) phase transition heat transfer fluids may provide greater heat transfer density, heat transfer capacity, and thermal conductivity compared to single phase heat transfer fluids in heat transfer applications. For example, in cooling of high-power density electronics, such as some computer chips, higher heat transfer density, heat transfer capacity, and thermal conductivity may be desirable. For example, higher heat transfer density or heat transfer capacity may enable the operation of higher power density chips or enable the operation of chips at higher power or performance. For example, higher heat transfer density or heat transfer capacity may enable the use of smaller diameter piping and/or smaller volume heat exchangers, which may enable higher density computing, or lower capital costs, or smaller server or data center footprints, or any combination thereof. For example, higher thermal conductivity may enable computer chips to operate at higher power densities, or higher performance, or any combination thereof while enabling the chips to be cooled to design temperatures or case temperatures. For example, greater heat transfer density, heat transfer capacity, and thermal conductivity may enable the use of higher temperature heat sinks or cooling sources while providing or supporting the same chip or case temperatures, which may enable lower PUE, or lower cooling energy consumption, or greater energy efficiency, or more free cooling hours, or less evaporative cooling, or less water consumption, or less hours of mechanical refrigeration, or any combination thereof.

The deployment or use of two-phase (gas-liquid) phase change heat transfer fluids in computer chip cooling in data centers, especially at the hyperscale, has been greatly inhibited by the environmental impact, or cost, or flammability, or any combination thereof properties of two phase (gas-liquid) heat transfer fluids. For example, non-flammable two-phase (gas-liquid) phase transition heat transfer fluids may comprise fluorocarbon fluids, such as PFAS, which are harmful to human health and the environment if/when incidentally released. For example, PFAS generally are known to cause long term human and environmental health damage, and generally have ultra-high global warming potential (such as greater than 5,000× the global warming potential of carbon dioxide). Prior art two phase (gas-liquid) phase transition heat transfer fluid cooling systems are prone to leakage and inherently release fluorocarbon two-phase fluid vapors, especially during installation, or maintenance, or deinstallation, or filling, or emptying, or draining, or any combination thereof. Release of fluorocarbon two-phase fluid vapors is not only harmful for human health and the environment, it is also expensive-lost fluid vapors must be replaced with makeup fluorocarbon two phase (gas-liquid) phase transfer fluid and fluorocarbon two phase (gas-liquid) phase transition fluids are generally expensive.

For example, alternative two-phase (gas-liquid) phase transition heat transfer fluids may be highly flammable or toxic. For example, alternative two-phase (gas-liquid) phase transition heat transfer fluids may comprise ‘natural’ refrigerants, such as pentane, butane, or hexane, or propane, or ammonia, or methyl formate, or sulfur dioxide. Some hydrocarbon refrigerants, such as pentane, butane, or hexane, or propane, or dimethyl ether, may be flammable in the presence of air or oxygen. Other hydrocarbon refrigerants, such as methyl formate, may be at least partially toxic and may be at least partially flammable in the presence of air or oxygen. Ammonia may be acutely toxic and ammonia may be flammable in the presence of air or oxygen. Sulfur dioxide may be acutely toxic and corrosive. Carbon dioxide may be employed, although may require very high pressures and/or may have less favorable phase transition characteristics in the temperature range of computer chip cooling and/or may be at risk of solidifying or deposition.

For two-phase (gas-liquid) cooling to be deployed and benefits to be fully realized, it is clear there is a significant need for systems and/or methods for two-phase (gas-liquid) cooling which at least partially avoid or prevent or eliminate potential leakage or release or vapor release during installation, or maintenance, or deinstallation, or filling, or emptying, or draining, or operation, or any combination thereof and/or at least partially inherently eliminate or greatly reduce the risk of fire or ignition. Some embodiments of the present invention may comprise systems and methods which may solve these needs.

### BRIEF DESCRIPTION OF THE DRAWINGS

FIG. 1A: A simplified figure embodiment of a heat transfer system with written labels.

FIG. 1B: A simplified figure embodiment of a heat transfer system with number labels.

FIG. 2A: A detailed figure embodiment of a heat transfer system with written labels which may show a system operating in a heat transfer mode.

FIG. 2B: A detailed figure embodiment of a heat transfer system with number labels which may show a system operating in a heat transfer mode.

FIG. 2C: A detailed figure embodiment of a heat transfer system with number labels which may show a system operating wherein a portion of gas is displaced by a portion of an at least partially insoluble fluid.

FIG. 2D: A detailed figure embodiment of a heat transfer system with number labels which may show a system operating wherein a portion of residual gas is removed from a fluid comprising an at least partially insoluble fluid.

FIG. 2E: A detailed figure embodiment of a heat transfer system with number labels which may show a system operating wherein a portion of a fluid comprising an at least partially insoluble fluid is displaced by a fluid comprising a two phase fluid.

FIG. 2F: A detailed figure embodiment of a heat transfer system with number labels which may show a system operating wherein a portion of a residual fluid comprising an at least partially insoluble fluid is removed or separated from a fluid comprising a two phase fluid.

FIG. 2G: A detailed figure embodiment of a heat transfer system with number labels which may show a system operating wherein a portion of a fluid comprising a two phase fluid is displaced by a fluid comprising a fluid comprising an at least partially insoluble fluid.

FIG. 2H: A detailed figure embodiment of a heat transfer system with number labels which may show a system operating wherein a portion of a residual fluid comprising a two phase fluid is removed or separated from a fluid comprising an at least partially insoluble fluid.

FIG. 2I: A detailed figure embodiment of a heat transfer system with number labels which may show a system operating wherein a portion of a fluid comprising an at least partially insoluble fluid is displaced by a fluid comprising a fluid comprising an inert gas.

FIG. 2J: detailed figure embodiment of a heat transfer system with number labels which may show a system operating wherein a portion of a residual fluid comprising an at least partially insoluble fluid is removed or separated from a fluid comprising an inert gas.

### DETAILED DESCRIPTION

Some embodiments of the present invention may pertain to systems and/or methods for installing, or deinstalling, or removing, or any combination thereof two phase fluids into or from heat transfer loops, or heat transfer systems or methods, or any combination thereof. Some embodiments of the present invention may pertain to systems and/or methods for ensuring safe or lower risk operation of a two phase fluid heat transfer systems or methods, or heat transfer loops.

Some embodiments may enable the installation or removal of a two phase fluid into or from a heat transfer loop while inherently avoiding or preventing at least a portion of any potential fluid losses, or vapor pollution, or fire risk, or electronics damage, or explosion risk, or hazard risk, or damage risk, or any combination thereof. Some embodiments may enable two phase fluid heat transfer loops to be safely installed, or operated, or maintained, or updated, or adjusted, or any combination thereof. For example, some embodiments may involve a multi-step process which may substantially prevent two phase fluid from being present or leaked into ambient air, or may prevent the contact or substantial presence of two phase fluid vapor with diatomic oxygen, or may substantially reduce or avoid or prevent the presence of two phase fluid vapor in a heat transfer loop when the heat transfer loop is in the presence of or being maintained by or modified by a human or robot, or may reduce risk of damage, or may reduce the risk of a hazard. For example, some embodiments may enable a heat transfer loop to change between being occupied by a two-phase fluid and being occupied by an inert gas, wherein minimal two phase fluid losses may occur during said change and/or minimal two phase fluid vapor may be present when inert gas may occupy the heat transfer loop and/or minimal inert gas may be present when two phase fluid may occupy the heat transfer loop. For example, some embodiments may enable a heat transfer loop to be occupied by an inert gas when desired, such as when being maintained or fixed or updated or modified by humans, and occupied by a two phase fluid when desired, such as when in the heat transfer loop may be in operation or may be actively cooling or heating. For example, some embodiments may enable a heat transfer loop to be occupied by an inert gas when desired, such as when being maintained or fixed or updated or modified or transported or viewed by humans, or in the presence of humans, or in the potential presence of potential hazards, and/or occupied by a two phase fluid when desired, such as when the heat transfer loop may be in operation or may be actively cooling or heating, and/or wherein some embodiments may enable the transition from inert gas to two phase fluid or two phase fluid to inert gas to be conducted with minimal fluid loss, or with minimal two phase fluid vapors in the inert gas when occupied by an inert gas, or with minimal inert gas present when occupied by two phase fluid, or any combination thereof.

Some embodiments may be enabled by or facilitated by the advent of at least partially automated or robot operated data centers. In some embodiments, for example, the presence of humans in data center spaces, or the presence of humans in rooms comprising servers or computers, or any combination thereof may be greatly reduced, or the frequency decreased, or any combination thereof. In some embodiments, for example, a portion of data center or computer rooms may be occupied by an inert gas, or a non-flammable gas, or any combination thereof, such as a gas comprising nitrogen, or carbon dioxide, or argon, or any combination thereof. In some embodiments, for example, a portion of data center or computer rooms may be occupied by an inert gas, or a non-flammable gas, or any combination thereof, such as a gas comprising nitrogen, or carbon dioxide, or argon, or any combination thereof, which may enable or facilitate the use of two phase fluids which may, for example, be flammable in some other environments, such as in environments comprising ambient air. In some embodiments, for example, robots may be the primary physical operators or maintainers of data centers, which may enable data center environments which may be less hospitable to humans, such as relatively low oxygen environments, or warmer temperature environments, or colder temperature environments, or ultra-low humidity environments, or any combination thereof. In some embodiments, for example, a lower oxygen environment may comprise an environment with a concentration of diatomic oxygen less than the concentration of oxygen in ambient outdoor air, or a sufficiently low concentration of oxygen to prevent ignition or combustion of a fuel, or any combination thereof. In some embodiments, for example, a lower oxygen environment may enable the use of heat transfer fluids, or refrigerants, or two phase fluids, or other fluids, or other materials, or any combination thereof which may be combustible in environments comprising greater diatomic oxygen concentrations or environments comprising the diatomic oxygen concentration of ambient outdoor air. In some embodiments, for example, a lower oxygen environment may enable the use of heat transfer fluids, or refrigerants, or two phase fluids, or other fluids, or other materials, or any combination thereof which may be potentially hazardous in the presence of humans, such as ammonia or sulfur dioxide. In some embodiments, for example, a lower oxygen environment may enable the use of heat transfer fluids, or refrigerants, or two phase fluids, or other fluids, or other materials, or any combination thereof which may be low cost, or environmentally benign, or abundant, or high efficiency, or low global warming potential (GWP), or biodegradable, or not forever chemicals, or any combination thereof. In some embodiments, for example, a space occupied by a gas comprising a low oxygen environment may enable other potential benefits, such as reduced corrosion, or greater longevity, or reduced biofouling, or any combination thereof. In some embodiments, for example, when or if it may be desirable for humans to enter or be present in a low oxygen environment or inert gas environment, it may be desirable for humans to wear devices which may enable safe access, such as breathing apparatuses, or enclosed breathing apparatuses, or suitable clothing, or suitable suits, or any combination thereof. In some embodiments, it may be desirable for a space or environment to be capable of transitioning from a low oxygen environment to an environment suitable for humans, while, for example, enabling the safety and/or health and/or security of potential human occupants. In some embodiments, it may be desirable for a space or environment to be capable of transitioning from a low oxygen environment to an environment comprising a higher oxygen environment, or an environment comprising oxygen, or an environment comprising air, or any combination thereof.

In some embodiments, may be desired for the servers, or racks, or computers, or systems or cooling systems, or heat transfer systems, or heat exchangers, or any combination thereof to be occupied by air, or inert gas, or liquid, or a non-hazardous fluid, or an at partially insoluble fluid, or any combination thereof during, for example, including, but not limited to, one or more or any combination of the following: manufacturing, or assembly, or transport, or installation, or pressure testing, or startup, or maintenance, or deinstallation, or mobilization, or modification, or adjustment, or inspection, or any combination thereof. Some embodiments may enable the, for example, manufacturing, or assembly, or transport, or installation, or pressure testing, or startup, or maintenance, or deinstallation, or mobilization, or modification, or adjustment, or inspection, or any combination thereof, while minimizing or reducing the potential risks which may be associated with potentially flammable or hazardous fluids.

For example, in some embodiments, a heat transfer loop may be occupied by a gas, such as an inert gas or air, and/or an at least partially insoluble fluid at least partially comprising a liquid phase may be transferred into the heat transfer loop to displace at least a portion of the gas from the heat transfer loop, and/or at least a portion of the at least partially insoluble fluid may be pumped, or transferred, or circulated into or within or out of the heat transfer loop to remove at least a portion of any residual gas, and/or separating at least a portion of any residual gas from the at least partially insoluble fluid using a gas-liquid separation, such as an automatic air remover or automatic gas remover or a decanter, and/or transferring at least a portion of a two phase fluid into the heat transfer loop to displace at least a portion of the at least partially insoluble fluid from the heat transfer loop, and/or at least a portion of the two phase fluid may be pumped, or transferred, or circulated into or within or out of the heat transfer loop to remove at least a portion of any residual at least partially insoluble fluid, and/or separating at least a portion of any residual gas from the at least partially insoluble fluid using a fluid-fluid separation, or a density based separation, or a liquid-liquid separation, or a liquid-gas separation, or any combination thereof, such as a decanter or coalescer.

For example, some embodiments may greatly reduce the risk of or inherently prevent or inherently minimize, for example, including, but not limited to, one or more or any combination of the following: fire hazards, or diatomic oxygen exposure, or substantial vapor formation or vapor mixing with a gas, or two phase fluid losses, or two phase fluid leaks. For example, some embodiments may enable effective installation or removal or deinstallation of two phase fluid and/or enable effective installation or removal or deinstallation of two phase fluid which may, for example, prevent undesired exposure to two phase fluid, or may prevent the presence of a fluid when the fluid's presence may not be desired, or any combination thereof.
For example, in some embodiments, two phase fluid may be displaced by an at least partially insoluble fluid, or an at least partially insoluble fluid may be displaced by a two phase fluid. For example, in some embodiments, a two phase fluid may be displaced by an at least partially insoluble fluid, wherein the two phase fluid may be at a liquid phase and/or the at least partially insoluble fluid may be at a liquid phase. For example, in some embodiments, an at least partially insoluble fluid may be displaced by a two phase fluid, wherein the two phase fluid may be at a liquid phase and/or the at least partially insoluble fluid may be at a liquid phase. For example, displacing two phase fluid with an at least partially insoluble fluid at a liquid phase may prevent two phase fluid vapor formation and/or may prevent the mixing of a two phase fluid with a gas. For example, displacing an at least partially insoluble fluid with an two phase fluid may prevent two phase fluid vapor formation and/or may prevent the mixing of a two phase fluid with a gas. For example, displacing two phase fluid with an at least partially insoluble fluid, displacing two phase fluid with an at least partially insoluble fluid at a liquid phase, or displacing an at least partially insoluble fluid with a two phase fluid, or any combination thereof may prevent the formation of a vapor-gas mixture during the installation or deinstallation of two phase fluid, whereby potentially avoiding or preventing or greatly reducing the need for a separation of two phase fluid vapor from a gas and/or whereby potentially eliminating or greatly reducing a fire risk and/or whereby potentially eliminating or greatly reducing a potential source of two phase fluid losses. For example, displacing two phase fluid with an at least partially insoluble fluid and/or flushing or circulating an at least partially insoluble fluid and/or separating at least a portion of two phase fluid from at least a portion of at least partially insoluble fluid with a liquid-liquid separation or gas-liquid separation or fluid-fluid separation, may enable two phase fluid to be removed from a heat transfer loop while, for example, maintaining two phase fluid at least partially at a liquid phase and/or may prevent two phase fluid vapor formation and/or may prevent two phase fluid vapor from mixing with a gas and/or may prevent two phase fluid losses. For example, displacing at least partially insoluble fluid with two phase fluid and/or flushing or circulating the two phase fluid and/or separating at least a portion of at least partially insoluble fluid from at least a portion of two phase fluid with a liquid-liquid separation or gas-liquid separation or fluid-fluid separation, may enable at least partially insoluble fluid to be removed from a heat transfer loop while, for example, maintaining two phase fluid at least partially at a liquid phase and/or may prevent two phase fluid vapor formation and/or may prevent two phase fluid vapor from mixing with a gas and/or may prevent two phase fluid losses. In some embodiments, it may be desirable for the at least partially insoluble fluid to be practically insoluble in the two phase fluid and/or it may be desirable for the two phase fluid to be practically insoluble in the at least partially insoluble fluid to, for example, facilitate or enable liquid-liquid separation or fluid-fluid separation, if desired. In some embodiments, it may be desirable for the two phase fluid liquid phase to comprise a substantially different density than the at least partially insoluble fluid liquid phase to, for example, facilitate or enable liquid-liquid separation, if desired.
For example, in some embodiments, an at least partially insoluble fluid may be displaced with a gas. For example, in some embodiments, a gas may be displaced with an at least partially insoluble fluid. For example, in some embodiments, an at least partially insoluble fluid may be displaced from a heat transfer loop with a gas. For example, in some embodiments, a gas may be displaced from a heat transfer loop with an at least partially insoluble fluid. For example, in some embodiments, displacing an at least partially insoluble fluid with a gas, or displacing a gas with an at least partially insoluble fluid, or any combination thereof may prevent, for example, including, but not limited to, one or more or any combination of the following: two phase fluid vapor losses, or two phase fluid vapor formation, or two phase fluid mixing with a gas, or substantial two phase fluid vapor-gas separation, or potential fire risk, or potential undesired exposure to residual two phase fluid, or any combination thereof. For example, in some embodiments, displacing an at least partially insoluble fluid with a gas, instead of, for example, displacing two phase fluid with a gas may prevent, for example, including, but not limited to, one or more or any combination of the following: two phase fluid vapor losses, or two phase fluid vapor formation, or two phase fluid mixing with a gas, or substantial two phase fluid vapor-gas separation, or potential fire risk, or potential undesired exposure to residual two phase fluid, or any combination thereof. For example, in some embodiments, displacing a gas with an at least partially insoluble fliod, instead of, for example, displacing a gas with a two phase fluid may prevent, for example, including, but not limited to, one or more or any combination of the following: two phase fluid vapor losses, or two phase fluid vapor formation, or two phase fluid mixing with a gas, or substantial two phase fluid vapor-gas separation, or potential fire risk, or potential undesired exposure to residual two phase fluid, or any combination thereof.
For example, in some embodiments, an at least partially insoluble fluid may comprise water. For example, in some embodiments, displacing or purging water with a gas, or displacing or flushing a gas with water, or any combination thereof may have minimal economic cost or environmental impact or safety hazard risk. For example, in some embodiments, displacing or purging water with a gas, or displacing or flushing a gas with water, or any combination thereof may have minimal economic cost or environmental impact or safety hazard risk due to, for example, including, but not limited to, one or more or any combination of the following: low cost of water, or the low environmental impact of water vapor, or the simplicity or relatively low cost of recovering or removing water vapor, or the ability to exhaust or vent water vapor, or the potentially low vapor pressure of water relative to a two phase fluid, or the non-flammability of water, or the practical insolubility of some inert gases in water. In some embodiments, to further reduce risk or potential hazards, it may be desirable for at least a portion of the ‘gas’ employed to comprise an inert gas. In some embodiments, for example, it may be desirable for the heat transfer loop to be occupied by a gas or an inert gas during, for example, modifications, or maintenance, or adjustments, or monitoring, or any combination thereof. In some embodiments, it may be desirable for at least a portion of the gas or inert gas to comprise, including, but not limited to, one or more or any combination of the following properties: non-oxidizing, or non-flammable, or electrically safe, or dielectric, or low cost, or low greenhouse gas potential, or low global warming potential, or no global warming potential, or an air gas, or environmentally safe, or environmentally friendly, or practically insoluble in the at least partially insoluble fluid comprising a liquid phase, or abundant, or non-toxic, or low toxicity, or detectability.

For example, in some embodiments, two phase fluid may be installed, or deinstalled, or removed, or any combination thereof from a heat transfer loop such that, including, but not limited to, one or more or any combination of the following: presence of potentially incompatible fluids may be avoided, or minimal two phase fluid vapor formation in the inert gas may be occur during installation or removal of two phase fluid, or two phase fluid vapor may be separated or removed or recovered or any combination thereof, or two phase fluid vapor or two phase fluid may not be present or may be minimally present or may be present at a concentration below a desired threshold or any combination thereof in the heat transfer loop when the heat transfer loop may be occupied by an inert gas or when the heat transfer loop may be maintained or operated on by a human or any combination thereof, or two phase fluid may be recoverable or separable.

For example, in some embodiments, a heat transfer loop may be occupied by an inert gas, and/or two phase fluid may be transferred into a heat transfer loop such that the two phase fluid comprises a liquid phase and inert gas comprises a gas phase, and/or transferring or pumping two phase fluid into or in the heat transfer loop wherein at least a portion of the inert gas may be displaced from the heat transfer loop by the two phase fluid, and/or at least a portion of any two phase fluid vapor which may be present in the displaced inert gas may be separated or recovered or removed or any combination thereof from the inert gas. For example, in some embodiments, a heat transfer loop may be occupied by a two-phase fluid, and/or inert gas may be transferred into a heat transfer loop such that at least a portion of two-phase fluid may comprise a liquid phase and at least a portion of inert gas comprises a gas phase, and/or displacing at least a portion of the two phase fluid comprising a liquid from the heat transfer loop with the inert gas, and/or at least a portion of any residual two phase fluid vapor which may be present in the inert gas in the heat transfer loop may be separated or recovered or removed or any combination thereof from the inert gas.

INSTALLING TWO-PHASE FLUID EMPLOYING AT LEAST PARTIALLY INSOLUBLE FLUID: In some embodiments, for example, systems and/or methods for installing two phase fluid may comprise, including, but not limited to, one or more or any combination of the following:

(1) Displacing and/or Flushing at Least a Portion of a Gas from a Heat Transfer Loop using an At Least Partially Insoluble Fluid: In some embodiments, for example, an at least partially insoluble fluid may be transferred into the heat transfer loop which may be at least partially occupied by or comprise a gas, such as an inert gas or air, and/or wherein at least a portion of said at least partially insoluble fluid may displace at least a portion of the gas, or may mix with at least a portion of the gas to form an gas-liquid mixture, or mix with at least a portion of the gas to form an gas-vapor mixture, or any combination thereof and/or may displace or otherwise transfer at least a portion of said gas from the heat transfer loop. For example, in some embodiments, it may be desirable for gas to comprise a gas and the at least partially insoluble fluid to comprise a liquid. In some embodiments, for example, it may be desirable for the gas to comprise a gas and the at least partially insoluble fluid to comprise a liquid, wherein a portion of said at least partially insoluble fluid may evaporate or form a vapor, for example, in the presence of the gas. In some embodiments, an at least partially insoluble fluid may be transferred into a heat transfer loop, displacing at least a portion of the gas from the heat transfer loop. In some embodiments, for example, at least partially insoluble fluid may be transferred into the heat transfer loop to displace or flush out at least a portion of any residual gas from the heat transfer loop. For example, in some embodiments, at least partially insoluble fluid, which may possess a relatively low proportion of entrenched or suspended or carried gas (for example: ‘gas lean’ at least partially insoluble fluid), may be transferred into the heat transfer loop, wherein at least a portion of gas may be removed by the at least partially insoluble fluid as, for example, a liquid-gas mixture, or a gas-liquid mixture, or gas-rich at least partially insoluble fluid, or displaced gas, or any combination thereof, and/or at least a portion of the gas may be separated, or exhausted, or released, or discharged, or vented. For example, in some embodiments, gas present in the at least partially insoluble fluid may be separated or removed by, including, but not limited to, one or more or any combination of the following: an automatic gas remover, or an automatic air remover, or a gas-liquid separator, or an air separator, or a gas remover, or any combination thereof. In some embodiments, for example, gas displaced, or removed, or flushed, or separated, or any combination thereof may be: separated, or dried, or may be regenerated into ‘dry’ inert gas, or may be regenerated into ‘dry’ gas, or a portion of any at least partially insoluble fluid vapor or aerosol may be removed, or a portion of any at least partially insoluble fluid vapor or aerosol may be separated, or a portion of any at least partially insoluble fluid vapor or aerosol may be recovered, or at least a portion of any at least partially insoluble fluid or at least a portion of any two phase fluid vapor or aerosol may be removed or separated or recovered, or recirculated, or transferred into the heat transfer loop, or compressed, or transferred into inert gas storage, or vented, or exhausted. In some embodiments, the volume or mass of an at least partially insoluble fluid transferred into a heat transfer loop may be measured or monitored. In some embodiments, the transfer and/or circulation of the at least partially insoluble fluid into or in the heat transfer loop may continue until, for example, at least 80%, or 85%, or 90%, or 95%, or 99%, or 99.5%, or 99.9%, or any combination thereof of the anticipated or expected volume or mass of at least partially insoluble fluid has entered the heat transfer loop or occupies the heat transfer loop, and/or a volume or mass of at least partially insoluble fluid comprising greater than or equal to, for example, at least 80%, or 85%, or 90%, or 95%, or 99%, or 99.5%, or 99.9%, or any combination thereof the available volume in the heat transfer loop, or internal volume of the heat transfer loop, or any combination thereof. In some embodiments, the volume or mass of the gas in the heat transfer loop, or displaced, or flushed out, or removed, or separated, or any combination thereof from the heat transfer loop may be measured or monitored. For example, in some embodiments, it may be desirable to transfer or circulate the at least partially insoluble fluid into or in the heat transfer loop until, for example, at least 80%, or 85%, or 90%, or 95%, or 99%, or 99.5%, or 99.9%, or any combination thereof of the gas, or the anticipated or expected volume of gas, or any combination thereof may be transferred, or recovered, or removed, or any combination thereof from the heat transfer loop. For example, in some embodiments, the volume or mass of the at least partially insoluble fluid which may have been transferred into the heat transfer loop may be measured or monitored by, including, but not limited to, one or more or any combination of the following: the volumetric level or liquid level of the at least partially insoluble fluid in storage or separation, or the volumetric level or liquid level of the liquid-liquid interface between two phase fluid and at least partially insoluble fluid in storage or in a separator, or fluid density, or total mass of fluid in storage, or total mass change of fluid in storage or system before or during or after or any combination thereof of transfer of at least a portion of inert gas into the heat transfer loop, or mass flow meter, or volumetric flow meter, or any combination thereof. In some embodiments, at least a portion of the at least partially insoluble fluid may be separated, or transferred, or recovered, or removed, or any combination thereof by fluid displacement. In some embodiments, it may be desirable to pause transferring or circulating the at least partially insoluble fluid into or in the heat transfer loop when, for example, the volumetric proportion of gas in the at least partially insoluble fluid in or exiting the heat transfer loop is less than or equal to, for example, one or more or any combination of the following: 10%, or 5%, or 2%, or 1%, or 0.5%, or 0.1%, or 0.05%, or 0.01%, or 0.005%, or 0.001%. In some embodiments, it may be desirable to measure or monitor the volume or mass of gas displaced or transferred from the heat transfer loop or system. In some embodiments, it may be desirable to pause transferring or circulating the at least partially insoluble fluid into or in the heat transfer loop when, for example, the volume or mass of gas displaced or transferred from the heat transfer loop or system is greater than or equal to, for example, at least 80%, or 85%, or 90%, or 95%, or 99%, or 99.5%, or 99.9%, or any combination thereof the volume in the heat transfer loop.

(2) Displacing and/or Flushing at Least a Portion of the At Least Partially Insoluble Fluid from a Heat Transfer Loop using a Two-Phase Fluid: In some embodiments, for example, at least a portion of a two phase fluid may be transferred or pumped into a heat transfer loop which may be at least partially occupied by or comprise an at least partially insoluble fluid, and/or wherein at least a portion of said two phase fluid displaces at least a portion of the at least partially insoluble fluid, or mixes with at least a portion of the at least partially insoluble fluid to form a liquid-liquid mixture, or any combination thereof and/or may displace or otherwise transfer at least a portion of said at least partially insoluble fluid from the heat transfer loop. For example, in some embodiments, the displaced at least partially insoluble fluid, or the mixture of the at least partially insoluble fluid and the two phase fluid, or any combination thereof may be at least partially separated or at least partially further separated, before or simultaneous to, storing at least a portion of the at least partially insoluble fluid, or transferring at least a portion of the two phase fluid into the heat transfer loop, or circulating or recirculating the two phase fluid, or storing the two phase fluid, or any combination thereof. For example, in some embodiments, if the two-phase fluid comprises a hydrocarbon, or a fluorocarbon, or non-polar liquid, or non-polar fluid, or other fluid which may be at least partially insoluble in water, or any combination thereof, then the ‘at least partially insoluble fluid’ may comprise water, or treated water, or deoxygenated water, or decarbonated water, or deionized water, or any combination thereof. For example, in some embodiments, if the two-phase fluid comprises n-Pentane, then the ‘at least partially insoluble fluid’ may comprise water, or treated water, or deoxygenated water, or decarbonated water, or deionized water, or any combination thereof. For example, in some embodiments, if the two-phase fluid comprises a polar fluid, such as ammonia, or sulfur dioxide, or methanol, then the ‘at least partially insoluble fluid’ may comprise an oil or a non-polar fluid. For example, in some embodiments, it may be desirable for the at least partially insoluble fluid to be at least partially deoxygenated, or to comprise an oxygen scavenger, or any combination thereof to, for example, minimize or reduce the potential presence of oxygen in the presence of the two phase fluid, which may be desirable, for example, if the two phase fluid may be potentially flammable or oxidizable in the presence of oxygen. For example, in some embodiments, it may be desirable for the at least partially insoluble fluid to comprise a liquid to, for example, prevent or reduce the potential residual at least partially insoluble fluid and/or prevent or reduce the potential presence of two phase fluid vapor in the at least partially insoluble fluid. For example, in some embodiments, the two phase fluid may displace at least a portion of the at least partially insoluble fluid. In some embodiments, for example, it may be desirable for the two phase fluid to be at a liquid state during displacing or transferring of the at least partially insoluble fluid. In some embodiments, for example, it may be desirable for the two-phase fluid to be at a gaseous state during displacing or transferring of the at least partially insoluble fluid. In some embodiments, for example, it may be desirable for the two-phase fluid to be at a gas-liquid mixture state during displacing or transferring of the at least partially insoluble fluid. In some embodiments, for example, it may be desirable for the two-phase fluid to be at a supercritical state during displacing or transferring of the at least partially insoluble fluid. In some embodiments, for example, it may be desirable to circulate or actively pump at least a portion of the two-phase fluid through at least a portion of the heat transfer loop. For example, in some embodiments, the two phase fluid may be pumped or otherwise transferred through the heat transfer loop, which may form a fluid comprising a mixture of the at least partially insoluble liquid and the two phase fluid, and/or then transferring at least a portion of said mixture into a storage container and/or a liquid-liquid separator or fluid-fluid separator. For example, in some embodiments, said liquid-liquid separator or fluid-fluid separator may comprise a decanter, or coalescer, or centrifuge, or a density based separation method, or any combination thereof. For example, in some embodiments, said liquid-liquid separator or fluid-fluid separator may comprise a storage tank wherein the two phase fluid and the at least partially insoluble fluid may self-separate or may separate while in storage, due to, for example, the difference in density between the two phase fluid and the at least partially insoluble fluid. For example, in some embodiments, at least a portion of a mixture comprising the at least partially insoluble fluid and the two phase fluid may be at least partially separated into a first fluid comprising the two phase fluid and a second fluid comprising the at least partially insoluble fluid. In some embodiments, for example, a fluid storage tank may comprise two liquid layers, a first layer comprising two phase fluid and a second layer comprising at least partially insoluble liquid. In some embodiments, for example, a fluid storage tank may comprise two liquid layers, a first layer comprising two phase fluid and a second layer comprising at least partially insoluble liquid, wherein, for example, if a mixture comprising two phase fluid and at least partially insoluble liquid may be transferred into the fluid storage tank, the two phase fluid and at least partially insoluble liquid may at least partially separate over time into their respective layers, such as, for example, a portion of two phase fluid may separate or migrate into the first layer comprising two phase fluid and/or a portion of the at least partially insoluble fluid may separate or migrate into the second layer comprising at least partially insoluble fluid. In some embodiments, for example, fluid ports may be present in the first layer and/or the second layer, which may enable selective transfer of a portion of two phase fluid and/or selective transfer of a portion of at least partially insoluble fluid. In some embodiments, at least a portion of said first fluid may be transported or transferred or pumped to storage and/or at least a portion of said second fluid may be transported or transferred or pumped to storage. In some embodiments, at least a portion of said first fluid may be transferred into or circulated within the heat transfer loop and/or may comprise at least a portion of the two phase fluid which may be transferred into the heat transfer loop. In some embodiments, displacement, or mixing, or turbulent flow, or high shear flow, or any combination thereof may be employed and/or may enable the removal or recovery of at least a portion of the at least partially insoluble fluid from a heat transfer loop, while, for example, reducing or minimizing the potential for two-phase fluid losses, and/or reducing or avoiding the formation of two phase fluid vapors in the heat transfer loop during the removal of at least a portion of the at least partially insoluble fluid. In some embodiments, it may be desirable for the two phase fluid to be at a liquid phase during transfer or circulation in the heat transfer loop, and/or it may be desirable for the two phase fluid to be at a liquid phase during the displacement and/or removal of the at least partially insoluble fluid form the heat transfer loop. In some embodiments, it may be desirable to transfer or circulate the two phase fluid in the heat transfer loop until, for example, at least 80%, or 85%, or 90%, or 95%, or 99%, or 99.5%, or 99.9%, or any combination thereof of at least partially insoluble fluid may be transferred, or recovered, or removed from the heat transfer loop. In some embodiments, the mass or volume of the at least partially insoluble fluid transferred from or exiting the heat transfer loop may be measured or monitored or weighed, to, for example, determine if sufficient at least partially insoluble fluid has been recovered or removed or otherwise transferred from the heat transfer loop. In some embodiments, it may be desirable to pause transferring or circulating the at least partially insoluble fluid into or in the heat transfer loop when, for example, a significant portion or at least 50%, or 75%, or 80%, or 85%, or 90%, or 91%, or 92%, or 93%, or 94%, or 95%, or 96%, or 97%, or 98%, or 99%, or any combination thereof of the at least partially insoluble fluid mass or volume originally transferred into the heat transfer loop may be removed or displaced from the heat transfer loop. For example, in some embodiments, the volume or mass of the at least partially insoluble fluid which may have exited the heat transfer loop may be measured or monitored by, including, but not limited to, one or more or any combination of the following: the volumetric level or liquid level of two phase fluid in storage or separation, or the volumetric level or liquid level of the liquid-liquid interface between two phase fluid and at least partially insoluble fluid in storage or in a separator, or fluid density, or total mass of fluid in storage, or total mass change of fluid in storage or system before or during or after or any combination thereof of transfer of at least a portion of the two phase fluid into the heat transfer loop, or mass flow meter, or volumetric flow meter, or any combination thereof. In some embodiments, at least a portion of the at least partially insoluble fluid may be separated, or transferred, or recovered, or removed by fluid displacement. In some embodiments, it may be desirable for at least a portion of the at least partially insoluble fluid to be transferred, or recovered, or removed by fluid displacement, and/or flushing or circulating. In some embodiments, it may be desirable to subsequently, or concurrently, or simultaneously, or any combination thereof separate a fluid-fluid mixture or liquid-liquid mixture comprising a two phase fluid and the at least partially insoluble fluid. In some embodiments, for example, it may be desirable for the two phase fluid to be transferred into or enter into the heat transfer loop from a higher elevation and/or exit the heat transfer loop at a lower elevation, if, for example, the at least partially insoluble fluid possesses a greater density than the two-phase fluid, for example, to facilitate or enable fluid displacement, and/or to reduce the need for or the proportion of the two phase fluid removed due to flushing and/or to reduce the potential separation demands of fluid-fluid or liquid-liquid separation processes. In some embodiments, for example, it may be desirable for the two phase fluid to be transferred into or enter into the heat transfer loop from a lower elevation and/or exit the heat transfer loop at a higher elevation, if, for example, the at least partially insoluble fluid possesses a lesser density than the two-phase fluid, for example, to facilitate or enable fluid displacement, and/or to reduce the need for or the proportion of the two phase fluid removed due to flushing and/or to reduce the potential separation demands of fluid-fluid or liquid-liquid separation processes.

In some embodiments, a heat transfer system comprising a two-phase fluid may benefit from or require the removal of at least a portion of two-phase fluid. For example, in some embodiments, a system comprising a two-phase fluid may require, including, but not limited to, one or more or any combination of the following: maintenance, or hardware replacement, or hardware update, or equipment replacement, or equipment update, or fixing, or may require fixing of a leak, or a system update, or a system fix, or a system inspection, or any combination thereof. It may be desirable for the removal of at least a portion of two-phase fluid to comprise a system and/or method which may, for example, including, but not limited to, one or more or any combination of the following: avoid or minimize residual vapor, or maximizes recovery of two-phase fluid, or prevents leakage of two-phase fluid, or prevents mixing of two phase fluid with air, or prevents mixing of two-phase fluid with oxygen, or prevents losses of two phase fluid, or any combination thereof.

REMOVING OR DEINSTALLING TWO-PHASE FLUID EMPLOYING AT LEAST PARTIALLY INSOLUBLE FLUID: In some embodiments, for example, systems and/or methods for removing or recovering two phase fluid may comprise, including, but not limited to, one or more or any combination of the following:

(1) Displacing and/or Flushing the Two-Phase Fluid from a Heat Transfer Loop using an At Least Partially Insoluble Fluid: In some embodiments, for example, an at least partially insoluble fluid may be transferred or pumped into a heat transfer loop which may be at least partially occupied by or comprise a two phase fluid, and/or wherein at least a portion of said at least partially insoluble fluid displaces at least a portion of the two-phase fluid, or mixes with at least a portion of the two-phase fluid to form a liquid-liquid mixture, or any combination thereof and/or may displace or otherwise transfer at least a portion of said two phase fluid from the heat transfer loop. For example, in some embodiments, the displaced two phase fluid, or the mixture of the at least partially insoluble fluid and the two phase fluid, or any combination thereof may be at least partially separated or at least partially further separated, before or simultaneous to, storing at least a portion of the two phase fluid, or transferring at least a portion of the at least partially insoluble fluid into the heat transfer loop, or circulating or recirculating the at least partially insoluble fluid, or storing the at least partially insoluble fluid, or any combination thereof. For example, in some embodiments, if the two-phase fluid comprises a hydrocarbon or a fluorocarbon or other fluid which may be at least partially insoluble in water, then the ‘at least partially insoluble fluid’ may comprise water, or treated water, or deoxygenated water, or decarbonated water, or deionized water, or any combination thereof. For example, in some embodiments, it may be desirable for the at least partially insoluble fluid to be at least partially deoxygenated, or to comprise an oxygen scavenger, or any combination thereof to, for example, minimize or reduce the potential presence of oxygen in the presence of the two phase fluid, which may be desirable, for example, if the two phase fluid may be potentially flammable or oxidizable in the presence of oxygen. For example, in some embodiments, it may be desirable for the at least partially insoluble fluid to comprise a liquid to, for example, prevent or reduce the potential residual vapor phase of the two phase fluid and/or prevent or reduce the potential formation of two phase fluid vapor during or after removal, or recovery, or separation, or any combination thereof. For example, in some embodiments, the at least partially insoluble fluid may displace at least a portion of the two phase fluid. For example, in some embodiments, it may be desirable to circulate or actively pump at least a portion of the at least partially insoluble fluid through at least a portion of the heat transfer loop. For example, in some embodiments, the at least partially insoluble fluid may be pumped or otherwise transferred through the heat transfer loop, forming a fluid comprising a mixture of the at least partially insoluble liquid and the two phase fluid, then transferring at least a portion of said mixture into a storage container and/or a liquid-liquid separator or fluid-fluid separator. For example, in some embodiments, said liquid-liquid separator or fluid-fluid separator may comprise a decanter, or coalescer, or centrifuge, or any combination thereof. For example, in some embodiments, at least a portion of said mixture comprising the at least partially insoluble fluid and the two phase fluid may be at least partially separated into a first fluid comprising the at least partially insoluble fluid and a second fluid comprising the two phase fluid. In some embodiments, at least a portion of said first fluid may be transported or transferred or pumped to storage and/or at least a portion of said second fluid may be transported or transferred or pumped to storage. In some embodiments, at least a portion of said first fluid may be transferred into or circulated within the heat transfer loop and/or may comprise at least a portion of the at least partially insoluble fluid which may be transferred into the heat transfer loop. In some embodiments, displacement, or mixing, or turbulent flow, or high shear flow, or any combination thereof may be employed and/or may enable the removal or recovery of at least a portion of the two phase fluid from a heat transfer loop, while, for example, reducing or minimizing the potential for two-phase fluid losses, or reducing or avoiding the formation of two phase fluid vapors in the heat transfer loop during or after the removal of at least a portion of two phase fluid. In some embodiments, it may be desirable to transfer or circulate the at least partially insoluble fluid in the heat transfer loop until, for example, at least 80%, or 85%, or 90%, or 95%, or 99%, or 99.5%, or 99.9%, or any combination thereof of two-phase fluid may be transferred, or recovered, or removed from the heat transfer loop. In some embodiments, the mass or volume of two phase fluid transferred from or exiting the heat transfer loop may be measured or monitored or weighed, to, for example, determine if sufficient two phase fluid has been recovered or removed or otherwise transferred from the heat transfer loop. In some embodiments, it may be desirable to pause transferring or circulating the at least partially insoluble fluid into or in the heat transfer loop when, for example, a significant portion or at least 50%, or 75%, or 80%, or 85%, or 90%, or 91%, or 92%, or 93%, or 94%, or 95%, or 96%, or 97%, or 98%, or 99%, or any combination thereof of the two phase fluid mass or volume originally transferred into the heat transfer loop may be removed or displaced from the heat transfer loop. For example, in some embodiments, the volume or mass of two phase fluid which may have exited the heat transfer loop may be measured or monitored by, including, but not limited to, one or more or any combination of the following: the volumetric level or liquid level of two phase fluid in storage or separation, or the volumetric level or liquid level of the liquid-liquid interface between two phase fluid and at least partially insoluble fluid in storage or in a separator, or fluid density, or total mass of fluid in storage, or total mass change of fluid in storage or system before or during or after or any combination thereof of transfer of at least a portion of at least partially insoluble fluid into the heat transfer loop, or mass flow meter, or volumetric flow meter, or any combination thereof. In some embodiments, at least a portion of the two-phase fluid may be separated, or transferred, or recovered, or removed by fluid displacement. In some embodiments, it may be desirable for at least a portion of the two-phase fluid to be transferred, or recovered, or removed by fluid displacement, and/or flushing or circulating. In some embodiments, it may be desirable to subsequently, or concurrently, or simultaneously, or any combination thereof separate a fluid-fluid mixture or liquid-liquid mixture comprising a two phase fluid and the at least partially insoluble fluid. In some embodiments, for example, it may be desirable for the at least partially insoluble fluid to be transferred into or enter into the heat transfer loop from a lower elevation and/or exit the heat transfer loop at a higher elevation, if, for example, the at least partially insoluble fluid possesses a greater density than the two-phase fluid, for example, to facilitate or enable fluid displacement, and/or to reduce the need for or the proportion of two phase fluid removed due to flushing and/or to reduce the potential separation demands of fluid-fluid or liquid-liquid separation processes. In some embodiments, for example, it may be desirable for the at least partially insoluble fluid to be transferred into or enter into the heat transfer loop from a higher elevation and/or exit the heat transfer loop at a lower elevation, if, for example, the at least partially insoluble fluid possesses a lesser density than the two-phase fluid, for example, to facilitate or enable fluid displacement, and/or to reduce the need for or the proportion of two phase fluid removed due to flushing and/or to reduce the potential separation demands of fluid-fluid or liquid-liquid separation processes.

Note: In some embodiments, at least a portion of any two phase fluid at a gas phase in the heat transfer loop may be condensed to a liquid phase. In some embodiments, two phase fluid may be condensed by, including, but not limited to, one or more or any combination of the following: cooling to a temperature below the boiling point, or by transferring into the heat transfer loop at least a portion additional two phase fluid, or increasing the pressure by transferring into the heat transfer loop at least a portion of an at least partially insoluble fluid while restricting or closing off the flow of fluid from exiting the heat transfer loop, or increasing the pressure by transferring into the heat transfer loop at least a portion of additional two phase fluid while restricting or closing off the flow of fluid from exiting the heat transfer loop, or by changing the morphology or shape or volume of the heat transfer loop, or decreasing the available volume of the heat transfer loop, or collapsing the volume or shrinking the volume of the heat transfer loop, or any combination thereof. It may be desirable for the two phase fluid to be at a liquid phase before deinstallation, or displacement with an at least partially insoluble fluid, or any combination thereof to, for example, prevent or reduce the potential release of gas phase two phase fluid.

Note: In some embodiments, for example, it may be desirable to pump or otherwise transfer at least partially insoluble fluid, or two phase fluid, or any combination thereof into a heat transfer loop such that the volume or mass of the fluid entering the heat transfer loop may be greater than the volume or mass of the fluid exiting the heat transfer loop. In some embodiments, for example, it may be desirable to pump or otherwise transfer at least partially insoluble fluid, or two phase fluid, or any combination thereof into a heat transfer loop while restricting or closing off at least a portion of the flow of fluid exiting the heat transfer loop to, for example, increase the internal fluid pressure and/or to facilitate the condensing of at least a portion of any residual gas phase two phase fluid into liquid phase two phase fluid. In some embodiments, it may be desirable for at least a portion of two phase fluid to be condensed to a liquid phase in advance of or during deinstallation or removal of two phase fluid.

Note: In some embodiments, for example, before deinstallation or removal, or as a step in deinstallation or removal, it may be desirable to cool the two phase fluid in a heat transfer loop to a temperature less than or significantly less than the two phase fluid's boiling point at the pressure in the heat transfer loop to facilitate the condensing of any gas phase two phase fluid. It may be desirable for the two phase fluid to be at a liquid phase before deinstallation, or displacement with an at least partially insoluble fluid, or any combination thereof to, for example, prevent or reduce the potential release of gas phase two phase fluid.

Note: In some embodiments, it may be desirable pump or transfer additional two phase fluid in a heat transfer loop at least partially occupied by two phase fluid to increase the pressure in the heat transfer loop and/or to force or facilitate or enable the condensing of at least a portion of any gas phase two phase fluid to a liquid phase. In some embodiments, for example, before deinstallation or removal, or as a step in deinstallation or removal, it may be desirable pump or transfer additional two phase fluid in a heat transfer loop at least partially occupied by two phase fluid to increase the pressure in the heat transfer loop and/or to force or facilitate or enable the condensing of at least a portion of any gas phase two phase fluid to a liquid phase. It may be desirable for the two phase fluid to be at a liquid phase before deinstallation, or displacement with an at least partially insoluble fluid, or any combination thereof to, for example, prevent or reduce the potential release of gas phase two phase fluid.

Note: In some embodiments, it may be desirable to cool the two phase fluid in a heat transfer loop to a temperature less than or significantly less than the two phase fluid's boiling point at the pressure in the heat transfer loop to facilitate the condensing of any gas phase two phase fluid to liquid phase two phase fluid and/or to pump or otherwise transfer two phase fluid into the heat transfer loop to, for example, provide liquid volume to makeup for the volume lost or volume reduction resulting from the condensing of the two phase fluid. In some embodiments, for example, before deinstallation or removal, or as a step in deinstallation or removal, it may be desirable to cool the two phase fluid in a heat transfer loop to a temperature less than or significantly less than the two phase fluid's boiling point at the pressure in the heat transfer loop to facilitate the condensing of any gas phase two phase fluid to liquid phase two phase fluid and/or to pump or otherwise transfer two phase fluid into the heat transfer loop to, for example, provide liquid volume to makeup for the volume lost or volume reduction resulting from the condensing of the two phase fluid.

Note: In some embodiments, at least a portion of any two phase fluid at a gas phase in the heat transfer loop may be condensed to a liquid phase, or gas phase separated from any liquid phase, or any combination thereof, by, for example, including, but not limited, one or more or any combination of the following: cooling to at or below boiling point, or pumping or transferring in more two phase fluid, or increasing the total mass of two phase fluid in the heat transfer loop, or pumping or transferring in at least partially insoluble fluid, or cooling, or reducing volume, or gas-liquid separation.

Note: In some embodiments, at least a portion of two phase fluid may exit a heat transfer loop at a gas phase. In some embodiments, it may be desirable to cool, or compress, or condense, or any combination thereof at least a portion of any fluids exiting a heat transfer loop. In some embodiments, at least a portion of two phase fluid may exit a heat transfer loop at a gas phase. In some embodiments, it may be desirable to cool, or compress, or condense, or any combination thereof at least a portion of any fluids comprising at least a portion of a gas phase within or exiting a heat transfer loop. In some embodiments, it may be desirable to separate at least a portion of any gas phase from liquid phase fluids and/or condense, or cool, or compress, or any combination thereof the gas phase two phase fluid to store and/or liquefy at least a portion of the gas phase two phase fluid. In some embodiments, for example, gas phase two phase fluid may be separated from liquid phase and/or condensed or compressed or stored when exiting the heat transfer loop. In some embodiments, when at least partially insoluble fluid displaces two phase fluid, at least a portion of the two phase fluid may be at a gas phase, or may exit the heat transfer loop at a gas phase, or any combination thereof and/or it may be desirable to separate, or isolate, or condense, or compress, or store, or any combination thereof the gas phase two phase fluid.

(2) Displacing and/or Purging the At Least Partially Insoluble Fluid from the Heat Transfer Loop using an Inert Gas: In some embodiments, for example, an inert gas may be transferred into the heat transfer loop which may be at least partially occupied by or may comprise an at least partially insoluble fluid, and/or wherein at least a portion of said inert gas may displace at least a portion of the at least partially insoluble fluid, or may mix with at least a portion of the at least partially insoluble fluid to form an inert gas-liquid mixture, or mix with at least a portion of the at least partially insoluble fluid to form an inert gas-vapor mixture, or any combination thereof and/or may displace or otherwise transfer at least a portion of said at least partially insoluble fluid from the heat transfer loop. For example, in some embodiments, it may be desirable for the inert gas to comprise a gas and the at least partially insoluble fluid to comprise a liquid. For example, in some embodiments, it may be desirable for the inert gas to comprise a gas and the at least partially insoluble fluid to comprise a liquid, wherein a portion of said at least partially insoluble fluid may evaporate or form a vapor, for example, in the presence of the inert gas. In some embodiments, an inert gas may be transferred into a heat transfer loop, displacing at least a portion of the at least partially insoluble fluid from the heat transfer loop. In some embodiments, for example, inert gas may be transferred into the heat transfer loop to purge or remove at least a portion of any residual at least partially insoluble fluid, or two phase fluid, or any combination thereof from the heat transfer loop. For example, in some embodiments, ‘dry’ inert gas may be transferred into the heat transfer loop, wherein at least a portion of residual at least partially insoluble fluid may be removed by the inert gas as, for example, an aerosol or vapor or evaporated vapor forming ‘wet’ inert gas, and/or the ‘wet’ inert gas may be exhausted or released or discharged or vented. For example, in some embodiments, ‘dry’ inert gas may be transferred into the heat transfer loop, wherein at least a portion of any residual at least partially insoluble fluid may be removed by the inert gas to form, for example, an aerosol or vapor or evaporated vapor, and/or forming ‘wet’ inert gas or inert gas exiting the heat transfer loop, and/or the ‘wet’ inert gas or inert gas exiting the heat transfer loop may be, including, but not limited to, one or more or any combination of the following: separated, or dried, or may be regenerated into ‘dry’ inert gas, or a portion of any at least partially insoluble fluid vapor or aerosol may be removed, or a portion of any at least partially insoluble fluid vapor or aerosol may be separated, or a portion of any at least partially insoluble fluid vapor or aerosol may be recovered, or at least a portion of any at least partially insoluble fluid or at least a portion of any two phase fluid vapor or aerosol may be removed or separated or recovered, or recirculated, or transferred into the heat transfer loop, or compressed, or transferred into inert gas storage. For example, in some embodiments, inert gas may be transferred into the heat transfer loop, wherein at least a portion of residual at least partially insoluble fluid and/or residual two phase fluid may be removed by the inert gas as, for example, an aerosol or vapor or evaporated vapor, forming ‘wet’ inert gas or inert gas exiting the heat transfer loop, and/or the ‘wet’ inert gas or inert gas exiting the heat transfer loop may be, including, but not limited to, one or more or any combination of the following: separated, or dried, or may be regenerated into ‘dry’ inert gas, or a portion of any at least partially insoluble fluid vapor or aerosol may be removed, or a portion of any at least partially insoluble fluid vapor or aerosol may be separated, or a portion of any at least partially insoluble fluid vapor or aerosol may be recovered, or at least a portion of any two phase fluid vapor or aerosol may be removed or separated or recovered, or a portion of any two phase fluid vapor or aerosol may be removed, or a portion of any two phase fluid vapor or aerosol may be separated, or a portion of any at two phase fluid vapor or aerosol may be recovered, or at least a portion of any two phase fluid or at least partially insoluble fluid vapor or aerosol may be removed or separated or recovered or recirculated, or transferred into the heat transfer loop, or compressed, or transferred into inert gas storage, or transferred into storage, or vented, or exhausted. In some embodiments, inert gas may be generated or produced on site, or generated or produced offsite, or transferred to site, or stored on site, or stored offsite, or pipelined, or transferred, or provided to the facility, or distributed throughout the facility, or any combination thereof. In some embodiments, the volume or mass of an at least partially insoluble fluid displaced by the inert gas, or purged by the inert gas, or otherwise transferred from the heat transfer loop may be measured or monitored. For example, in some embodiments, it may be desirable to transfer or circulate the inert gas in the heat transfer loop until, for example, at least 80%, or 85%, or 90%, or 95%, or 99%, or 99.5%, or 99.9%, or any combination thereof of the at least partially insoluble fluid may be transferred, or recovered, or removed from the heat transfer loop. In some embodiments, the mass or volume of the at least partially insoluble fluid transferred from or exiting the heat transfer loop may be measured or monitored or weighed to, for example, determine if sufficient at least partially insoluble fluid has been recovered or removed or otherwise transferred from the heat transfer loop. For example, in some embodiments, the volume or mass of the at least partially insoluble fluid which may have exited the heat transfer loop may be measured or monitored by, including, but not limited to, one or more or any combination of the following: the volumetric level or liquid level of the at least partially insoluble fluid in storage or separation, or the volumetric level or liquid level of the liquid-liquid interface between two phase fluid and at least partially insoluble fluid in storage or in a separator, or fluid density, or total mass of fluid in storage, or total mass change of fluid in storage or system before or during or after or any combination thereof of transfer of at least a portion of inert gas into the heat transfer loop, or mass flow meter, or volumetric flow meter, or any combination thereof. In some embodiments, at least a portion of the at least partially insoluble fluid may be separated, or transferred, or recovered, or removed, or any combination thereof by fluid displacement. In some embodiments, it may be desirable to pause transferring inert gas into the heat transfer loop or pause purging with the inert gas when, for example, a significant portion or at least 50%, or 75%, or 80%, or 85%, or 90%, or 91%, or 92%, or 93%, or 94%, or 95%, or 96%, or 97%, or 98%, or 99%, or 99.5%, or 99.9%, or any combination thereof of the at least partially insoluble fluid mass or volume originally transferred into the heat transfer loop may be removed or displaced from the heat transfer loop. In some embodiments, for example, the concentration of at least partially insoluble fluid, or two-phase fluid, or any combination thereof in the inert gas may be measured or monitored. For example, in some embodiments, the concentration of at least partially insoluble fluid, or two-phase fluid, or any combination thereof in the inert gas exiting the heat transfer loop may be measured or monitored. For example, in some embodiments, the concentration of or amount of or rate of at least partially insoluble fluid vapor, or droplets, or aerosol, or misted liquid, or demisted liquid, or any combination thereof may be measured or monitored. For example, in some embodiments, the concentration of or amount of or rate of two-phase fluid vapor, or droplets, or aerosol, or misted liquid, or demisted liquid, or any combination thereof may be measured or monitored. For example, in some embodiments, the measurement or monitoring of mass of the at least partially insoluble fluid may include the mass of at least partially insoluble fluid in, or carried by, or exiting the heat transfer loop in, or any combination thereof the inert gas. For example, in some embodiments, it may be desirable to pause inert gas transfer into the heat transfer loop, or circulating inert gas, or purging inert gas, or any combination thereof when the concentration of at least partially insoluble fluid vapor in the inert gas decreases to a concentration less than a desired concentration or threshold concentration, such as, for example, less than 1000 PPM, or 500 PPM, or 100 PPM, or 50 PPM, or 10 PPM, or 5 PPM, or 1 PPM, or 0.1 PPM, or any combination thereof. For example, in some embodiments, it may be desirable to pause inert gas transfer into the heat transfer loop, or circulating inert gas, or purging inert gas, or any combination thereof when the concentration of two phase fluid vapor in the inert gas decreases to a concentration below a desired concentration or threshold concentration, such as, for example, below 1000 PPM, or 500 PPM, or 100 PPM, or 50 PPM, or 10 PPM, or 5 PPM, or 1 PPM, or 0.1 PPM, or 0.01 PPM, or 0.001 PPM, or any combination thereof. In some embodiments, it may be desirable to measure or monitor the volume or mass of gas transferred into the heat transfer loop or system. In some embodiments, the volume or mass of gas may be measured by, for example, including, but not limited to, one or more or any combination of the following: flow meter, or mass flow meter, or volumetric flow meter, or gas analyzer, or gas analyzer, or gas totalizer, or tank mass, or change in mass, or pressure, or pressure change, or total pressure.

INSTALLING RECOVERABLE TWO-PHASE FLUID EMPLOYING INERT GAS DISPLACEMENT AND TWO PHASE FLUID RECOVERY: In some embodiments, for example, systems and/or methods for installing two phase fluid may comprise, including, but not limited to, one or more or any combination of the following:

(1) Adding Recoverable Two-Phase Fluid to the Heat Transfer Loop and/or Pressurizing until at least a portion of Recoverable Two-Phase Fluid is at a Liquid Phase: In some embodiments, a two-phase fluid may be transferred into a heat transfer loop, wherein the heat transfer loop may be occupied by a gas, such as an inert gas. In some embodiments, a two-phase fluid may be pumped or otherwise transferred into a heat transfer loop, increasing the pressure or pressurizing the heat transfer loop to a pressure sufficient for at least a portion of the two-phase fluid to comprise a liquid phase. In some embodiments, the inert gas present in the heat transfer loop may be compressed by the two-phase fluid and/or sufficient two-phase fluid may be added to or transferred into the heat transfer loop such that a gas-liquid interface forms, wherein the two phase fluid comprises the liquid phase and the inert gas comprises the gas phase in the gas-liquid interface. In some embodiments, sufficient two phase fluid may be added or transferred into the heat transfer loop such that the total pressure inside the heat transfer loop or the internal pressure within the heat transfer loop may be near or about the same as a desired, or threshold, or design, or any combination thereof pressure of the heat transfer loop. In some embodiments, for example, it may be desirable to add or transfer two phase fluid into the heat transfer loop such that the pressure within the heat transfer loop approaches or reaches desired or design pressure and/or to achieve a substantial proportion of two-phase fluid in the heat transfer loop at a liquid phase to, for example, reduce the potential amount of two phase fluid vapor which may need to be separated from inert gas. In some embodiments, it may be desirable to cool the two-phase fluid before or while transferring the two-phase fluid into the heat transfer loop, or to cool the two-phase fluid while the two phase fluid is in the heat transfer loop, or any combination thereof to, for example, reduce the two phase fluid vapor pressure and/or reduce the potential amount of the two phase fluid vapor which may need to be separated from the inert gas. In some embodiments, it may be desirable to vacuum or remove at least a portion of inert gas from the heat transfer loop, which may result in the internal pressure of the heat transfer loop decreasing to a pressure less than ambient pressure or less than atmospheric pressure. In some embodiments, it may be desirable to vacuum or remove at least a portion of inert gas from the heat transfer loop, which may result in the internal pressure of the heat transfer loop decreasing to a pressure less than ambient pressure or less than atmospheric pressure, before transferring two phase fluid into the heat transfer loop, to, for example, reduce the potential amount of inert gas which may need to be removed or separated from the two phase fluid in the heat transfer loop, or reduce the potential amount of two phase fluid vapor which may be mixed with or be present in the inert gas which may need to be separated from the two phase fluid in the heat transfer loop, or any combination thereof.

(2) Separating Inert Gas from Recoverable Two-Phase Fluid Liquid: In some embodiments, a heat transfer loop may be occupied by fluids comprising two-phase fluid and/or inert gas. In some embodiments, it may be desirable to separate at least a portion of the inert gas from at least a portion of the two-phase fluid. In some embodiments, at least a portion of the two-phase fluid may comprise a liquid phase and at least a portion of the inert gas may comprise a gas phase. In some embodiments, at least a portion of the two-phase fluid comprising a liquid phase may be separated from at least a portion of inert gas comprising a gaseous phase by a gas-liquid separation. In some embodiments, at least a portion of the two-phase fluid comprising a liquid phase may be separated from at least a portion of inert gas comprising a gaseous phase by a gas-liquid separation while the two-phase fluid and/or inert gas are pumped and/or circulated within a heat transfer loop. In some embodiments, at least a portion of the two-phase fluid comprising a liquid phase may be separated from at least a portion of inert gas comprising a gaseous phase by a gas-liquid separation using a gas-liquid separation system external to the heat transfer loop. In some embodiments, at least a portion of the two-phase fluid comprising a liquid phase may be separated from at least a portion of the inert gas comprising a gaseous phase, wherein the two phase fluid comprising a liquid phase displaces the at least a portion of the inert gas comprising a gaseous phase. For example, in some embodiments, additional two-phase fluid may be added or transferred into the heat transfer loop while, for example, at least a portion of inert gas may be removed from the heat transfer loop, to, for example, occupy at least a portion of the volume in heat transfer loop which may have previously been occupied by inert gas. For example, in some embodiments, inert gas comprising a gaseous phase may be separated from two phase fluid comprising a liquid phase by, for example, including, but not limited to, one or more or any combination of the following: an automatic gas remover, or an automatic air remover, or a decanter, or an automatic gas vent, or an automatic air vent, or an in-line air remover, or an in-line gas remover, or automatic air eliminator, or float automatic air separator, or a centrifuge, or a coalescer, or a defrother, or a defoamer. In some embodiments, separated or recovered inert gas may be captured, or transferred, or further separated, or treated, or stored, or any combination thereof. In some embodiments, inert gas separated from two phase fluid comprising a liquid may comprise inert gas further comprising two-phase fluid vapor or may comprise two-phase fluid vapor rich inert gas and/or at least a portion of two-phase fluid vapor may be separated and/or recovered from the two-phase fluid vapor rich inert gas.

(3) Separating Recoverable Two-Phase Fluid Vapor from Inert Gas: In some embodiments, two phase fluid vapor may be present in the inert gas separated from a liquid comprising a two phase fluid. In some embodiments, at least a portion of two phase fluid vapor may be removed or separated from an inert gas comprising at least a portion of two-phase fluid vapor. For example, in some embodiments, two phase fluid vapor may be removed from an inert gas by, including, but not limited to, one or more or any combination of the following: absorption in a solvent, or absorption in water, or a chemical reaction or a membrane based process, or cooling separation, or cryogenic separation, or condensation, or deposition, or adsorption, a molecular sieve, or combustion, or catalytic degradation, or venting, or exhausting. For example, in some embodiments, two phase fluid vapor may be at least partially soluble in a solvent and/or inert gas comprising at least a portion of two phase fluid vapor may be contacted with a solvent and/or said solvent may absorb at least a portion of the two phase fluid vapor. In some embodiments, at least a portion of two phase fluid may be recovered or regenerated from solvent comprising absorbed two phase fluid by, including, but not limited to, one or more or any combination of the following: desorption, or pressure swing, or thermal regeneration, or stripping, or steam stripping, or steam desorption, or thermal desorption, or distillation, or any combination thereof. In some embodiments, the two phase fluid may be reactive. For example, in some embodiments, the two phase fluid may comprise an acid or an acid gas. For example, in some embodiments, the two phase fluid may comprise an acid or an acid gas, and/or two phase fluid vapor may be at least partially removed or recovered by contacting or reacting with a basic chemical, or basic solution, or basic solid, or any combination thereof. For example, in some embodiments, a two phase fluid may comprise sulfur dioxide, which may comprise an acid or acid gas, and/or at least a portion of sulfur dioxide vapor may be removed or recovered by contacting or reacting with a basic chemical, or basic solution, or basic solid, or any combination thereof. For example, in some embodiments, the two phase fluid may comprise a base or a basic gas. For example, in some embodiments, the two phase fluid may comprise an base or basic gas, and/or two phase fluid vapor may be at least partially removed or recovered by contacting or reacting with an acidic chemical, or acidic solution, or acidic solid, or any combination thereof. For example, in some embodiments, a two phase fluid may comprise ammonia, which may comprise an base or basic gas, and/or at least a portion of ammonia vapor may be removed or recovered by contacting or reacting with an acidic chemical, or acidic solution, or acidic solid, or any combination thereof. In some embodiments, a two phase fluid may react with an acidic or basic solution or solid and/or the two phase fluid may be regenerated from the two-phase fluid rich solution by, for example, including, but not limited to, one or more or any combination of the following: thermal desorption, or chemical reaction, or a neutralization reaction, or a displacement reaction, or thermal decomposition, or calcining. For example, in some embodiments, a two phase fluid vapor comprising sulfur dioxide may react with a sulfur dioxide lean amine absorbent solution, forming sulfur dioxide rich amine solution, and/or the sulfur dioxide rich amine solution may be heated to form a gas comprising sulfur dioxide and an amine solution lean in sulfur dioxide. For example, in some embodiments, a two phase fluid vapor comprising sulfur dioxide may react with an solution comprising an alkali salt, such as sodium hydroxide, or sodium carbonate, or sodium bicarbonate, or sodium-carboxylic acid, or any combination thereof, to form an aqueous solution or solid comprising sodium sulfite, or sodium bisulfite, or sodium metabisulfite, or any combination thereof and/or reacting said formed solid with calcium oxide or calcium hydroxide to form a solid comprising calcium sulfite and/or decomposing said formed calcium sulfite to form a gas or fluid comprising sulfur dioxide and a solid comprising calcium oxide. For example, in some embodiments, a two phase fluid vapor comprising sulfur dioxide may react with a solid, or a solid-liquid mixture, or a suspension, or a solution, or any combination thereof comprising an alkaline earth oxide, or an alkaline earth hydroxide, or calcium oxide, or calcium hydroxide, or magnesium oxide, or magnesium hydroxide, or any combination thereof to form a solid or solution comprising an alkaline earth sulfite, or calcium sulfite, or magnesium sulfite, and/or decomposing or calcining or reacting said formed sulfite to form a gas or fluid comprising sulfur dioxide. For example, in some embodiments, a two phase fluid vapor comprising ammonia may react with an aqueous solution comprising an ammonium phosphate lean in ammonia, forming an aqueous solution comprising ammonium phosphate rich in ammonia, and/or the aqueous solution comprising ammonium phosphate rich in ammonia may be heated to form a gas comprising ammonia. For example, in some embodiments, a two phase fluid vapor comprising ammonia may be absorbed in an aqueous solution comprising water lean in ammonia, forming an aqueous solution comprising water rich in ammonia, and/or the aqueous solution comprising water rich in ammonia may be heated or steam stripped to form a gas comprising ammonia. For example, in some embodiments, a two phase fluid vapor comprising ammonia may be absorbed in an aqueous solution comprising water lean in ammonia, forming an aqueous solution comprising water rich in ammonia, and/or the aqueous solution comprising water rich in ammonia may be reacted with carbon dioxide to form an ammonia-carbon dioxide salt, and/or concentrating and/or precipitating or crystallizing at least a portion of said ammonia-carbon dioxide salt; and/or including, but not limited to, one or more or any combination of the following: separating said ammonia-carbon dioxide salt, or selling said precipitate, or converting said precipitate into a valuable chemical, or employing said ammonia-carbon dioxide in a chemical process, or employing said ammonia-carbon dioxide as a fertilizer, or employing said ammonia-carbon dioxide to produce a fertilizer, or reacting or employing said ammonia-carbon dioxide to form captured carbon dioxide, or reacting or employing said ammonia-carbon dioxide to form captured ammonia, or transporting said precipitate, or separating at least a portion of ammonia from at least a portion of carbon dioxide in said precipitate or any combination thereof. For example, in some embodiments, a two-phase fluid vapor comprising ammonia may be absorbed in an aqueous solution comprising sulfuric acid, forming an aqueous solution or solid comprising ammonium sulfate or ammonium bisulfate and/or removing at least a portion of the ammonia vapor from, for example, other gas or gases. In some embodiments, for example, two phase fluid vapor may be separated from a gas, such as an inert gas, by cooling or cryogenic separation. For example, in some embodiments, two phase fluid may exhibit significantly higher temperature condensing point, or lower vapor pressure, or higher temperature sublimation point, or higher temperature deposition point, or any combination thereof than, for example, some inert gases, and/or cooling or cryogenically cooling a gas comprising two phase fluid vapor by result in the condensation or deposition of at least a portion of two phase fluid and/or the separation of at least a portion of two phase fluid from one or more other gases. In some embodiments, two phase fluid vapor or two phase fluid chemical may be at least partially separated by a membrane-based process, or a gas membrane based process, or a selective membrane based process, or electrodialysis, or a molecular sieve, or any combination thereof. In some embodiments, at least a portion of separated gas or inert gas, for example, after the removal or separation of at least a portion of two phase fluid vapor, may be, including, but not limited to, one or more or any combination of the following: stored, or transferred to the heat transfer loop, or recirculated into the heat transfer loop, or exhausted, or vented, or treated, or dehydrated, or dried, or undergo at least a portion of water vapor removal, or any combination thereof.

(4) Removing at Least a Portion of any Excess Recoverable Two-Phase Fluid from the Heat Transfer Loop when at Least a Portion of the Recoverable Two-Phase Fluid Phase Transitions from a Liquid Phase to a Gas Phase due to Heat Input or Operation of the Heat Transfer Loop: In some embodiments, a heat transfer loop may move heat or transfer heat by absorbing heat in a two phase fluid wherein the two phase fluid endothermically phase transitions from at least a portion of a first phase to at least a portion of second phase, and/or releasing heat from the two phase fluid wherein the two phase fluid exothermically phase transitions from at least a portion of a second phase to at least a portion of a first phase. In some embodiments, a heat transfer loop may move heat or transfer heat by absorbing heat in a two phase fluid wherein the two phase fluid endothermically phase transitions from at least a portion of a liquid phase to at least a portion of gas phase, and/or releasing heat from the two phase fluid wherein the two phase fluid exothermically phase transitions from at least a portion of a gas phase to at least a portion of a liquid phase. In some embodiments, a phase transition may result in a change in the volume or density of the fluid for the same amount of fluid or fluid mass. In some embodiments, for example, a heat transfer loop may be occupied by two phase fluid comprising liquid phase two phase fluid, and/or it may be desirable to remove at least a portion of two phase fluid from the heat transfer loop to facilitate the formation of at least a portion of two phase fluid vapor in the heat transfer loop, for example, to enable two phase heat transfer operation. For example, in some embodiments, at least a portion of the mass of two phase fluid may be removed or may displaced from the heat transfer loop by, for example, including, but not limited to, one or more or any combination of the following: heating, or the application of heat, or at least partial depressurization, or opening a valve, or opening access to new or additional volume, or any combination thereof. In some embodiments, it may be desirable to store at least a portion of the displaced or removed two phase fluid.

REMOVING OR DEINSTALLING RECOVERABLE TWO-PHASE FLUID EMPLOYING INERT GAS DISPLACEMENT AND TWO PHASE FLUID RECOVERY: In some embodiments, for example, systems and/or methods for removing or recovering two phase fluid may comprise, including, but not limited to, one or more or any combination of the following:

(1) Preparation for Displacing Two-Phase Fluid with Inert Gas: In some embodiments, before displacing with an inert gas, it may be desirable to add two phase fluid to the heat transfer loop to increase proportion of heat transfer loop volume occupied by two phase fluid comprising a liquid and/or reduce proportion of heat transfer loop volume occupied by two phase fluid vapor and/or to increase heat transfer loop pressure and/or to promote the phase transition at least a portion of any two phase fluid comprising a vapor phase into a liquid phase. For example, in some embodiments, it may be desirable to pump or otherwise transfer additional two phase fluid into the heat transfer loop to promote or facilitate the phase transition of at least a portion of two phase fluid vapor into two phase fluid liquid and/or increase the proportion of heat transfer loop volume occupied by a liquid phase. In some embodiments, in the heat transfer loop, it may be desirable to increase the proportion of two phase fluid at a liquid phase or the proportion of the heat transfer loop comprising liquid phase two phase fluid to, for example, reduce the potential volume or amount of two phase fluid vapor which may mix with inert gas, for example, if or when two phase fluid may be displaced by an inert gas. In some embodiments, it may be desirable to cool the two phase fluid in the heat transfer loop to, for example, reduce the potential volume or amount of two phase fluid vapor which may mix with inert gas during displacing, or reduce the vapor pressure of the two phase fluid, or any combination thereof.

(2) Displacing Two-Phase Fluid with Inert Gas: In some embodiments, an inert gas may be pumped or pressurized or fed or otherwise transferred into a heat transfer loop comprising or at least partially occupied by a two-phase fluid. In some embodiments, it may be desirable to increase the pressure within the heat transfer loop through the transfer or addition of or application of inert gas into the heat transfer loop. In some embodiments, inert gas may be transferred into a heat transfer loop at a first port in the heat transfer loop, and/or a second port in the heat transfer loop may be opened, for example, allowing the displacement or removal of at least a portion of two-phase fluid from the heat transfer loop, for example, through the second power. In some embodiments, it may be desirable for the second port to be configured to allow for the transfer or exit or passing of fluid comprising a liquid phase or a fluid with a density greater than desired density from the heat transfer loop, and/or prevent the passing or transfer or exit of a fluid comprising a gas phase or a fluid with a density less than desired density from the heat transfer loop. In some embodiments, it may be desirable for a third port to be present to allow for, for example, the transfer or removal or passing or exit of a gas or at least a portion of a gas from the heat transfer loop. In some embodiments, it may be desirable for the heat transfer loop to maintain a pressurized state during displacement of two-phase fluid. For example, in some embodiments, it may be desirable for the heat transfer loop to be at a pressure above atmospheric pressure to ensure at least a portion of two-phase fluid is at a liquid phase or maintain liquid phase state of the two phase fluid. For example, in some embodiments, it may be desirable for the heat transfer loop to be at a pressure above the vapor pressure of the two-phase fluid at the temperature of the two-phase fluid in the heat transfer loop to ensure, for example, at least a portion of the displaced or removed two phase fluid may be at a liquid phase or may maintain a liquid phase state. In some embodiments, it may be desirable for the heat or heat source to be turned off during the displacement or removal of two-phase fluid. In some embodiments, it may be desirable to cool the two-phase fluid in the heat transfer loop before or during displacement or removal of at least a portion of two phase fluid from the heat transfer loop. In some embodiments, it may be desirable for the inert gas transferred into the heat transfer loop to be dry or of a lower water vapor concentration or of a reduced water vapor concentration, to, for example, prevent potential chemical reaction or corrosion of components which may occur in the presence of water and/or some two phase fluids. In some embodiments, a gas-liquid separator or gas remover may be employed to separate any gas or vapors from liquid. For example, in some embodiments, it may be desirable to separate or recover or remove at least a portion of any gas present in the two phase fluid being transferred through or from or out of the heat transfer loop. In some embodiments, an inert gas may be employed to, for example, prevent or avoid or reduce corrosion or oxidation, or prevent or avoid or reduce risk of combustion, or prevent or avoid or reduce risk of ignition, or any combination thereof. In some embodiments, air may be may be employed as an inert gas, for example, if, for example, the two phase fluid may possess low flammability, or no flammability, or low risk of interactions or reactions with air under the conditions in or near the heat transfer loop or in the environment of the heat transfer loop, or any combination thereof.

(3) Depressurizing Heat Transfer Loop and/or Removing at Least a Portion of Gas or Vapor from Heat Transfer Loop and/or Separating Two-Phase Fluid Vapor from Inert Gas: In some embodiments, during or following the displacement and/or removal of at least a portion of two phase fluid or at least a portion of two phase fluid liquid, at least a portion of the heat transfer loop may be occupied by gas or vapor, or inert gas, or two phase fluid vapor, or a mixture comprising inert gas and two phase fluid vapor, or any combination thereof, and/or if the internal pressure of the heat transfer loop, for example, comprises a pressure greater than, for example, ambient pressure or atmospheric pressure, it may be desirable to depressurize the heat transfer loop by opening a valve or port and/or transfer at least a portion of fluid, such as gas, or vapor, or liquid, or any combination thereof, from the heat transfer loop into, for example, storage, or separation, or treatment, or venting, or any combination thereof. In some embodiments, for example, at least a portion of the gas or vapor or any combination thereof exiting or transferred from the heat transfer loop may be captured, or recovered, or transferred, or stored or any combination thereof. In some embodiments, for example, a fluid exiting a heat transfer loop comprising inert gas and/or two-phase fluid may be separated by, for example, including, but not limited to, systems or methods for at least partially separating a two phase fluid from an inert gas described herein. In some embodiments, systems or methods employed for separating, or recovering, or removing, or any combination thereof at least a portion of the two-phase fluid may change as the vapor concentration of the two phase fluid change. For example, in some embodiments, systems or methods for separating, or recovering, or removing, or any combination thereof two phase fluid vapor may be different for higher concentrations of two phase fluid vapor than, for example, lower concentrations of two phase fluid vapor. For example, in some embodiments, if vapor is recovered from an inert gas, or the vapor is diluted by an inert gas, or any combination thereof, the concentration of two phase fluid vapor in a gas stream may decrease. For example, in some embodiments, at least a portion of two phase fluid vapor may be recovered or separated by cryogenic separation at higher vapor concentrations or partial pressures and/or at least a portion of two phase fluid vapor may be removed by reaction with an acidic solution or a basic solution at lower vapor concentrations or partial pressures. For example, in some embodiments, two phase fluid vapor separation, or recovery, or removal, or any combination thereof may comprise a more than one system or method, or more than one separation mechanism, or more than one process step, or any combination thereof. For example, in some embodiments, in some embodiments, a first gas comprising a gas rich in two phase fluid vapor may be contacted with a physical, wherein the solvent absorbs at least a portion of the two phase fluid vapor and forms at least a portion of a second gas comprising gas lean in two phase fluid vapor, then, in some embodiments, for example, the second gas comprising gas lean in two phase fluid vapor may be contacted with an acidic or basic solution to react with at least a portion of the residual two phase fluid vapor and/or forming a third gas comprising gas ultra-lean in two phase fluid vapor. For example, in some embodiments, at least a portion of two phase fluid vapor may be recovered from a gas comprising a higher concentration of two phase fluid vapor using a physical solvent, and/or at least a portion of two phase fluid vapor may be recovered from a gas comprising a higher, or middle, or lower concentration of two phase fluid vapor using a chemical solvent or absorbent, or and/or at least a portion of two phase fluid vapor may be recovered from a gas comprising a higher, or middle, or lower concentration of two phase fluid vapor using an acid or a base which may reacted with the two phase fluid vapor.

(4) Purging Heat Transfer Loop with Inert Gas and/or Separating Two-Phase Fluid Vapor from Inert Gas: In some embodiments, residual two phase fluid or residual two-phase fluid vapor may be present in a heat transfer loop. In some embodiments, residual two phase fluid or residual two phase fluid vapor may be present in a heat transfer loop following the depressurization and/or removal of at least a portion of inert gas, or two-phase fluid, or any combination thereof. In some embodiments, it may be desirable to transfer inert gas into the heat transfer loop, or circulate inert gas in the heat transfer loop, or dilute two phase fluid vapor in the heat transfer loop, or any combination thereof and/or allow gas or vapor to be transferred from, or circulate within, or any combination thereof the heat transfer loop. For example, in some embodiments, it may be desirable to purge a heat transfer loop comprising residual two phase fluid vapor with an inert gas. For example, in some embodiments, it may be desirable to separate, or recover, or remove, or any combination thereof two phase fluid vapor from gases or fluids within or transferred from the heat transfer loop. For example, in some embodiments, two phase fluid vapor may be recovered from a gas comprising an inert gas and/or two phase fluid vapor by, for example, including, but not limited to, one or more or any combination of systems or methods described herein. In some embodiments, the concentration of two phase fluid vapor may change during displacement or purging and/or the systems or methods employed to recover, or separate, or remove, or any combination thereof two phase fluid vapor may change as the concentration or amount of two phase fluid vapor changes. In some embodiments, two phase fluid vapor separation, or recovery, or removal, or any combination thereof may comprise one process step or separation mechanism. In some embodiments, two phase fluid vapor separation, or recovery, or removal, or any combination thereof may comprise multiple process steps or separate mechanisms In some embodiments, the transfer of inert gas into a heat transfer loop, or purging with an inert gas, or the circulation of an inert gas, or any combination thereof may be paused or cease when the concentration of two phase fluid vapor in the heat transfer loop, or exiting the heat transfer loop, or transferred from the heat transfer loop decreases to less than or equal to a threshold concentration or a desired concentration of two phase fluid vapor, which may be measured by, for example, a gas sensor.

Additional Description which May be Applicable to Some Embodiments Comprising the Installation or Deinstallation or Removal of Some Two Phase Fluids, which May Include, but are not Limited to, Sulfur Dioxide or Ammonia:
In some embodiments, it may be desirable to dry the inert gas, or at least partially reduce or eliminate the presence or concentration of at least a portion of any water vapor before or during the transfer or circulation of the inert gas into or in the heat transfer loop to, for example, prevent the presence of water in the presence of some two phase fluids, such as sulfur dioxide or ammonia, which may result in the corrosion or degradation or reaction with copper, or aluminum, or other metals, or other materials, or other chemicals, or any combination thereof which may be present in heat exchanger, or other heat transfer loop components, or other system components, or any combination thereof.
In some embodiments, an inert gas may comprise air or a gas comprising oxygen. In some embodiments, a two-phase fluid may exhibit low flammability in the presence of diatomic oxygen at the temperatures or conditions of operation of the heat transfer loop, or may be non-flammable under the temperatures or other conditions in a heat transfer loop. For example, sulfur dioxide may be non-flammable at the temperatures or conditions in some heat transfer loops.
In some embodiments, it may be desirable for the inert gas to be compressed, or pressurized, or cooled, or any combination thereof before or during the transfer of inert gas into a heat transfer loop.
In some embodiments, it may be desirable for people in a structure or in the vicinity of potentially hazardous two-phase fluid, such as sulfur dioxide or ammonia, to wear proper personal protective equipment (PPE). In some embodiments, a potential advantage of some two-phase fluids, such as sulfur dioxide or ammonia, may be their detectability by scent and/or their ability to be removed or separated by available personal protective equipment due to, for example, their acidic or basic nature or their reactivity.
In some embodiments, installation may comprise: (1) transferring at least a portion of two-phase fluid into a heat transfer loop and/or pressurizing the heat transfer loop to a pressure greater than the atmospheric pressure or ambient pressure. At least a portion of the two-phase fluid may comprise at a liquid phase while at least a portion of the inert gas may comprise a gas phase. (2) At least a portion of inert gas may be removed by or during, for example, displacement, or transfer, or circulation, or any combination thereof by, for example, including, but not limited to, one or more or any combination of the following: an automatic air remover, or an automatic gas remover, or in-line gas remover, or a gas-liquid separator, or an in-line gas-liquid separator, or any combination thereof. In some embodiments, at least a portion of two-phase fluid vapor may be at least partially present in the inert gas and/or may be separated, or recovered, or removed, or any combination thereof by systems or methods for separating, or recovering, or removing, or any combination thereof the applicable two-phase fluid. In some embodiments, it may be desirable to depressurize the heat transfer loop when the heat transfer loop is at least partially occupied by an inert gas or air. In some embodiments, it may be desirable to depressurize the heat transfer loop to about the same as or near atmospheric pressure when the heat transfer loop is at least partially occupied by an inert gas or air.
In some embodiments, depressurization may reduce any hazards associated with maintenance, or updates, or modifications, or adjustments, or other potential human or robotic or other interactions or interfaces, or any combination thereof with a heat transfer loop.
In some embodiments, a fluid comprising sulfur dioxide may be considered, including, but not limited to, one or more or any combination of the following non-flammable or low flammability. In some embodiments, it may be desirable to reduce potential contact of sulfur dioxide with water in the presence of metals or other materials which may be potentially susceptible to corrosion or reaction in the presence of sulfur dioxide and/or water.
In some embodiments, air, or dry air, or air with at least a portion of water vapor removed or air with a water vapor pressure concentration less than 1 vol %, or air with a water vapor pressure concentration less than 3 vol %, or air with a water vapor pressure concentration less than 5 vol %, or any combination thereof may be employed as or may comprise an inert gas.
In some embodiments, for example embodiments employing low flammability or non-flammable two phase fluid, air, or dry air, or air with at least a portion of water vapor removed or air with a water vapor pressure concentration less than 1 vol %, or air with a water vapor pressure concentration less than 3 vol %, or air with a water vapor pressure concentration less than 5 vol %, or any combination thereof may be employed as or may comprise an inert gas.
In some embodiments, a fluid comprising ammonia may be considered, including, but not limited to, one or more or any combination of the following: low flammability, or medium flammability, or low flammability risk in the operating environment, or any combination thereof. In some embodiments, it may be desirable to reduce potential contact of ammonia with water in the presence of metals or other materials which may be potentially susceptible to corrosion or reaction in the presence of ammonia and/or water.
In some embodiments, a fluid comprising sulfur dioxide, if released into the environment, which may occur accidentally, or incidentally, or due to a leak, may potentially cool the climate or may comprise the opposite of a greenhouse gas.
In some embodiments, at least a portion of a fluid comprising two phase fluid may be allowed to boil or phase transition from a liquid into a gas to, for example, increase the volume from the formation of a gas phase to, for example, displace or release at least a portion of two phase fluid from a heat transfer loop to, for example, enable sufficient volume of the heat transfer loop occupied by gas to enable gas-liquid phase transition heat transfer operation in the heat transfer loop.
   Example Simplified Step-by-Step Descriptions of the Installation and/or Removal of Two Phase Fluid Wherein the Example Two Phase Fluid Comprises n-Pentane, the Example at Least Partially Insoluble Fluid Comprises Water, and the Example Inert Gas Comprises Nitrogen Gas

Example installation of a two phase fluid wherein the example two phase fluid comprises n-Pentane and the example at least partially insoluble fluid comprises water.

(1) Displacing Gas with Water: Water may be pumped or otherwise transferred into a heat transfer loop, displacing at least a portion of the gas in the heat transfer loop from the heat transfer loop. The gas may comprise, for example, an inert gas, or air, or any combination thereof. The water may be circulated through the heat transfer loop to recover or remove or flush out residual gas from the heat transfer loop. In some embodiments, at least a portion of gas may be separated from the water by an automatic air removal or an automatic gas removal, which may be present or employed in a flow line or pipe and/or in a flow line or pipe carrying water exiting the heat transfer loop, or circulating within the heat transfer loop, or any combination thereof. In some embodiments, the circulation or pumping or transfer of water to, for example, remove gas, may be paused when a desired amount of gas has been removed from the heat transfer loop or when the heat transfer loop contains a sufficiently low presence or proportion or amount of gas.

(2) Displacing Water with n-Pentane: n-Pentane may be pumped or otherwise transferred into a heat transfer loop, displacing at least a portion of the water in the heat transfer loop from the heat transfer loop. The n-Pentane pumped or otherwise transferred into the heat transfer loop may comprise liquid phase n-Pentane. The n-Pentane may be circulated through the heat transfer loop to recover or remove or flush out residual water from the heat transfer loop. In some embodiments, at least a portion of water may be separated from the two-phase fluid by a liquid-liquid separation, such as a gravity separation, or a decanter, or coalescer, or a centrifuge. In some embodiments, the circulation or pumping or transfer of two-phase fluid to, for example, remove water, may be paused when a desired amount of water has been removed from the heat transfer loop or when the heat transfer loop contains a sufficiently low presence or proportion or amount of water.

Example deinstallation or removal of a two-phase fluid wherein the example two phase fluid comprises n-Pentane, the example at least partially insoluble fluid comprises water, and the example inert gas comprises nitrogen.

(1) Condensing or Separating or Recovering any Gas Phase n-Pentane in the Heat Transfer Loop: In some embodiments, at least a portion of any n-Pentane at a gas phase in the heat transfer loop may be condensed to a liquid phase, or gas phase separated from liquid phase, or any combination thereof, by, for example, including, but not limited, one or more or any combination of the following: cooling to at or below boiling point, or pumping or transferring in more n-Pentane, or increasing the total mass of n-Pentane in the heat transfer loop, or pumping or transferring in water, or cooling, or reducing volume, or gas-liquid separation.

(2) Displacing n-Pentane with Water: Water may be pumped or otherwise transferred into a heat transfer loop, displacing at least a portion of the n-Pentane in the heat transfer loop from the heat transfer loop. The water may be circulated through the heat transfer loop to recover or remove or flush out residual n-Pentane from the heat transfer loop. In some embodiments, at least a portion of the two phase fluid may be separated from the n-Pentane by a liquid-liquid separation, such as a gravity separation, or a decanter, or coalescer, or a centrifuge. In some embodiments, the circulation or pumping or transfer of water to, for example, remove n-Pentane, may be paused when a desired amount of n-Pentane has been removed from the heat transfer loop or when the heat transfer loop contains a sufficiently low presence or proportion or amount of n-Pentane.

(3) Displacing Water with Nitrogen Gas: Nitrogen gas may be pumped or otherwise transferred into a heat transfer loop, displacing at least a portion of the water in the heat transfer loop from the heat transfer loop. The nitrogen gas may be circulated or purged through the heat transfer loop to recover or remove or flush out or evaporate residual water from the heat transfer loop. In some embodiments, the nitrogen gas may be exhausted. In some embodiments, the nitrogen gas may be recirculated. In some embodiments, at least a portion of the water may be separated from the nitrogen gas. In some embodiments, the circulation or pumping or transferring or purging of the nitrogen gas to, for example, remove water, may be paused when a desired amount of water has been removed from the heat transfer loop, or when the heat transfer loop contains a sufficiently low presence or proportion or amount of water, or when the concentration of water in the nitrogen gas is less than a threshold or a desired concentration.

Example Simplified Step-by-Step Descriptions of the Installation and/or Removal of Two Phase Fluid Wherein the Example Two Phase Fluid Comprises a Hydrofluoroether, the Example at Least Partially Insoluble Fluid Comprises Water, and the Example Inert Gas Comprises Air

Example installation of a two phase fluid wherein the example two phase fluid comprises Hydrofluoroether and the example at least partially insoluble fluid comprises water.

(1) Displacing Gas with Water: Water may be pumped or otherwise transferred into a heat transfer loop, displacing at least a portion of the gas in the heat transfer loop from the heat transfer loop. The gas may comprise, for example, an inert gas, or air, or any combination thereof. The water may be circulated through the heat transfer loop to recover or remove or flush out residual gas from the heat transfer loop. In some embodiments, at least a portion of gas may be separated from the water by an automatic air removal or an automatic gas removal, which may be present or employed in a flow line or pipe and/or in a flow line or pipe carrying water exiting the heat transfer loop, or circulating within the heat transfer loop, or any combination thereof. In some embodiments, the circulation or pumping or transfer of water to, for example, remove gas, may be paused when a desired amount of gas has been removed from the heat transfer loop or when the heat transfer loop contains a sufficiently low presence or proportion or amount of gas.

(2) Displacing Water with Hydrofluoroether: A hydrofluoroether may be pumped or otherwise transferred into a heat transfer loop, displacing at least a portion of the water in the heat transfer loop from the heat transfer loop. The Hydrofluoroether pumped or otherwise transferred into the heat transfer loop may comprise liquid phase Hydrofluoroether. The Hydrofluoroether may be circulated through the heat transfer loop to recover or remove or flush out residual water from the heat transfer loop. In some embodiments, at least a portion of water may be separated from the two-phase fluid by a liquid-liquid separation, such as a gravity separation, or a decanter, or coalescer, or a centrifuge. In some embodiments, the circulation or pumping or transfer of two-phase fluid to, for example, remove water, may be paused when a desired amount of water has been removed from the heat transfer loop or when the heat transfer loop contains a sufficiently low presence or proportion or amount of water.

Example deinstallation or removal of a two-phase fluid wherein the example two phase fluid comprises hydrofluoroether, the example at least partially insoluble fluid comprises water, and the example inert gas comprises air.

(1) Condensing or Separating or Recovering any Gas Phase Hydrofluoroether in the Heat Transfer Loop: In some embodiments, at least a portion of any Hydrofluoroether at a gas phase in the heat transfer loop may be condensed to a liquid phase, or gas phase separated from liquid phase, or any combination thereof, by, for example, including, but not limited, one or more or any combination of the following: cooling to at or below boiling point, or pumping or transferring in more Hydrofluoroether, or increasing the total mass of Hydrofluoroether in the heat transfer loop, or pumping or transferring in water, or cooling, or reducing volume, or gas-liquid separation.

(2) Displacing Hydrofluoroether with Water: Water may be pumped or otherwise transferred into a heat transfer loop, displacing at least a portion of the Hydrofluoroether in the heat transfer loop from the heat transfer loop. The water may be circulated through the heat transfer loop to recover or remove or flush out residual Hydrofluoroether from the heat transfer loop. In some embodiments, at least a portion of the two phase fluid may be separated from the Hydrofluoroether by a liquid-liquid separation, such as a gravity separation, or a decanter, or coalescer, or a centrifuge. In some embodiments, the circulation or pumping or transfer of water to, for example, remove Hydrofluoroether, may be paused when a desired amount of Hydrofluoroether has been removed from the heat transfer loop or when the heat transfer loop contains a sufficiently low presence or proportion or amount of Hydrofluoroether.

(3) Displacing Water with Air: Air may be pumped or otherwise transferred into a heat transfer loop, displacing at least a portion of the water in the heat transfer loop from the heat transfer loop. The air may be circulated or purged through the heat transfer loop to recover or remove or flush out or evaporate residual water from the heat transfer loop. In some embodiments, the air may be exhausted. In some embodiments, the air may be recirculated. In some embodiments, at least a portion of the water may be separated from the air. In some embodiments, the circulation or pumping or transferring or purging of the air to, for example, remove water, may be paused when a desired amount of water has been removed from the heat transfer loop, or when the heat transfer loop contains a sufficiently low presence or proportion or amount of water, or when the concentration of water in the air is less than a threshold or a desired concentration.

Example Simplified Step-by-Step Descriptions of the Installation and/or Removal of Two Phase Fluid Wherein the Example Two Phase Fluid Comprises Ammonia, the Example at Least Partially Insoluble Fluid Comprises an Oil, and the Example Inert Gas Comprises Nitrogen Gas

Example installation of a two phase fluid wherein the example two phase fluid comprises ammonia and the example at least partially insoluble fluid comprises an oil, which may include, but is not limited to, one or more or any combination of the following: mineral oil (MO), polyalphaolefine (PAO) and alkyl benzene (AB).

(1) Displacing Gas with Oil: A fluid comprising oil may be pumped or otherwise transferred into a heat transfer loop, displacing at least a portion of the gas in the heat transfer loop from the heat transfer loop. The gas may comprise, for example, an inert gas, or air, or any combination thereof. The oil may be circulated through the heat transfer loop to recover or remove or flush out residual gas from the heat transfer loop. In some embodiments, at least a portion of gas may be separated from the oil by an automatic air removal or an automatic gas removal, which may be present or employed in a flow line or pipe and/or in a flow line or pipe carrying oil exiting the heat transfer loop, or circulating within the heat transfer loop, or any combination thereof. In some embodiments, the circulation or pumping or transfer of oil to, for example, remove gas, may be paused when a desired amount of gas has been removed from the heat transfer loop or when the heat transfer loop contains a sufficiently low presence or proportion or amount of gas.

(2) Displacing Oil with Ammonia: A two phase fluid comprising ammonia may be pumped or otherwise transferred into a heat transfer loop, displacing at least a portion of the oil in the heat transfer loop from the heat transfer loop. The ammonia pumped or otherwise transferred into the heat transfer loop may comprise liquid phase ammonia. The ammonia may be circulated through the heat transfer loop to recover or remove or flush out residual oil from the heat transfer loop. In some embodiments, at least a portion of oil may be separated from the two-phase fluid by a liquid-liquid separation, such as a gravity separation, or a decanter, or coalescer, or a centrifuge. In some embodiments, the circulation or pumping or transfer of two-phase fluid to, for example, remove oil, may be paused when a desired amount of oil has been removed from the heat transfer loop or when the heat transfer loop contains a sufficiently low presence or proportion or amount of oil.

Example deinstallation or removal of a two-phase fluid wherein the example two phase fluid comprises ammonia, the example at least partially insoluble fluid comprises oil, and the example inert gas comprises nitrogen.

(1) Condensing or Separating or Recovering any Gas Phase Ammonia in the Heat Transfer Loop: In some embodiments, at least a portion of any ammonia at a gas phase in the heat transfer loop may be separated, or removed, or recovered, or condensed to a liquid phase, or gas phase separated from liquid phase, or any combination thereof, by, for example, including, but not limited, one or more or any combination of the following: cooling to at or below boiling point, or pumping or transferring in more ammonia, or increasing the total mass of ammonia in the heat transfer loop, or pumping or transferring in oil, or cooling, or reducing volume, or gas-liquid separation.

(2) Displacing Ammonia with Oil: Oil may be pumped or otherwise transferred into a heat transfer loop, displacing at least a portion of the ammonia in the heat transfer loop from the heat transfer loop. The oil may be circulated through the heat transfer loop to recover or remove or flush out residual ammonia from the heat transfer loop. In some embodiments, at least a portion of the two phase fluid may be separated from the ammonia by a liquid-liquid separation, such as a gravity separation, or a decanter, or coalescer, or a centrifuge. In some embodiments, the circulation or pumping or transfer of oil to, for example, remove ammonia, may be paused when a desired amount of ammonia has been removed from the heat transfer loop or when the heat transfer loop contains a sufficiently low presence or proportion or amount of ammonia.

(3) Displacing Oil with Nitrogen Gas: Nitrogen gas may be pumped or otherwise transferred into a heat transfer loop, displacing at least a portion of the oil in the heat transfer loop from the heat transfer loop. The nitrogen gas may be circulated or purged through the heat transfer loop to recover or remove or flush out or evaporate residual oil from the heat transfer loop. In some embodiments, the nitrogen gas may be exhausted. In some embodiments, the nitrogen gas may be recirculated. In some embodiments, at least a portion of the oil may be separated from the nitrogen gas. In some embodiments, the circulation or pumping or transferring or purging of the nitrogen gas to, for example, remove oil, may be paused when a desired amount of oil has been removed from the heat transfer loop, or when the heat transfer loop contains a sufficiently low presence or proportion or amount of oil, or when the concentration of oil in the nitrogen gas is less than a threshold or a desired concentration.

Example Simplified Step-by-Step Descriptions the of Installation and/or Removal of Two Phase Fluid Wherein the Example Two Phase Fluid Comprises Sulfur Dioxide, the Example at Least Partially Insoluble Fluid Comprises an Oil or Hydrocarbon, and the Example Inert Gas Comprises Air Gas

Example installation of a two phase fluid wherein the example two phase fluid comprises sulfur dioxide and the example at least partially insoluble fluid comprises an oil, which may include, but is not limited to, one or more or any combination of the following: mineral oil (MO), polyalphaolefine (PAO) and alkyl benzene (AB).

(1) Displacing Gas with Oil: Oil may be pumped or otherwise transferred into a heat transfer loop, displacing at least a portion of the gas in the heat transfer loop from the heat transfer loop. The gas may comprise, for example, an inert gas, or air, or any combination thereof. The oil may be circulated through the heat transfer loop to recover or remove or flush out residual gas from the heat transfer loop. In some embodiments, at least a portion of gas may be separated from the oil by an automatic air removal or an automatic gas removal, which may be present or employed in a flow line or pipe and/or in a flow line or pipe carrying oil exiting the heat transfer loop, or circulating within the heat transfer loop, or any combination thereof. In some embodiments, the circulation or pumping or transfer of oil to, for example, remove gas, may be paused when a desired amount of gas has been removed from the heat transfer loop or when the heat transfer loop contains a sufficiently low presence or proportion or amount of gas.

(2) Displacing Oil with Sulfur dioxide: sulfur dioxide may be pumped or otherwise transferred into a heat transfer loop, displacing at least a portion of the oil in the heat transfer loop from the heat transfer loop. The sulfur dioxide pumped or otherwise transferred into the heat transfer loop may comprise liquid phase sulfur dioxide. The sulfur dioxide may be circulated through the heat transfer loop to recover or remove or flush out residual oil from the heat transfer loop. In some embodiments, at least a portion of oil may be separated from the two-phase fluid by a liquid-liquid separation, such as a gravity separation, or a decanter, or coalescer, or a centrifuge. In some embodiments, the circulation or pumping or transfer of two-phase fluid to, for example, remove oil, may be paused when a desired amount of oil has been removed from the heat transfer loop or when the heat transfer loop contains a sufficiently low presence or proportion or amount of oil.

Example deinstallation or removal of a two-phase fluid wherein the example two phase fluid comprises sulfur dioxide, the example at least partially insoluble fluid comprises oil, and the example inert gas comprises air.

(1) Condensing or Separating or Recovering any Gas Phase Sulfur Dioxide in the Heat Transfer Loop: In some embodiments, a portion of any sulfur dioxide at a gas phase or vapor phase in the heat transfer loop may be separated, or removed, or recovered, or condensed to a liquid phase, or gas phase separated from liquid phase, or any combination thereof, by, for example, including, but not limited, one or more or any combination of the following: cooling to at or below boiling point, or pumping or transferring in more sulfur dioxide, or increasing the total mass of sulfur dioxide in the heat transfer loop, or pumping or transferring in oil, or cooling, or reducing volume, or gas-liquid separation.

(2) Displacing Sulfur dioxide with Oil: Oil may be pumped or otherwise transferred into a heat transfer loop, displacing at least a portion of the sulfur dioxide in the heat transfer loop from the heat transfer loop. The oil may be circulated through the heat transfer loop to recover or remove or flush out residual sulfur dioxide from the heat transfer loop. In some embodiments, at least a portion of the oil may be separated from the sulfur dioxide by a liquid-liquid separation, such as a gravity separation, or a decanter, or coalescer, or a centrifuge. In some embodiments, the circulation or pumping or transfer of oil to, for example, remove sulfur dioxide, may be paused when a desired amount of sulfur dioxide has been removed from the heat transfer loop or when the heat transfer loop contains a sufficiently low presence or proportion or amount of sulfur dioxide.

(3) Displacing Oil with Air Gas: Air gas may be pumped or otherwise transferred into a heat transfer loop, displacing at least a portion of the oil in the heat transfer loop from the heat transfer loop. The air gas may be circulated or purged through the heat transfer loop to recover or remove or flush out or evaporate residual oil from the heat transfer loop. In some embodiments, the air gas may be exhausted. In some embodiments, the Air gas may be recirculated. In some embodiments, at least a portion of the oil may be separated from the air gas. In some embodiments, the circulation or pumping or transferring or purging of the air gas to, for example, remove oil, may be paused when a desired amount of oil has been removed from the heat transfer loop, or when the heat transfer loop contains a sufficiently low presence or proportion or amount of oil, or when the concentration of oil in the air gas is less than a threshold or a desired concentration.

Example Simplified Step-by-Step Descriptions of the Installation and/or Removal of Two Phase Fluid Wherein the Example Two Phase Fluid Comprises Carbon Dioxide, the Example at Least Partially Insoluble Fluid Comprises Water, and the Example Inert Gas Comprises Air Gas

Example installation of a two phase fluid wherein the example two phase fluid comprises carbon dioxide and the example at least partially insoluble fluid comprises water.

(1) Displacing Gas with Water: Water may be pumped or otherwise transferred into a heat transfer loop, displacing at least a portion of the gas in the heat transfer loop from the heat transfer loop. The gas may comprise, for example, an inert gas, or air, or any combination thereof. The water may be circulated through the heat transfer loop to recover or remove or flush out residual gas from the heat transfer loop. In some embodiments, at least a portion of gas may be separated from the water by an automatic air removal or an automatic gas removal, which may be present or employed in a flow line or pipe and/or in a flow line or pipe carrying water exiting the heat transfer loop, or circulating within the heat transfer loop, or any combination thereof. In some embodiments, the circulation or pumping or transfer of water to, for example, remove gas, may be paused when a desired amount of gas has been removed from the heat transfer loop or when the heat transfer loop contains a sufficiently low presence or proportion or amount of gas.

(2) Displacing Water with Carbon dioxide: Carbon dioxide may be pumped or otherwise transferred into a heat transfer loop, displacing at least a portion of the water in the heat transfer loop from the heat transfer loop. The carbon dioxide pumped or otherwise transferred into the heat transfer loop may comprise liquid phase carbon dioxide. The carbon dioxide may be circulated through the heat transfer loop to recover or remove or flush out residual water from the heat transfer loop. In some embodiments, at least a portion of water may be separated from the two-phase fluid by a liquid-liquid separation, such as a gravity separation, or a decanter, or coalescer, or a centrifuge. In some embodiments, the circulation or pumping or transfer of two-phase fluid to, for example, remove water, may be paused when a desired amount of water has been removed from the heat transfer loop or when the heat transfer loop contains a sufficiently low presence or proportion or amount of water.

Example deinstallation or removal of a two-phase fluid wherein the example two phase fluid comprises carbon dioxide, the example at least partially insoluble fluid comprises water, and the example inert gas comprises air.

(1) Condensing or Separating or Recovering any Gas Phase Carbon Dioxide in the Heat Transfer Loop: In some embodiments, at least a portion of any carbon dioxide at a gas phase in the heat transfer loop may be condensed to a liquid phase, or gas phase separated from liquid phase, or any combination thereof, by, for example, including, but not limited, one or more or any combination of the following: cooling to at or below watering point, or pumping or transferring in more carbon dioxide, or increasing the total mass of carbon dioxide in the heat transfer loop, or pumping or transferring in water, or cooling, or reducing volume, or gas-liquid separation.

(2) Displacing Carbon Dioxide with Water: Water may be pumped or otherwise transferred into a heat transfer loop, displacing at least a portion of the carbon dioxide in the heat transfer loop from the heat transfer loop. The water may be circulated through the heat transfer loop to recover or remove or flush out residual carbon dioxide from the heat transfer loop. In some embodiments, at least a portion of the two phase fluid may be separated from the carbon dioxide by a liquid-liquid separation, such as a gravity separation, or a decanter, or coalescer, or a centrifuge. In some embodiments, the circulation or pumping or transfer of water to, for example, remove carbon dioxide, may be paused when a desired amount of carbon dioxide has been removed from the heat transfer loop or when the heat transfer loop contains a sufficiently low presence or proportion or amount of carbon dioxide.

(3) Displacing Water with Air Gas: Air gas may be pumped or otherwise transferred into a heat transfer loop, displacing at least a portion of the water in the heat transfer loop from the heat transfer loop. The air gas may be circulated or purged through the heat transfer loop to recover or remove or flush out or evaporate residual water from the heat transfer loop. In some embodiments, the air gas may be exhausted. In some embodiments, the Air gas may be recirculated. In some embodiments, at least a portion of the water may be separated from the air gas. In some embodiments, the circulation or pumping or transferring or purging of the air gas to, for example, remove water, may be paused when a desired amount of water has been removed from the heat transfer loop, or when the heat transfer loop contains a sufficiently low presence or proportion or amount of water, or when the concentration of water in the air gas is less than a threshold or a desired concentration.

Example Simplified Step-by-Step Descriptions of the Installation and/or Removal of Two Phase Fluid Wherein the Example Two Phase Fluid Comprises a Refrigerant Blend, the Example at Least Partially Insoluble Fluid Comprises Water, and the Example Inert Gas Comprises Air Gas

Example installation of a two phase fluid wherein the example two phase fluid comprises refrigerant blend and the example at least partially insoluble fluid comprises water.

(1) Displacing Gas with Water: A fluid comprising water may be pumped or otherwise transferred into a heat transfer loop, displacing at least a portion of the gas in the heat transfer loop from the heat transfer loop. The gas may comprise, for example, an inert gas, or air, or any combination thereof. The water may be circulated through the heat transfer loop to recover or remove or flush out residual gas from the heat transfer loop. In some embodiments, at least a portion of gas may be separated from the water by an automatic air removal or an automatic gas removal, which may be present or employed in a flow line or pipe and/or in a flow line or pipe carrying water exiting the heat transfer loop, or circulating within the heat transfer loop, or any combination thereof. In some embodiments, the circulation or pumping or transfer of water to, for example, remove gas, may be paused when a desired amount of gas has been removed from the heat transfer loop or when the heat transfer loop contains a sufficiently low presence or proportion or amount of gas.

(2) Displacing Water with Refrigerant Blend: A fluid comprising a refrigerant blend may be pumped or otherwise transferred into a heat transfer loop, displacing at least a portion of the water in the heat transfer loop from the heat transfer loop. The refrigerant blend pumped or otherwise transferred into the heat transfer loop may comprise liquid phase refrigerant blend. The refrigerant blend may be circulated through the heat transfer loop to recover or remove or flush out residual water from the heat transfer loop. In some embodiments, at least a portion of water may be separated from the two-phase fluid by a liquid-liquid separation, such as a gravity separation, or a decanter, or coalescer, or a centrifuge. In some embodiments, the circulation or pumping or transfer of two-phase fluid to, for example, remove water, may be paused when a desired amount of water has been removed from the heat transfer loop or when the heat transfer loop contains a sufficiently low presence or proportion or amount of water.

Example deinstallation or removal of a two-phase fluid wherein the example two phase fluid comprises a refrigerant blend, the example at least partially insoluble fluid comprises water, and the example inert gas comprises air.

(1) Condensing or Separating or Recovering any Gas Phase Refrigerant blend in the Heat Transfer Loop: In some embodiments, at least a portion of a refrigerant blend at a gas phase in the heat transfer loop may be condensed to a liquid phase, or gas phase separated from liquid phase, or any combination thereof, by, for example, including, but not limited, one or more or any combination of the following: cooling to about the same as or less than a boiling point, or pumping or transferring in additional fluid comprising refrigerant blend into the heat transfer loop, or increasing the total mass of refrigerant blend in the heat transfer loop, or pumping or transferring in water, or cooling, or reducing volume, or gas-liquid separation.

(2) Displacing Refrigerant Blend with Water: Water may be pumped or otherwise transferred into a heat transfer loop, displacing at least a portion of the refrigerant blend in the heat transfer loop from the heat transfer loop. The water may be circulated through the heat transfer loop to recover or remove or flush out residual refrigerant blend from the heat transfer loop. In some embodiments, at least a portion of the two-phase fluid may be separated from the refrigerant blend by a liquid-liquid separation, such as a gravity separation, or a decanter, or coalescer, or a centrifuge. In some embodiments, the circulation or pumping or transfer of water to, for example, remove refrigerant blend, may be paused when a desired amount of refrigerant blend has been removed from the heat transfer loop or when the heat transfer loop contains a sufficiently low presence or proportion or amount of refrigerant blend.

(3) Displacing Water with Air Gas: Air gas may be pumped or otherwise transferred into a heat transfer loop, displacing at least a portion of the water in the heat transfer loop from the heat transfer loop. The air gas may be circulated or purged through the heat transfer loop to recover or remove or flush out or evaporate residual water from the heat transfer loop. In some embodiments, the air gas may be exhausted. In some embodiments, the Air gas may be recirculated. In some embodiments, at least a portion of the water may be separated from the air gas. In some embodiments, the circulation or pumping or transferring or purging of the air gas to, for example, remove water, may be paused when a desired amount of water has been removed from the heat transfer loop, or when the heat transfer loop contains a sufficiently low presence or proportion or amount of water, or when the concentration of water in the air gas is less than a threshold or a desired concentration.

### DETAILED FIGURE DESCRIPTIONS

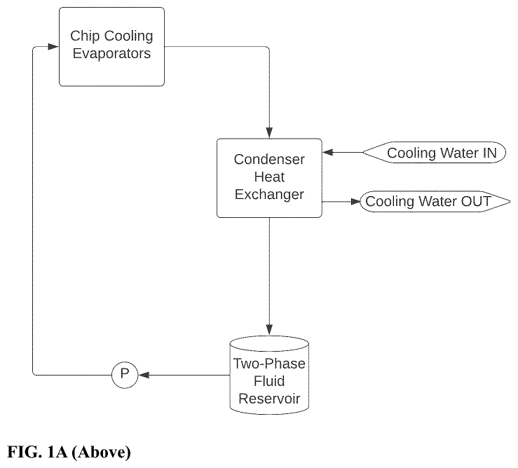

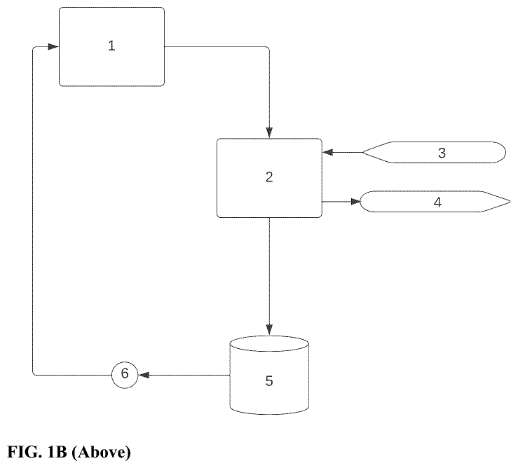

### FIG. 1A, 1B

### Example FIG. 1A, 1B Summary

### FIG. 1A Summary:

FIG. 1A may comprise a simplified figure embodiment with written labels. FIG. 1A may show a process operating in a heat transfer mode, wherein, for example, two phase fluid may be transferred between a heat exchanger cooling a heat source, such as a coldplate and/or GPU, and a heat exchanger removing heat from the two phase fluid or a heat sink heat exchanger, such as a CDU or fluid distribution unit or condenser heat exchanger.

### FIG. 1B Summary:

FIG. 1B may comprise a simplified figure embodiment with numbered labels. FIG. 1B may show a process operating in a heat transfer mode, wherein, for example, two phase fluid may be transferred between a heat exchanger cooling a heat source, such as a coldplate and/or GPU, and a heat exchanger removing heat from the two phase fluid or a heat sink heat exchanger, such as a CDU or fluid distribution unit or condenser heat exchanger.

### Example FIG. 1A, 1B Key

Example FIG. 1A, 1B Key

| ID | Description |
|---|---|
| 1 | ‘1’ may comprise a cold plate. ‘1’ may comprise a two-phase cold plate. ‘1’ may |
| | comprise a heat exchanger. ‘1’ may comprise a heat exchanger which may absorb or |
| | remove a portion of heat from a heat source, such as an electronic device, or a computer |
| | chip, or GPU, or CPU, or memory, or a high power electronic, or high power device, or |
| | any combination thereof. In some embodiments, a fluid comprising a two phase fluid |
| | may be transferred into ‘1’ as, for example, a portion of fluid comprising a liquid phase, |
| | and/or may be transferred out of ‘1’ as a portion of a fluid comprising a gas phase, or a |
| | super-heated phase, or any combination thereof. ‘1’ may comprise direct fluid cooling |
| | or heat transfer heat exchangers, or series of cold plate, or parallel cold plates, or series |
| | cold plates, or configured cold plates, or electronic heat exchanger system, or a fluid |
| | distribution system, or any combination thereof. |
| | In some embodiments, ‘1’ may be at least partially or temporarily compatible with an |
| | at least partially insoluble liquid, or water, or air, or an inert gas, or any combination |
| | thereof. In some embodiments, ‘1’ may be at least partially or temporarily compatible |
| | with an at least partially insoluble liquid, or water, or air, or an inert gas, or any |
| | combination thereof, which may enable the installation and/or deinstallation of a two |
| | phase fluid by, for example, fluid displacement and/or flushing. |
| 2 | ‘2’ may comprise a heat sink, or a heat sink heat exchanger, or a heat exchanger, or any |
| | combination thereof. ‘2’ may comprise a condenser heat exchanger. In some |
| | embodiments, a fluid comprising a two phase fluid may be transferred into ‘2’ as, for |
| | example, a portion of fluid comprising a gas or vapor phase, and/or may be transferred |
| | out of ‘2’ as a portion of a liquid phase. In some embodiments, a fluid may be passed |
| | through or transferred through ‘2’ and/or the fluid may comprise, for example, |
| | including, but not limited to, one or more or any combination of the following: chilled |
| | water, or a refrigerant, or air, or inert gas or a heat transfer fluid, or water, or glycol + |
| | water, or glycol, or methanol, or an organic solvent, or a two phase fluid, or a three |
| | phase fluid, or any combination thereof. |
| | In some embodiments, ‘2’ may be at least partially or temporarily compatible with an |
| | at least partially insoluble liquid, or water, or air, or an inert gas, or any combination |
| | thereof. In some embodiments, ‘2’ may be at least partially or temporarily compatible |
| | with an at least partially insoluble liquid, or water, or air, or an inert gas, or any |
| | combination thereof, which may enable the installation and/or deinstallation of a two |
| | phase fluid by, for example, fluid displacement and/or flushing |
| 3 | ‘3’ may comprise a heat transfer fluid. ‘3’ may comprise a coolant. ‘3’ may comprise a |
| | supply or ‘cold’ or any combination thereof coolant or heat transfer fluid. ‘3’ may |
| | comprise chilled water. ‘3’ may comprise chilled water supply. ‘3’ may comprise |
| | coolant supply, or supply heat transfer fluid, or any combination thereof which may be |
| | employed to remove or transfer or absorb a portion of heat from ‘2’. |
| 4 | ‘4’ may comprise a heat transfer fluid. ‘4’ may comprise a coolant. ‘4’ may comprise a |
| | return or ‘warm’ or any combination thereof coolant or heat transfer fluid. ‘4’ may |
| | comprise chilled water. ‘4’ may comprise chilled water return. ‘4’ may comprise coolant |
| | return, or return heat transfer fluid, or any combination thereof which may be employed |
| | to remove or transfer or absorb a portion of heat from ‘2’. |
| 5 | ‘5’ may comprise a storage reservoir, or buffer tank, or any combination thereof. ‘5’ |
| | may comprise a storage reservoir. ‘5’ may storage reservoir configured to store a portion |
| | of two phase fluid. ‘5’ may store a fluid comprising at least a portion of two phase fluid, |
| | which may comprise a liquid phase. In some embodiments, ‘5’ may store two phase |
| | fluid and/or at least partially insoluble liquid. In some embodiments, ‘5’ may store a |
| | fluid comprising two phase fluid. |
| 6 | ‘6’ may comprise a fluid pump. ‘6’ may comprise a two phase fluid pump. ‘6’ may |
| | comprise a circulation pump. ‘6’ may comprise a fluid pump which may be compatible |
| | with two phase fluid. ‘6’ may comprise a fluid pump which may be compatible with |
| | two phase fluid, or at least partially insoluble liquid, or any combination thereof. ‘6’ |
| | may comprise a fluid pump which may enable the bypass of a gas, or a gas removal, or |
| | the flow of a gas, or the circulation of a gas, or any combination thereof, for example, |
| | if an inert gas is transferred into, or out of, or any combination thereof the system, or |
| | heat transfer loop, or any combination thereof. |
| | In some embodiments, ‘6’ may be at least partially or temporarily compatible, or |
| | designed to handle or bypass, or any combination thereof with a fluid comprising an at |
| | least partially insoluble liquid, or water, or air, or an inert gas, or any combination |
| | thereof. In some embodiments, ‘6’ may be at least partially or temporarily compatible |
| | with a fluid comprising an at least partially insoluble liquid, or water, or air, or an inert |
| | gas, or any combination thereof, which may enable or facilitate the installation and/or |
| | deinstallation of a two phase fluid by, for example, fluid displacement and/or flushing. |

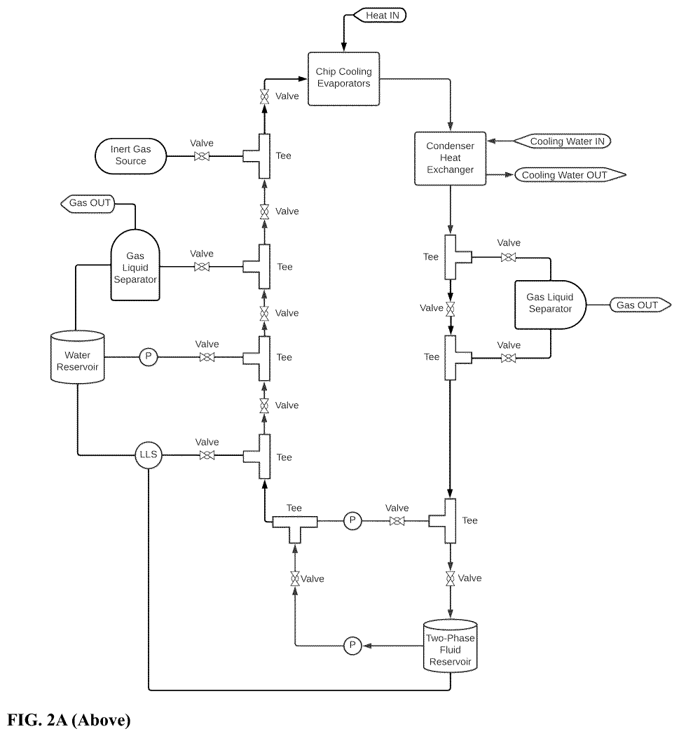

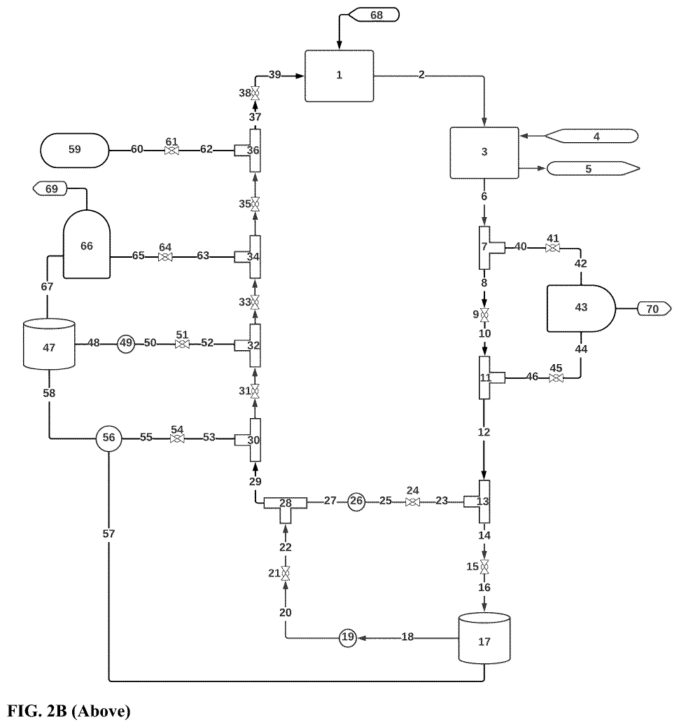

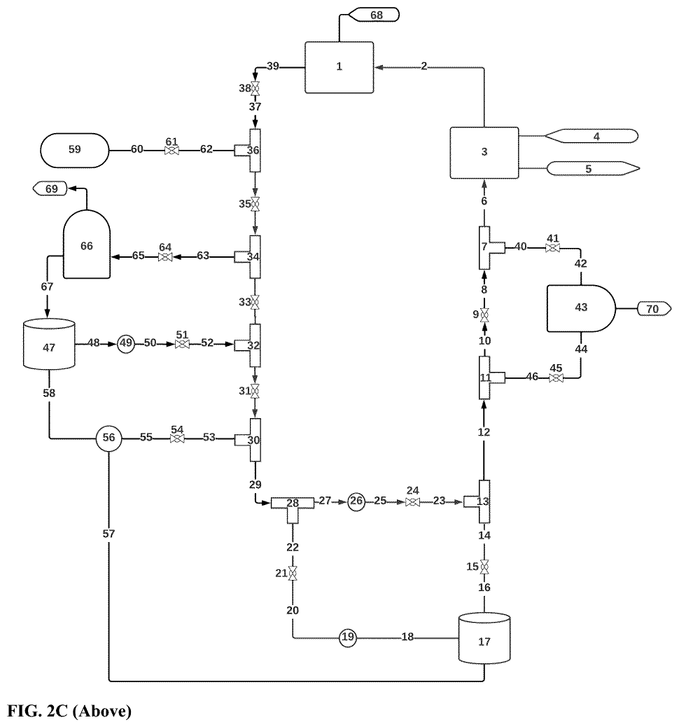

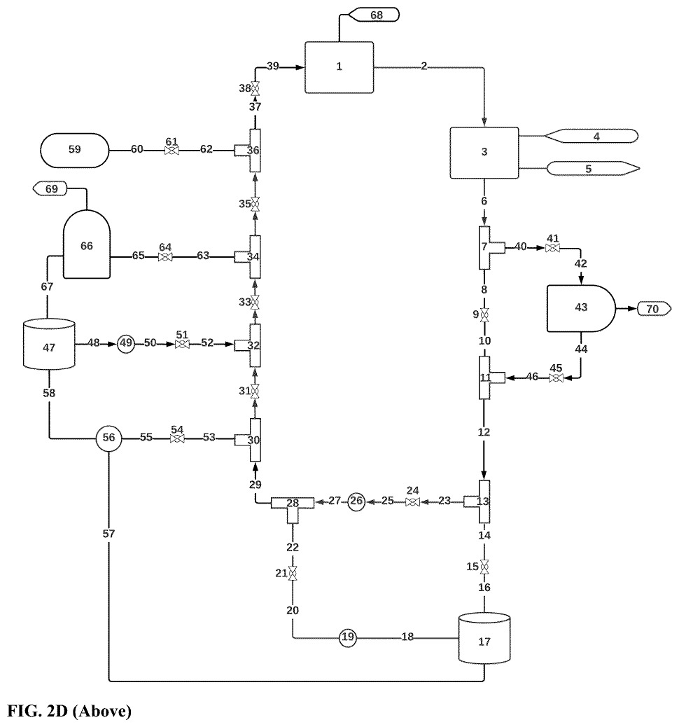

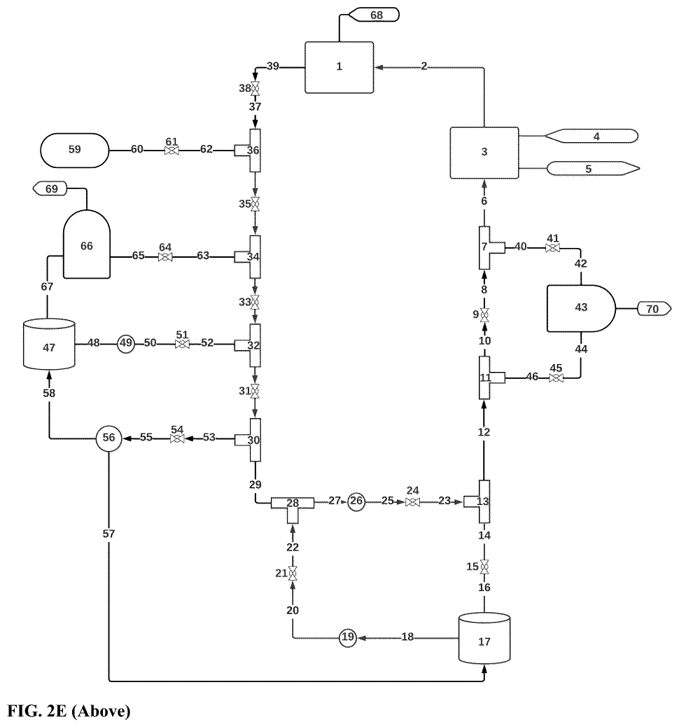

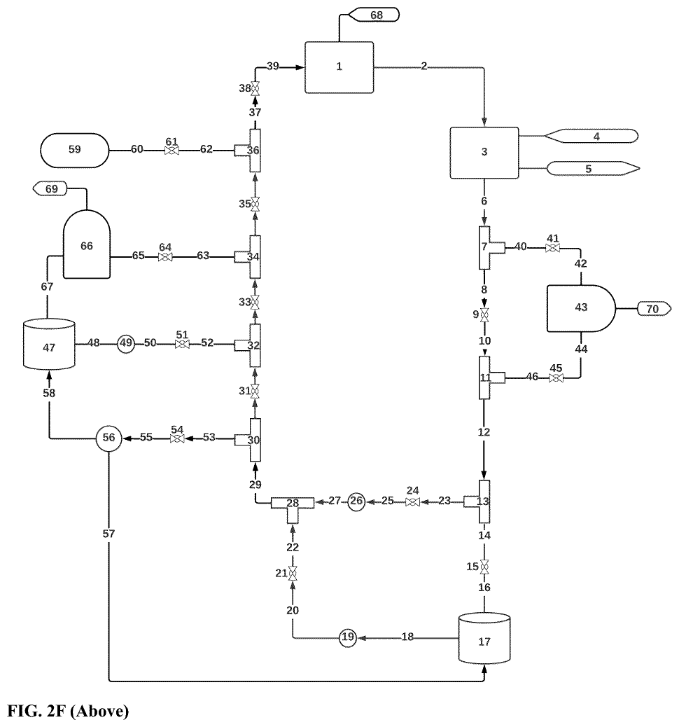

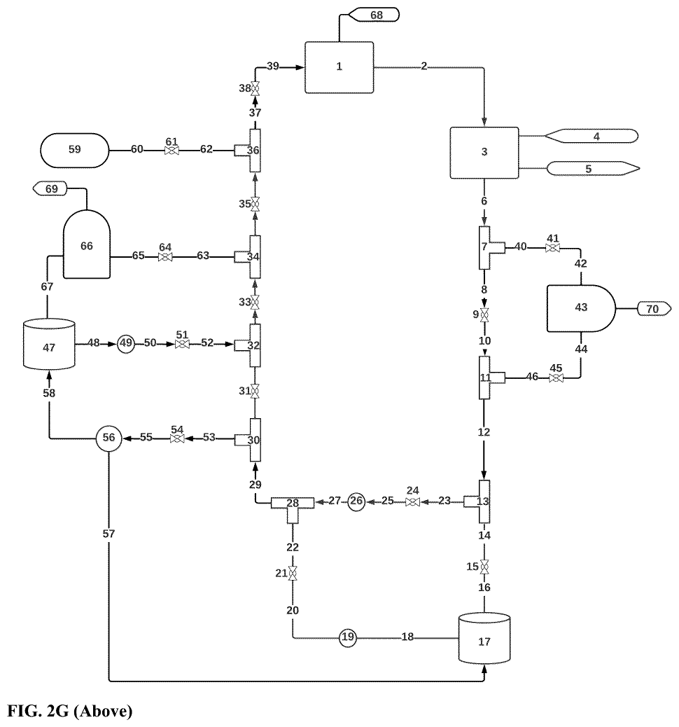

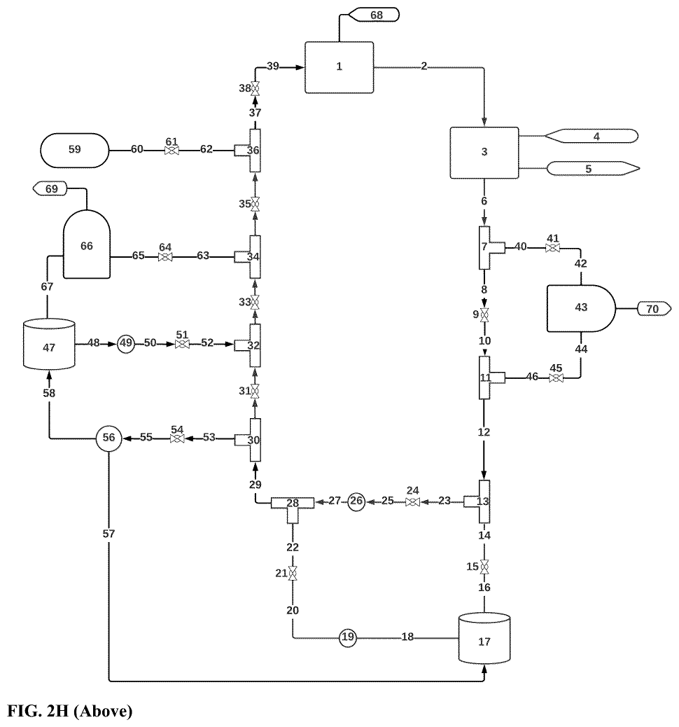

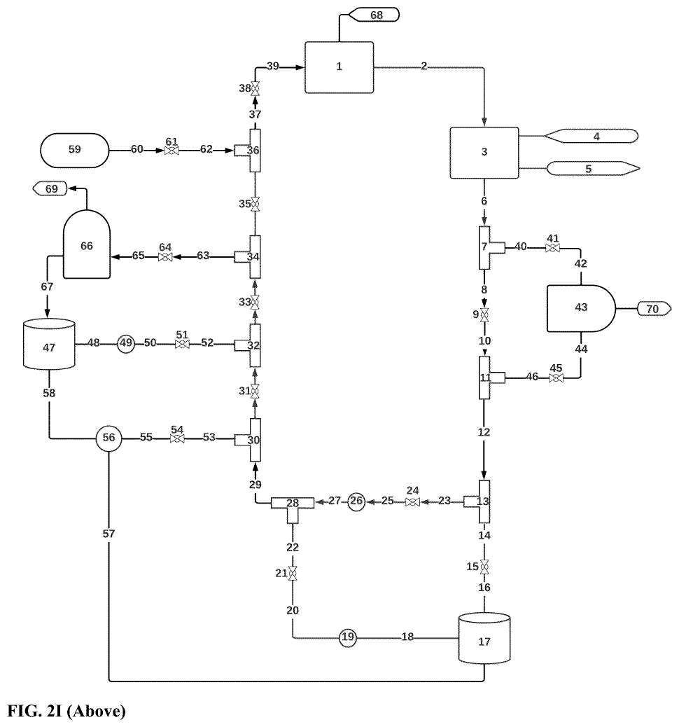

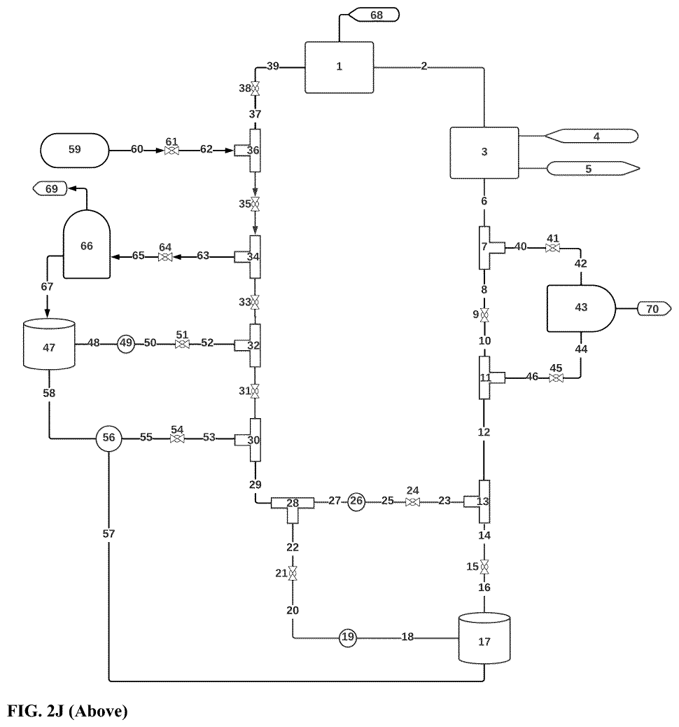

### FIG. 2

### Example FIG. 2A-2J Summary

### FIG. 2A Summary:

FIG. 2A may comprise a detailed figure embodiment with written labels. FIG. 2A may show a process operating in a heat transfer mode, wherein, for example, two phase fluid may be transferred between a heat exchanger cooling a heat source, such as a coldplate and/or GPU, and a heat exchanger removing heat from the two phase fluid or a heat sink heat exchanger, such as a CDU or fluid distribution unit or condenser heat exchanger.

### FIG. 2B Summary:

FIG. 2B may comprise a detailed figure embodiment with numbered labels. FIG. 2B may show a process operating in a heat transfer mode, wherein, for example, two phase fluid may be transferred between a heat exchanger cooling a heat source, such as a coldplate and/or GPU, and a heat exchanger removing heat from the two phase fluid or a heat sink heat exchanger, such as a CDU or fluid distribution unit or condenser heat exchanger.

### FIG. 2C Summary:

FIG. 2C may comprise a detailed figure embodiment with numbered labels. FIG. 2C may show a process displacing, or flushing out, or any combination thereof a gas, or an inert gas, or any combination thereof with an at least partially insoluble fluid. FIG. 2C may show a process bulk displacing, or displacing, or flushing out, or any combination thereof a gas, or an inert gas, or any combination thereof, such as a gas comprising nitrogen or air, with an at least partially insoluble fluid, such as a liquid comprising water.

### FIG. 2D Summary:

FIG. 2D may comprise a detailed figure embodiment with numbered labels. FIG. 2D may show a process displacing, or flushing out, or any combination thereof a gas, or an inert gas, or any combination thereof with an at least partially insoluble fluid. FIG. 2D may show a process displacing, or flushing out, or any combination thereof a gas, or an inert gas, or any combination thereof, such as a gas comprising nitrogen or air, with an at least partially insoluble fluid, such as a liquid comprising water. FIG. 2D may show a process displacing, or flushing out, or any combination thereof a portion of residual gas, or a residual inert gas, or any combination thereof, such as a gas comprising nitrogen or air, which may comprise separating a portion of gas from a portion of an least partially insoluble fluid, such as a liquid comprising water.

### FIG. 2E Summary:

FIG. 2E may comprise a detailed figure embodiment with numbered labels. FIG. 2E may show a process bulk displacing, or displacing, or flushing out, or any combination thereof an at least partially insoluble fluid with a two phase fluid. In some embodiments, it may be desirable for a portion of the two phase fluid to comprise a liquid. In some embodiments, a portion of a two phase fluid may displace a portion of an at least partially insoluble fluid. In some embodiments, a mixture comprising a two phase fluid and an at least partially insoluble fluid, which may form, may be separated using a liquid-liquid separator, or gravitational separation, or any combination thereof.

### FIG. 2F Summary:

FIG. 2F may comprise a detailed figure embodiment with numbered labels. FIG. 2F may show a process displacing, or flushing out, or any combination thereof an at least partially insoluble fluid with a two phase fluid. FIG. 2F may show a process of removing a portion of residual at least partially insoluble fluid from a portion of two phase fluid. In some embodiments, it may be desirable for a portion of the two phase fluid to comprise a liquid. In some embodiments, a portion of a two phase fluid may displace a portion of an at least partially insoluble fluid. In some embodiments, a mixture comprising a two phase fluid and an at least partially insoluble fluid, which may form, may be separated using a liquid-liquid separator, or gravitational separation, or any combination thereof.

### FIG. 2G Summary:

FIG. 2G may comprise a detailed figure embodiment with numbered labels. FIG. 2G may show a process bulk displacing, or displacing, or flushing out, or any combination thereof a two phase fluid with an at least partially insoluble fluid. In some embodiments, it may be desirable for a portion of the two phase fluid to comprise a liquid. In some embodiments, a portion of an at least partially insoluble fluid may displace a portion of a two phase fluid. In some embodiments, a mixture comprising a two phase fluid and an at least partially insoluble fluid, which may form, may be separated using a liquid-liquid separator, or gravitational separation, or any combination thereof.

### FIG. 2H Summary:

FIG. 2H may comprise a detailed figure embodiment with numbered labels. FIG. 2H may show a process displacing, or flushing out, or any combination thereof a two phase fluid with an at least partially insoluble fluid. FIG. 2H may show a process of removing a portion of residual two phase fluid from a portion of an at least partially insoluble fluid. In some embodiments, it may be desirable for a portion of the two phase fluid to comprise a liquid. In some embodiments, a portion of an at least partially insoluble fluid may displace a portion of a two phase fluid. In some embodiments, a mixture comprising a two phase fluid and an at least partially insoluble fluid, which may form, may be separated using a liquid-liquid separator, or gravitational separation, or any combination thereof.

### FIG. 2I Summary:

FIG. 2I may comprise a detailed figure embodiment with numbered labels. FIG. 2I may show a process bulk displacing, or displacing, or flushing out, or any combination thereof an at least partially insoluble fluid with an inert gas. In some embodiments, a portion of an inert gas may displace a portion of an at least partially insoluble fluid. In some embodiments, a mixture comprising an inert gas and an at least partially insoluble fluid, which may form, may be separated using an automatic air remover, or a gas-liquid separator, or liquid drop out, or evaporation, or purging, or gravitational separation, or any combination thereof.

### FIG. 2J Summary:

FIG. 2J may comprise a detailed figure embodiment with numbered labels. FIG. 2J may show a process displacing, or flushing out, or any combination thereof an at least partially insoluble fluid with an inert gas. FIG. 2J may show a process of removing a portion of residual at least partially insoluble fluid from a portion of an inert gas. In some embodiments, a portion of an inert gas may displace a portion of an at least partially insoluble fluid. In some embodiments, a mixture comprising an inert gas and an at least partially insoluble fluid, which may form, may be separated using an automatic air remover, or a gas-liquid separator, or liquid drop out, or evaporation, or purging, or gravitational separation, or any combination thereof.

### Example FIG. 2A-J Key

Example FIG. 2A-J Key

| ID | Description |
|---|---|
| 1 | ‘1’ may comprise a cold plate. ‘1’ may comprise a two-phase cold plate. ‘1’ may |
| | comprise a heat exchanger. ‘1’ may comprise a heat exchanger which may absorb or |
| | remove a portion of heat from a heat source, such as an electronic device, or a computer |
| | chip, or GPU, or CPU, or memory, or a high power electronic, or high power device, or |
| | any combination thereof. In some embodiments, a fluid comprising a two phase fluid |
| | may be transferred into ‘1’ as, for example, a portion of fluid comprising a liquid phase, |
| | and/or may be transferred out of ‘1’ as a portion of a fluid comprising a gas phase, or a |
| | super-heated phase, or any combination thereof. ‘1’ may comprise direct fluid cooling |
| | or heat transfer heat exchangers, or series of cold plate, or parallel cold plates, or series |
| | cold plates, or configured cold plates, or electronic heat exchanger system, or a fluid |
| | distribution system, or any combination thereof. |
| | In some embodiments, ‘1’ may be at least partially or temporarily compatible with an |
| | at least partially insoluble liquid, or water, or air, or an inert gas, or any combination |
| | thereof. In some embodiments, ‘1’ may be at least partially or temporarily compatible |
| | with an at least partially insoluble liquid, or water, or air, or an inert gas, or any |
| | combination thereof, which may enable the installation and/or deinstallation of a two |
| | phase fluid by, for example, fluid displacement and/or flushing. |
| 2 | ‘2’ may comprise a pipe or conduit which may transfer, or enable the transfer, or |
| | facilitate the transfer, or any combination thereof of a fluid. |
| 3 | ‘3’ may comprise a heat sink, or a heat sink heat exchanger, or a heat exchanger, or any |
| | combination thereof. ‘3’ may comprise a condenser heat exchanger. In some |
| | embodiments, a fluid comprising a two phase fluid may be transferred into ‘3’ as, for |
| | example, a portion of fluid comprising a gas or vapor phase, and/or may be transferred |
| | out of ‘3’ as a portion of a liquid phase. In some embodiments, a fluid may be passed |
| | through or transferred through ‘3’ and/or the fluid may comprise, for example, |
| | including, but not limited to, one or more or any combination of the following: chilled |
| | water, or a refrigerant, or air, or inert gas or a heat transfer fluid, or water, or glycol + |
| | water, or glycol, or methanol, or an organic solvent, or a two phase fluid, or a three |
| | phase fluid, or any combination thereof. |
| | In some embodiments, ‘3’ may be at least partially or temporarily compatible with an |
| | at least partially insoluble liquid, or water, or air, or an inert gas, or any combination |
| | thereof. In some embodiments, ‘3’ may be at least partially or temporarily compatible |
| | with an at least partially insoluble liquid, or water, or air, or an inert gas, or any |
| | combination thereof, which may enable the installation and/or deinstallation of a two |
| | phase fluid by, for example, fluid displacement and/or flushing. |
| 4 | ‘4’ may comprise a heat transfer fluid. ‘4’ may comprise a coolant. ‘4’ may comprise a |
| | supply or ‘cold’ or any combination thereof coolant or heat transfer fluid. ‘4’ may |
| | comprise chilled water. ‘4’ may comprise chilled water supply. ‘4’ may comprise |
| | coolant supply, or supply heat transfer fluid, or any combination thereof which may be |
| | employed to remove or transfer or absorb a portion of heat from ‘3’. |
| 5 | ‘5’ may comprise a heat transfer fluid. ‘5’ may comprise a coolant. ‘5’ may comprise a |
| | return or ‘warm’ or any combination thereof coolant or heat transfer fluid. ‘5’ may |
| | comprise chilled water. ‘5’ may comprise chilled water return. ‘5’ may comprise coolant |
| | return, or return heat transfer fluid, or any combination thereof which may be employed |
| | to remove or transfer or absorb a portion of heat from ‘3’. |
| 6 | ‘2’ may comprise a pipe or conduit which may transfer, or enable the transfer, or |
| | facilitate the transfer, or any combination thereof of a fluid. |
| 7 | ‘7’ may comprise a tee connection. ‘7’ may comprise a pipe, or conduit, or valve, or |
| | branch, or manifold, or connection, or any combination thereof. ‘7’ may transfer, or |
| | enable the transfer, or facilitate the transfer, or facilitate the directing or control, or any |
| | combination thereof of a fluid. |
| 8 | ‘8’ may comprise a pipe or conduit which may transfer, or enable the transfer, or |
| | facilitate the transfer, or any combination thereof of a fluid. |
| 9 | ‘9’ may comprise a valve. ‘9’ may comprise, for example, including, but not limited to, |
| | one or more or any combination of the following: an open/close valve, or a shutoff |
| | valve, or a ball valve, or an actuated valve, or a needle valve, or a one way valve, or a |
| | two way valve, or other valve, or any combination thereof. |
| 10 | ‘10’ may comprise a pipe or conduit which may transfer, or enable the transfer, or |
| | facilitate the transfer, or any combination thereof of a fluid. |
| 11 | ‘11’ may comprise a tee connection. ‘11’ may comprise a pipe, or conduit, or valve, or |
| | branch, or manifold, or connection, or any combination thereof. ‘11’ may transfer, or |
| | enable the transfer, or facilitate the transfer, or facilitate the directing or control, or any |
| | combination thereof of a fluid. |
| 12 | ‘12’ may comprise a pipe or conduit which may transfer, or enable the transfer, or |
| | facilitate the transfer, or any combination thereof of a fluid. |
| 13 | ‘13’ may comprise a tee connection. ‘13’ may comprise a pipe, or conduit, or valve, or |
| | branch, or manifold, or connection, or any combination thereof. ‘13’ may transfer, or |
| | enable the transfer, or facilitate the transfer, or facilitate the directing or control, or any |
| | combination thereof of a fluid. |
| 14 | ‘14’ may comprise a pipe or conduit which may transfer, or enable the transfer, or |
| | facilitate the transfer, or any combination thereof of a fluid. |
| 15 | ‘15’ may comprise a valve. ‘15’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 16 | ‘16’ may comprise a pipe or conduit which may transfer, or enable the transfer, or |
| | facilitate the transfer, or any combination thereof of a fluid. |
| 17 | ‘17’ may comprise a storage reservoir, or buffer tank, or any combination thereof. ‘17’ |
| | may comprise a storage reservoir. ‘17’ may storage reservoir configured to store a |
| | portion of two phase fluid. ‘17’ may store a fluid comprising at least a portion of two |
| | phase fluid, which may comprise a liquid phase. In some embodiments, ‘17’ may store |
| | two phase fluid and/or at least partially insoluble liquid. In some embodiments, ‘17’ |
| | may store a fluid comprising two phase fluid. |
| 18 | ‘18’ may comprise a pipe or conduit which may transfer, or enable the transfer, or |
| | facilitate the transfer, or any combination thereof of a fluid. |
| 19 | ‘19’ may comprise a fluid pump. ‘19’ may comprise a two phase fluid pump. ‘19’ may |
| | comprise a circulation pump. ‘19’ may comprise a fluid pump which may be compatible |
| | with two phase fluid. ‘19’ may comprise a fluid pump which may be compatible with |
| | two phase fluid, or at least partially insoluble liquid, or any combination thereof. ‘19’ |
| | may comprise a fluid pump which may enable or facilitate the transfer of, or bypass of |
| | a gas, or a gas removal, or the flow of a gas, or the circulation of a gas, or any |
| | combination thereof, for example, if an inert gas is transferred into, or out of, or any |
| | combination thereof the system, or heat transfer loop, or any combination thereof. |
| | In some embodiments, ‘19’ may be at least partially or temporarily compatible, or |
| | designed to handle or bypass, or any combination thereof with a fluid comprising an at |
| | least partially insoluble liquid, or water, or air, or an inert gas, or any combination |
| | thereof. In some embodiments, ‘19’ may be at least partially or temporarily compatible |
| | with a fluid comprising an at least partially insoluble liquid, or water, or air, or an inert |
| | gas, or any combination thereof, which may enable or facilitate the installation and/or |
| | deinstallation of a two phase fluid by, for example, fluid displacement and/or flushing. |
| 20 | ‘20’ may comprise a pipe or conduit which may transfer, or enable the transfer, or |
| | facilitate the transfer, or any combination thereof of a fluid. |
| 21 | ‘21’ may comprise a valve. ‘21’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 22 | ‘22’ may comprise a pipe or conduit which may transfer, or enable the transfer, or |
| | facilitate the transfer, or any combination thereof of a fluid. |
| 23 | ‘23’ may comprise a pipe or conduit which may transfer, or enable the transfer, or |
| | facilitate the transfer, or any combination thereof of a fluid. |
| 24 | ‘24’ may comprise a valve. ‘24’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 25 | ‘25’ may comprise a pipe or conduit which may transfer, or enable the transfer, or |
| | facilitate the transfer, or any combination thereof of a fluid. |
| 26 | ‘26’ may comprise a fluid pump. ‘26’ may comprise a two phase fluid pump. ‘26’ may |
| | comprise a circulation pump. ‘26’ may comprise a fluid pump which may be compatible |
| | with two phase fluid. ‘26’ may comprise a fluid pump which may be compatible with |
| | two phase fluid, or at least partially insoluble liquid, or any combination thereof. ‘26’ |
| | may comprise a fluid pump which may enable or facilitate the transfer of, or bypass of |
| | a gas, or a gas removal, or the flow of a gas, or the circulation of a gas, or any |
| | combination thereof, for example, if an inert gas is transferred into, or out of, or any |
| | combination thereof the system, or heat transfer loop, or any combination thereof. |
| | In some embodiments, ‘26’ may be at least partially or temporarily compatible, or |
| | designed to handle or bypass, or any combination thereof with a fluid comprising an at |
| | least partially insoluble liquid, or water, or air, or an inert gas, or any combination |
| | thereof. In some embodiments, ‘26’ may be at least partially or temporarily compatible |
| | with a fluid comprising an at least partially insoluble liquid, or water, or air, or an inert |
| | gas, or any combination thereof, which may enable or facilitate the installation and/or |
| | deinstallation of a two phase fluid by, for example, fluid displacement and/or flushing. |
| 27 | ‘27’ may comprise a pipe or conduit which may transfer, or enable the transfer, or |
| | facilitate the transfer, or any combination thereof of a fluid. |
| 28 | ‘28’ may comprise a tee connection. ‘28’ may comprise a pipe, or conduit, or valve, or |
| | branch, or manifold, or connection, or any combination thereof. ‘28’ may transfer, or |
| | enable the transfer, or facilitate the transfer, or facilitate the directing or control, or any |
| | combination thereof of a fluid. |
| 29 | ‘29’ may comprise a pipe or conduit which may transfer, or enable the transfer, or |
| | facilitate the transfer, or any combination thereof of a fluid. |
| 30 | ‘30’ may comprise a tee connection. ‘30’ may comprise a pipe, or conduit, or valve, or |
| | branch, or manifold, or connection, or any combination thereof. ‘30’ may transfer, or |
| | enable the transfer, or facilitate the transfer, or facilitate the directing or control, or any |
| | combination thereof of a fluid. |
| 31 | ‘31’ may comprise a valve. ‘31’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 32 | ‘32’ may comprise a tee connection. ‘32’ may comprise a pipe, or conduit, or valve, or |
| | branch, or manifold, or connection, or any combination thereof. ‘32’ may transfer, or |
| | enable the transfer, or facilitate the transfer, or facilitate the directing or control, or any |
| | combination thereof of a fluid. |
| 33 | ‘33’ may comprise a valve. ‘33’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 34 | ‘34’ may comprise a tee connection. ‘34’ may comprise a pipe, or conduit, or valve, or |
| | branch, or manifold, or connection, or any combination thereof. ‘34’ may transfer, or |
| | enable the transfer, or facilitate the transfer, or facilitate the directing or control, or any |
| | combination thereof of a fluid. |
| 35 | ‘35’ may comprise a valve. ‘35’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 36 | ‘36’ may comprise a tee connection. ‘36’ may comprise a pipe, or conduit, or valve, or |
| | branch, or manifold, or connection, or any combination thereof. ‘36’ may transfer, or |
| | enable the transfer, or facilitate the transfer, or facilitate the directing or control, or any |
| | combination thereof of a fluid. |
| 37 | ‘37’ may comprise a pipe or conduit which may transfer, or enable the transfer, or |
| | facilitate the transfer, or any combination thereof of a fluid. |
| 38 | ‘38’ may comprise a valve. ‘38’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 39 | ‘39’ may comprise a pipe or conduit which may transfer, or enable the transfer, or |
| | facilitate the transfer, or any combination thereof of a fluid. |
| 40 | ‘40’ may comprise a pipe or conduit which may transfer, or enable the transfer, or |
| | facilitate the transfer, or any combination thereof of a fluid. |
| 41 | ‘41’ may comprise a valve. ‘41’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 42 | ‘42’ may comprise a pipe or conduit which may transfer, or enable the transfer, or |
| | facilitate the transfer, or any combination thereof of a fluid. |
| 43 | ‘43’ may comprise a gas-liquid separator. ‘43’ may comprise an automatic gas remover. |
| | ‘43’ may comprise a method for separating a portion of a gas phase from a portion of a |
| | liquid phase. In some embodiments, ‘43’ may comprise a fluid storage tank. In some |
| | embodiments, ‘43’ may comprise a liquid storage tank. In some embodiments, for |
| | example, a fluid comprising a mixture of a liquid, such as a liquid comprising at least |
| | partially insoluble liquid, and a gas, such as a gas comprising nitrogen, may be |
| | transferred into ‘43’, wherein, for example, a portion of the gas may be separated from |
| | the liquid. In some embodiments, a portion of a gas may be separated, or transported |
| | out, or stored separately, or released, or any combination thereof. In some embodiments, |
| | a portion of a liquid may be separated, or transported out, or stored separately, or |
| | released, or any combination thereof. In some embodiments, a portion of a separated |
| | liquid may be transferred to or returned to the system, or loop, or heat transfer loop, or |
| | any combination thereof. In some embodiments, for example, a liquid comprising an at |
| | least partially insoluble liquid may be transferred into and/or circulated within a heat |
| | transfer loop to displace and/or flush out a gas, such as an inert gas or air. In some |
| | embodiments, for example, a liquid comprising an at least partially insoluble liquid may |
| | be transferred into and/or circulated within a heat transfer loop to displace and/or flush |
| | out a gas, such as an inert gas or air, wherein it may be desirable to separate a portion |
| | of liquid from a portion of gas. In some embodiments, for example, a gas comprising, |
| | for example, an inert gas or air, may be transferred into and/or circulated within a heat |
| | transfer loop to displace and/or flush out a liquid, such as an at least partially insoluble |
| | liquid. In some embodiments, for example, a gas comprising, for example, an inert gas |
| | or air, may be transferred into and/or circulated within a heat transfer loop to displace |
| | and/or flush out a liquid, such as an at least partially insoluble liquid, wherein it may be |
| | desirable to separate a portion of gas from a portion of liquid. |
| 44 | ‘44’ may comprise a pipe or conduit which may transfer, or enable the transfer, or |
| | facilitate the transfer, or any combination thereof of a fluid. |
| 45 | ‘45’ may comprise a valve. ‘45’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 46 | ‘46’ may comprise a pipe or conduit which may transfer, or enable the transfer, or |
| | facilitate the transfer, or any combination thereof of a fluid. |
| 47 | ‘47’ may comprise a fluid storage reservoir. ‘47’ may comprise a liquid storage |
| | reservoir. ‘47’ may comprise an at least partially insoluble liquid storage reservoir. ‘47’ |
| | may comprise an at least partially insoluble liquid storage reservoir, such as a water |
| | storage reservoir. ‘47’ may comprise a storage reservoir for a fluid comprising water. |
| | ‘47’ may comprise a storage reservoir, or buffer tank, or any combination thereof. ‘47’ |
| | may comprise a storage reservoir. ‘47’ may storage reservoir configured to store a |
| | portion of an at least partially insoluble liquid. In some embodiments, ‘47’ may store |
| | two phase fluid and/or at least partially insoluble liquid. In some embodiments, ‘47’ |
| | may store a fluid comprising at least partially insoluble liquid, or a liquid, or water, or |
| | any combination thereof. |
| 48 | ‘48’ may comprise a pipe or conduit which may transfer, or enable the transfer, or |
| | facilitate the transfer, or any combination thereof of a fluid. |
| 49 | ‘49’ may comprise a fluid pump. ‘49’ may comprise an at least partially insoluble liquid |
| | pump. ‘49’ may comprise a pump configured to pump a fluid comprising water. ‘49’ |
| | may comprise a pump configured to pump a fluid comprising a liquid. ‘49’ may |
| | comprise a circulation pump. ‘49’ may comprise a fluid pump which may be compatible |
| | with water. ‘49’ may comprise a fluid pump which may be compatible with two phase |
| | fluid, or at least partially insoluble liquid, or any combination thereof. ‘49’ may |
| | comprise a fluid pump which may enable or facilitate the transfer of, or bypass of a gas, |
| | or a gas removal, or the flow of a gas, or the circulation of a gas, or any combination |
| | thereof, for example, if an inert gas is transferred into, or out of, or any combination |
| | thereof the system, or heat transfer loop, or any combination thereof. |
| | In some embodiments, ‘49’ may be at least partially or temporarily compatible, or |
| | designed to handle or bypass, or any combination thereof with a fluid comprising an at |
| | two phase fluid, or water, or air, or gas, or vapor, or an inert gas, or any combination |
| | thereof. In some embodiments, ‘49’ may be at least partially or temporarily compatible |
| | with a fluid comprising two phase fluid, or water, or air, or gas, or vapor, or an inert gas, |
| | or any combination thereof, which may enable or facilitate the installation and/or |
| | deinstallation of a two phase fluid by, for example, fluid displacement and/or flushing. |
| 50 | ‘50’ may comprise a pipe or conduit which may transfer, or enable the transfer, or |
| | facilitate the transfer, or any combination thereof of a fluid. |
| 51 | ‘51’ may comprise a valve. ‘51’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 52 | ‘52’ may comprise a pipe or conduit which may transfer, or enable the transfer, or |
| | facilitate the transfer, or any combination thereof of a fluid. |
| 53 | ‘53’ may comprise a pipe or conduit which may transfer, or enable the transfer, or |
| | facilitate the transfer, or any combination thereof of a fluid. |
| 54 | ‘54’ may comprise a valve. ‘54’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 55 | ‘55’ may comprise a pipe or conduit which may transfer, or enable the transfer, or |
| | facilitate the transfer, or any combination thereof of a fluid. |
| 56 | ‘56’ may comprise a fluid separator. ‘56’ may comprise a liquid-liquid separator. ‘56’ |
| | may comprise a fluid-fluid separator. ‘56’ may comprise a fluid-fluid-fluid separator. |
| | ‘56’ may comprise a separator to separate at least a portion of a first phase comprising |
| | a liquid from a second phase comprising a liquid, or vapor, or any combination thereof. |
| | In some embodiments, ‘56’ may separate a portion of a fluid comprising a two phase |
| | fluid from a portion of a fluid comprising an at least partially insoluble liquid. In some |
| | embodiments, ‘56’ may separate a portion of a fluid comprising an-Pentane from a |
| | portion of a fluid comprising water. In some embodiments, ‘56’ may comprise a density |
| | based separation, or a gravitational based separation, or a polarity based separation, or |
| | any combination thereof. In some embodiments, ‘56’ may comprise including, but not |
| | limited to, one or more or any combination of the following: a liquid-liquid separator, |
| | or a decanter, or a centrifuge, or a coalescer, or a membrane, or an affinity based |
| | separation, or a polarity based separation, or a dielectric constant based separation, or a |
| | viscosity based separation, or a surface tension based separation, or a separation herein, |
| | or a separation in the art. |
| 57 | ‘57’ may comprise a pipe or conduit which may transfer, or enable the transfer, or |
| | facilitate the transfer, or any combination thereof of a fluid. |
| 58 | ‘58’ may comprise a pipe or conduit which may transfer, or enable the transfer, or |
| | facilitate the transfer, or any combination thereof of a fluid. |
| 59 | ‘59’ may comprise a gas, or a compressed gas, or an inert gas, or input gas, or stored |
| | gas, or any combination thereof. In some embodiments, ‘59’ may comprise a source of |
| | a gas, or an input for a gas, or any combination thereof which may be employed to, for |
| | example, to displace, or remove, or flush out, or purge, or any combination thereof a |
| | portion of the at least partially insoluble fluid. In some embodiments,′ ‘59’ may |
| | comprise a source of a gas, or an input for a gas, or any combination thereof which may |
| | be employed to, for example, to displace, or remove, or flush out, or purge, or any |
| | combination thereof a portion of the two phase fluid. In some embodiments,′ ‘59’ may |
| | comprise a source of a gas, or an input for an inert gas, or any combination thereof |
| | which may be employed to, for example, to displace, or remove, or flush out, or purge, |
| | or any combination thereof a portion of air, or a gas comprising oxygen, or any |
| | combination thereof. |
| 60 | ‘60’ may comprise a pipe or conduit which may transfer, or enable the transfer, or |
| | facilitate the transfer, or any combination thereof of a fluid. |
| 61 | ‘61’ may comprise a valve. ‘61’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 62 | ‘62’ may comprise a pipe or conduit which may transfer, or enable the transfer, or |
| | facilitate the transfer, or any combination thereof of a fluid. |
| 63 | ‘63’ may comprise a pipe or conduit which may transfer, or enable the transfer, or |
| | facilitate the transfer, or any combination thereof of a fluid. |
| 64 | ‘64’ may comprise a valve. ‘64’ may comprise, for example, including, but not limited |
| | to, one or more or any combination of the following: an open/close valve, or a shutoff |
| | valve, or a ball valve, or an actuated valve, or a needle valve, or a one way valve, or a |
| | two way valve, or other valve, or any combination thereof. |
| 65 | ‘65’ may comprise a pipe or conduit which may transfer, or enable the transfer, or |
| | facilitate the transfer, or any combination thereof of a fluid. |
| 66 | ‘66’ may comprise a gas-liquid separator. ‘66’ may comprise an automatic gas remover. |
| | ‘66’ may comprise a method for separating a portion of a gas phase from a portion of a |
| | liquid phase. In some embodiments, ‘66’ may comprise a fluid storage tank. In some |
| | embodiments, ‘66’ may comprise a liquid storage tank. In some embodiments, for |
| | example, a fluid comprising a mixture of a liquid, such as a liquid comprising at least |
| | partially insoluble liquid, and a gas, such as a gas comprising nitrogen, may be |
| | transferred into ‘66’, wherein, for example, a portion of the gas may be separated from |
| | the liquid. In some embodiments, a portion of a gas may be separated, or transported |
| | out, or stored separately, or released, or any combination thereof. In some embodiments, |
| | a portion of a liquid may be separated, or transported out, or stored separately, or |
| | released, or any combination thereof. In some embodiments, a portion of a separated |
| | liquid may be transferred to or returned to the system, or loop, or heat transfer loop, or |
| | any combination thereof. In some embodiments, for example, a liquid comprising an at |
| | least partially insoluble liquid may be transferred into and/or circulated within a heat |
| | transfer loop to displace and/or flush out a gas, such as an inert gas or air. In some |
| | embodiments, for example, a liquid comprising an at least partially insoluble liquid may |
| | be transferred into and/or circulated within a heat transfer loop to displace and/or flush |
| | out a gas, such as an inert gas or air, wherein it may be desirable to separate a portion |
| | of liquid from a portion of gas. In some embodiments, for example, a gas comprising, |
| | for example, an inert gas or air, may be transferred into and/or circulated within a heat |
| | transfer loop to displace and/or flush out a liquid, such as an at least partially insoluble |
| | liquid. In some embodiments, for example, a gas comprising, for example, an inert gas |
| | or air, may be transferred into and/or circulated within a heat transfer loop to displace |
| | and/or flush out a liquid, such as an at least partially insoluble liquid, wherein it may be |
| | desirable to separate a portion of gas from a portion of liquid. |
| 67 | ‘67’ may comprise a pipe or conduit which may transfer, or enable the transfer, or |
| | facilitate the transfer, or any combination thereof of a fluid. |
| 68 | ‘68’ may comprise a heat source. In some embodiments, ‘68’ may comprise a heat |
| | source, which may comprise, including, but not limited to, one or more or any |
| | combination of the following: a high power electronic, or a GPU, or a CPU, or a server, |
| | or a rack, or memory, or circuitry, or high temperature electrode, or an electrode, or a |
| | device requiring cooling, or switchgear, or low voltage, or medium voltage, or high |
| | voltage, or battery, or capacitor, or inverter, or a semiconductor, or a motor, or an engine, |
| | or TEG, or a generator, or steam, or display, or LED, or laser, or any combination |
| | thereof. |
| 69 | ‘69’ may comprise a gas. ‘69’ may comprise an at least partially separated gas. In some |
| | embodiments, ‘69’ may comprise a gas which may have been at least partially separated |
| | from a fluid comprising at least partially insoluble fluid, or two phase fluid, or any |
| | combination thereof. In some embodiment, ‘69’ may be, for example, including, but not |
| | limited to, one or more or any combination of the following: treated, or compressed, or |
| | stored, or purified, or a portion of residual chemicals separated or recovered or removed, |
| | or stored, or compressed, or recirculated, or any combination thereof. |
| 70 | ‘70’ may comprise a gas. ‘70’ may comprise an at least partially separated gas. In some |
| | embodiments, ‘70’ may comprise a gas which may have been at least partially separated |
| | from a fluid comprising at least partially insoluble fluid, or two phase fluid, or any |
| | combination thereof. In some embodiment, ‘69’ may be, for example, including, but not |
| | limited to, one or more or any combination of the following: treated, or compressed, or |
| | stored, or purified, or a portion of residual chemicals separated or recovered or removed, |
| | or stored, or compressed, or recirculated, or any combination thereof. |

### EXAMPLE EMBODIMENTS

### Example Independent Embodiments, or Dependent Embodiments, or any Combination Thereof:

A process for installing a two phase fluid comprising:
Transferring an at least partially insoluble fluid into a heat transfer loop to displace an inert gas from a heat transfer loop; and
Transferring a two phase fluid into a heat transfer loop to displace the at least partially insoluble fluid from the heat transfer loop.

A process for installing a two phase fluid comprising:
Transferring water into a heat transfer loop to displace an inert gas from a heat transfer loop; and Transferring a two phase fluid into a heat transfer loop to displace water from the heat transfer loop.

A process for installing a two phase fluid comprising:
Transferring a liquid comprising water into a heat transfer loop to displace at least a portion of a gas from the heat transfer loop;
Transferring a two phase fluid into the heat transfer loop to displace at least a portion of the liquid comprising water from the heat transfer loop.

A process for installing a two phase fluid comprising:
Transferring a two phase fluid into a heat transfer loop to displace at least a portion of an at least partially insoluble fluid;
Wherein at least a portion of the two phase fluid is at a liquid phase or liquid state.

A process for installing a two phase fluid comprising:
Transferring a two phase fluid into a heat transfer loop to displace at least a portion of an at least partially insoluble fluid from a heat transfer loop;
Wherein at least a portion of the two phase fluid is at a liquid phase or liquid state.

A process for installing a two phase fluid comprising:
Transferring a two phase fluid into a heat transfer loop to displace at least a portion of an at least partially insoluble liquid;
Wherein at least a portion of the two phase fluid is at a liquid phase or liquid state.

A process for installing a two phase fluid comprising:
Transferring a two phase fluid into a heat transfer loop to displace at least a portion of an at least partially insoluble liquid from a heat transfer loop;
Wherein at least a portion of the two phase fluid is at a liquid phase or liquid state.

A process for installing a two phase fluid comprising:
Transferring a two phase fluid into a heat transfer loop to displace at least a portion of water from a heat transfer loop;
Wherein at least a portion of the two phase fluid is at a liquid phase or liquid state.

A process for installing a two phase fluid comprising:
Transferring a fluid comprising pentane into a heat transfer loop to displace at least a portion of water from a heat transfer loop;
Wherein at least a portion of the two phase fluid is at a liquid phase or liquid state.

A process for installing a two phase fluid comprising:
Transferring a two phase fluid into a heat transfer loop to displace at least a portion of a fluid comprising an at least partially insoluble fluid;
Wherein at least a portion of the two phase fluid is at a gaseous state or gaseous phase.

A process for installing a two phase fluid comprising:
Transferring a two phase fluid into a heat transfer loop to displace at least a portion of a liquid comprising an at least partially insoluble fluid;
Wherein at least a portion of the two phase fluid is at a gaseous state or gaseous phase.

A process for installing a two phase fluid comprising:
Transferring a two phase fluid into a heat transfer loop to displace at least a portion of a fluid comprising an at least partially insoluble fluid from the heat transfer loop;
Wherein at least a portion of the two phase fluid is at a gaseous state or gaseous phase.

A process for installing a two phase fluid comprising:
Transferring a two phase fluid into a heat transfer loop to displace at least a portion of an at least partially insoluble liquid from the heat transfer loop;
Wherein at least a portion of the two phase fluid is at a liquid state or liquid phase.

A process for installing a two phase fluid comprising:
Transferring a two phase fluid into a heat transfer loop to displace at least a portion of a fluid comprising water from the heat transfer loop;
Wherein at least a portion of the two phase fluid is at a gaseous state or gaseous phase.

A process for installing a two phase fluid comprising:
Transferring a two phase fluid into a heat transfer loop to displace at least a portion of a liquid comprising water from the heat transfer loop;
Wherein at least a portion of the two phase fluid is at a gaseous state or gaseous phase.

A process for deinstalling or uninstalling or removing a two phase fluid comprising:
Transferring at least a portion of a fluid comprising an at least a partially insoluble fluid into a heat transfer loop to displace a least a portion of a fluid comprising a two phase fluid from the heat transfer loop,
Transferring at least a portion of a gas into the heat transfer loop to displace at least a portion of at least partially insoluble fluid from the heat transfer loop.

A process for deinstalling or uninstalling or removing a two phase fluid comprising:
Transferring at least a portion of a fluid comprising an at least a partially insoluble fluid into a heat transfer loop to displace a least a portion of a fluid comprising a two phase fluid from the heat transfer loop,
Transferring at least a portion of an inert gas into the heat transfer loop to displace at least a portion of at least partially insoluble fluid from the heat transfer loop.

A process for deinstalling or uninstalling or removing a two phase fluid comprising:
Transferring at least a portion of a liquid comprising an at least a partially insoluble liquid into a heat transfer loop to displace a least a portion of a fluid comprising a two phase fluid from the heat transfer loop,
Transferring at least a portion of an inert gas into the heat transfer loop to displace at least a portion of at least partially insoluble fluid from the heat transfer loop.

A process for deinstalling or uninstalling or removing a two phase fluid comprising:
Transferring at least a portion of a liquid comprising water into a heat transfer loop to displace a least a portion of a fluid comprising a two phase fluid from the heat transfer loop,
Transferring at least a portion of an inert gas into the heat transfer loop to displace at least a portion of the water from the heat transfer loop.

A process for deinstalling or uninstalling or removing a two phase fluid comprising:
Transferring at least a portion of a fluid comprising an at least a partially insoluble fluid into a heat transfer loop to displace a least a portion of a fluid comprising a two phase fluid from the heat transfer loop,
Wherein at least a portion of the two phase fluid comprises a liquid phase or liquid state.

A process for deinstalling or uninstalling or removing a two phase fluid comprising:
Transferring at least a portion of a fluid comprising water into a heat transfer loop to displace a least a portion of a fluid comprising a two phase fluid from the heat transfer loop,
Wherein at least a portion of the two phase fluid comprises a liquid phase or liquid state.

A process for deinstalling or uninstalling or removing a two phase fluid comprising:
Transferring at least a portion of a fluid comprising water into a heat transfer loop to displace a least a portion of a fluid comprising a two phase fluid from the heat transfer loop,
Wherein at least a portion of the displaced two phase fluid comprises a liquid phase or liquid state.

A process for deinstalling or uninstalling or removing a two phase fluid comprising:
Transferring at least a portion of a fluid comprising water into a heat transfer loop to displace a least a portion of a fluid comprising a two phase fluid from the heat transfer loop,
Wherein at least a portion of the displaced two phase fluid exiting from the heat transfer loop comprises a liquid phase or liquid state.

### Example Dependent Embodiments, or Independent Embodiments, or any Combination Thereof:

Wherein the heat transfer loop comprises an electronics cooling system.
Wherein the heat transfer loop comprising a direct to chip cooling system.
Wherein the heat transfer loop comprises a cold plate cooling system.
Wherein the heat transfer loop comprises a pumped two phase fluid cooling system.
Wherein the two phase fluid is selected from a hydrocarbon, or a natural refrigerant, or propane, or butane, or pentane, or hexane, or isomers thereof, or derivatives thereof, or any combination thereof.
Wherein the two phase fluid is a fire hazard below 200 degrees Fahrenheit in the presence of sufficient diatomic oxygen according to NFPA definitions
Wherein the inert gas comprises nitrogen, or argon, or carbon dioxide, or helium, or neon, or noble gas, or a mixture thereof.
Wherein the two phase fluid comprises a fluorocarbon.
Transferring an inert gas into the heat transfer loop to purge or dilute air which may be present in the heat transfer loop.
Wherein the water comprises deionized water, or deoxygenated water, or any combination thereof.
Wherein the deionized water is produced within 24 hours, or 48 hours, or 1 week, or 1 month, or 3 months, or 6 months, or any combination thereof to prevent biofouling, or fouling, or scalants.
Wherein the deionized water is stored at a refrigerated temperature to prevent or reduce, for example, biofouling or microbial growth.
Wherein said deionized water is stored at a temperature less than 25° C., or 20° C., or 15° C., or 10° C., or 7.5° C., or 5° C., or any combination thereof to, for example, prevent or reduce, for example, potential biofouling or microbial growth.
Wherein said deionized water is stored at a heated temperature to prevent or reduce, for example, biofouling or microbial growth.
Wherein said deionized water is stored at a temperature greater than 25° C., or 30° C., or 35° C., or 40° C., or 45° C., or 50° C., or any combination thereof to, for example, prevent or reduce, for example, potential biofouling or microbial growth.
Wherein the at least partially insoluble fluid comprises water.
Wherein the at least partially insoluble fluid is treated to prevent or reduce, for example, including, but not limited to, one or more or any combination of the following: biofouling, or corrosion, or scalants, or scaling, or degradation, or residue, or dissolved oxygen, or dissolved gases, or undesired dissolved gases.
Wherein the water is treated to prevent or reduce, for example, including, but not limited to, one or more or any combination of the following: biofouling, or corrosion, or scalants, or scaling, or degradation, or residue, or dissolved oxygen, or dissolved gases, or undesired dissolved gases.
Wherein the at least partially insoluble fluid comprises a glycol.
Wherein the at least partially insoluble fluid comprises an alcohol.
Wherein the at least partially insoluble fluid comprises a diol.
Wherein a fluid comprises, one or more or any combination of the following: a diol, or glycol, or a ketone, or an aldehyde, or an ester, or ammonia, or an amine, or a compound comprising sulfur, or a nitrogenous compound, or an organosulfur compound, or a fluorocarbon, or a halogenated hydrocarbon, or water, or an alcohol, or a carboxylic acid.
Wherein water comprises at least a portion of water and at least a portion of an alcohol.
Wherein water comprises at least a portion of water and at least a portion of an glycol.
Wherein water comprises an at least partially biostatic solution.
Wherein the at least partially insoluble fluid comprises a liquid.
Wherein the at least partially insoluble fluid comprises an at least partially biostatic solution.
Wherein the at least partially insoluble fluid comprises a solution of water and a glycol.
Wherein the at least partially insoluble fluid comprises a solution of water and propylene glycol.
Wherein the at least partially insoluble fluid comprises a solution of water and ethylene glycol.
Wherein the at least partially insoluble fluid comprises a solution of water and ethanol.
Wherein the at least partially insoluble fluid comprises a solution of water and methanol.
Wherein the at least partially insoluble fluid comprises a solution of water and isopropyl alcohol.
Wherein the at least partially insoluble fluid comprises a solution of water and a glycol polymer, or a diol polymer, or a polyol.
Wherein the at least partially insoluble fluid comprises a solution of water and propylene glycol, wherein the propylene glycol concentration is greater than 20 wt %.
Wherein the at least partially insoluble fluid comprises a solution of water and ethanol, wherein the ethanol concentration is greater than 20 wt %.
Wherein at least a portion of the two phase fluid comprises a liquid phase.
Wherein at least a portion of the two phase fluid comprises a liquid phase when displacing at least a portion of the at least partially insoluble fluid.
Wherein at least a portion of the two phase fluid comprises a liquid phase when displacing at least a portion of the water.
Wherein the two phase fluid comprises one or more or any combination of the following: a hydrocarbon, or propane, or butane, or pentane, or hexane, or dimethyl ether, or methyl formate, or propylene, or butylene, or a natural refrigerant.
Wherein the two phase fluid comprises one or more or any combination of the following: a fluorocarbon, or a hydrofluoroether, or a PFAS, or a fluorocarbon refrigerant, or a low flammability refrigerant, or a refrigerant blend.
Wherein the two phase fluid comprises one or more or any combination of the following: carbon dioxide, sulfur dioxide, or ammonia, or amine, or nitrogen dioxide, or dinitrogen tetroxide, or nitrous oxide.
Wherein the two phase fluid comprises a liquid.
Wherein the two phase fluid comprises a gas.
Wherein the two phase fluid comprises a gas, or a liquid, or a vapor, or a supercritical fluid, or any combination thereof.
Wherein the gas comprises an inert gas.
Wherein the gas comprises air.
Wherein an inert gas comprises a gas with a concentration of diatomic oxygen less than one or more or any combination of the following by volume: 20%, or 19%, or 18%, or 17%, or 16%, or 15%, or 14%, or 13%, or 12%, or 11%, or 10%, or 9%, or 8%, or 7%, or 6%, or 5%, or 4%, or 3%, or 2%, or 1%.
Wherein an inert gas comprises a gas which a two phase fluid may be unable to or less likely to combust or degrade in under the conditions in the one or more or any combination of potentially present systems, or potentially present conditions, or any combination thereof.
Wherein an inert gas comprises one or more or any combination of the following: nitrogen gas, or argon gas, or a noble gas, or carbon dioxide gas, or a fluorocarbon gas, or a non-flammable gas, or air, or air comprising a lower concentration of diatomic oxygen, or steam.
Wherein an inert gas is transferred into and/or circulated within a heat transfer loop to, for example, displace, or evaporate, or purge, or any combination thereof at least a portion of any residual at least partially insoluble fluid, or two phase fluid, or any combination thereof.
Wherein an inert gas is transferred into and/or circulated within a heat transfer loop to, for example, displace, or evaporate, or purge, or any combination thereof at least a portion of any residual water.
Wherein the heat transfer loop is purged with an inert gas to, for example, displace, or evaporate, or purge, or any combination thereof at least a portion of any residual at least partially insoluble fluid, or two phase fluid, or any combination thereof.
Wherein said purging with an inert gas is paused when the concentration of a two phase fluid vapor in the inert gas within, or exiting the heat transfer loop is less than one or more or any combination of the following: 10,000 PPM, or 5,000 PPM, or 1,000 PPM, or 500 PPM, or 250 PPM, or 100 PPM, or 50 PPM, or 25 PPM, or 10 PPM, or 5 PPM, or 2.5 PPM, or 1 PPM, or 0.5 PPM, or 0.1 PPM.
Wherein said purging with an inert gas is paused when the concentration of at least partially insoluble fluid vapor in the inert gas within, or exiting the heat transfer loop is less than one or more or any combination of the following: 50,000 PPM, or 25,000 PPM, 10,000 PPM, or 5,000 PPM, or 1,000 PPM, or 500 PPM, or 250 PPM, or 100 PPM, or 50 PPM, or 25 PPM, or 10 PPM, or 5 PPM, or 2.5 PPM, or 1 PPM, or 0.5 PPM, or 0.1 PPM.
Wherein said purging with an inert gas is paused when the concentration of water vapor in the inert gas within, or exiting the heat transfer loop is less than one or more or any combination of the following: 50,000 PPM, or 25,000 PPM, 10,000 PPM, or 5,000 PPM, or 1,000 PPM, or 500 PPM, or 250 PPM, or 100 PPM, or 50 PPM, or 25 PPM, or 10 PPM, or 5 PPM, or 2.5 PPM, or 1 PPM, or 0.5 PPM, or 0.1 PPM.
Wherein a mixture comprising two phase fluid and at least partially insoluble fluid may form.
Wherein a mixture comprising two phase fluid and at least partially insoluble liquid may form.
Wherein a mixture comprising two phase fluid and at least partially insoluble fluid may be separated into at least a portion of a first fluid comprising two phase fluid and at least a portion of a second fluid comprising an at least partially insoluble fluid.
Wherein a mixture comprising two phase fluid and water may be separated into at least a portion of a first fluid comprising two phase fluid and at least a portion of a second fluid comprising water.
Wherein a mixture comprising two phase fluid and at least partially insoluble liquid may be separated into at least a portion of a first fluid comprising two phase fluid and at least a portion of a second fluid comprising an at least partially insoluble liquid.
Wherein a mixture comprising an at least partially insoluble fluid and a gas may form.
Wherein a mixture comprising an at least partially insoluble fluid and an inert gas may form.
Wherein a mixture comprising an at least partially insoluble liquid and an inert gas may form.
Wherein a mixture comprising water and a gas may form.
Wherein a mixture comprising water and an inert gas may form.
Wherein a mixture at least partially insoluble fluid and a gas may be separated.
Wherein said mixture may be separated.
Wherein at least a portion of said mixture may be separated.
Wherein at least a portion of said mixture may be separated into a first fluid comprising an at least partially insoluble and a second fluid comprising an inert gas.
Wherein said separation may comprise a liquid-liquid separation, or a gas-liquid separation, or a fluid-fluid separation, or a solid-liquid separation, or a solid-gas separation, or a solid-fluid separation, or any combination thereof.
Wherein said separation comprises one or more or any combination of the following: decanting, or coalescing, or centrifugation, or automatic gas remover, or gas vent, or density based separating, or gravity based separating, or settling.
Wherein said separation comprises one or more or any combination of the following: boiling, or vaporization, or distillation, or separation based on differences in boiling point, or separation based on differences in vapor pressure, or separation based on differences in surface tension, or separation based on differences in viscosity.

1. A process for installing a two phase fluid comprising:
Transferring an at least partially insoluble fluid into a heat transfer loop to displace at least a portion of a gas from the heat transfer loop;
Transferring a two phase fluid into the heat transfer loop to displace at least a portion of the partially insoluble fluid from the heat transfer loop;
Separating a portion of the at least partially insoluble fluid from a portion of the two phase fluid.

2. The process of example independent or dependent embodiment 1 wherein the two phase fluid comprises one or more or any combination of the following: a hydrocarbon, or propane, or butane, or pentane, or hexane, or dimethyl ether, or methyl formate, or ethylene, or propylene, or butylene, or a natural refrigerant.

3. The process of example independent or dependent embodiment 1 wherein the at least partially insoluble fluid comprises water.

4. The process of example independent or dependent embodiment 1 wherein the at least partially insoluble fluid comprises a liquid.

5. The process of example independent or dependent embodiment 1 wherein the gas comprises an inert gas.

6. The process of example independent or dependent embodiment 1 wherein the gas comprises air.

7. The process of example independent or dependent embodiment 1 wherein a portion of the two phase fluid comprises a liquid.

8. The process of example independent or dependent embodiment 1 wherein the heat transfer loop comprising a direct to chip cooling system.

9. The process of example independent or dependent embodiment 1 wherein the at least partially insoluble fluid is treated to prevent or reduce, for example, including, but not limited to, one or more or any combination of the following: biofouling, or corrosion, or scalants, or scaling, or degradation, or residue, or dissolved oxygen, or dissolved gases, or undesired dissolved gases, or undesired ions.

10. The process of example independent or dependent embodiment 1 wherein the two phase fluid comprises one or more or any combination of the following: sulfur dioxide, or ammonia, or amine, or nitrogen dioxide, or dinitrogen tetroxide, or nitrous oxide

11. The process of example independent or dependent embodiment 1 wherein at least a portion of the two phase fluid comprises a liquid phase when displacing at least a portion of the at least partially insoluble fluid.

12. The process of example independent or dependent embodiment 1 wherein said separation comprises a density-based liquid-liquid separation, or a surface tension based liquid-liquid separation, or any combination thereof.

13. A process for installing a two phase fluid comprising:
Transferring at least a portion of a fluid comprising an at least a partially insoluble fluid into a heat transfer loop to displace a least a portion of a fluid comprising a two phase fluid from the heat transfer loop wherein at least a portion of the two phase fluid comprises a liquid phase or liquid state; and
Separating a portion of the two phase fluid from a portion of the at least partially insoluble fluid.

14. The process of example independent or dependent embodiment 13 wherein the two phase fluid comprises one or more or any combination of the following: a hydrocarbon, or propane, or butane, or pentane, or hexane, or dimethyl ether, or methyl formate, or propylene, or butylene, or a natural refrigerant.

15. The process of example independent or dependent embodiment 13 wherein the at least partially insoluble fluid comprises water.

16. The process of example independent or dependent embodiment 13 further comprising transferring at least a portion of an inert gas into the heat transfer loop to displace at least a portion of the at least partially insoluble fluid from the heat transfer loop.

17. The process of example independent or dependent embodiment 16 wherein the inert gas comprises nitrogen, or argon, or carbon dioxide, or helium, or neon, or noble gas, or a mixture thereof.

18. The process of example independent or dependent embodiment 16 wherein an inert gas comprises a gas with a concentration of diatomic oxygen less than 5% by volume.

19. The process of example independent or dependent embodiment 16 wherein a portion of the at least partially insoluble fluid is purged from the heat transfer loop with an inert gas.

20. The process of example independent or dependent embodiment 19 wherein said purging with an inert gas is paused when the concentration of at least partially insoluble fluid vapor within, or exiting the heat transfer loop in the fluid comprising the inert gas is less than 1,000 PPM.

21. The process of example independent or dependent embodiment 16 wherein the concentration of the two phase fluid vapor in the inert gas within, or exiting the heat transfer loop in the fluid comprising the inert gas is less than 100 PPM.

### ADDITIONAL DETAILED DESCRIPTION

The power density of GPUs and CPUs have been increasing. In recent years, the power density of leading GPUs and CPUs have reached a level where cooling with air becomes challenging due to the limited mass transfer (low density) and specific heat capacity of air. Computing systems have transitioned from using air as a cooling fluid to higher density, higher heat capacity fluids, especially for high power density components, such as GPUs and CPUs. For example, some computing systems have shifted to liquid cooling. For example, some computing systems have shifted to using liquid cooling at a single phase, such as liquid water, or glycol water mixtures, or oils. With the continued increase in high performance GPU and CPU power density, the cooling capacity of single phase liquids has also become limiting. In some applications, oils have become unable to sufficiently cool high performance GPUs and CPUs due to the relative low specific heat capacity of oils. In some applications, water must be cooled to lower temperatures to sufficiently cool high performance GPUs and CPUs due to the need to increase the heat carrying capacity of water, even with water's very high specific heat capacity and heat carrying capacity among single phase liquid. Cooling water to a lower temperature increases the energy or power required to cool a GPU or CPU, increasing data center electricity consumption, which is problematic from an economic and environmental perspective.

Two phase fluids, which may comprise a liquid which boils or vaporizes into a gas when heated, may possess a greater cooling density or heat carrying capacity than single phase fluids due to the heat absorbed in the latent phase change from a liquid to a gas. Two phase systems suffer from fluid handling issues, including inherent leakage or fluid losses, especially during installation and maintenance of components. There is a significant need for two phase systems which can better avoid or minimize fluid leakage or losses. Additionally, two phase fluids in the art generally must be highly non-flammable due to exposure to high power electronics and air. As a result, two phase fluids are historically expensive, highly custom chemicals which have two phase properties without flammability. In the art, two phase fluids employed in cooling computers are fluorocarbons or fluorocarbon derivatives. These fluorocarbons and fluorocarbon derivatives are expensive, which is especially costly due to losses and leakage. Potentially even more problematic, the fluorocarbons and fluorocarbon derivatives are possess very high global warming potential (in some cases greater than 5,000 GWP or greater than 5,000× the potency of CO2) and are considered ‘forever chemicals.’ As forever chemicals, release of these fluorocarbons and fluorocarbon derivatives may cause long term or permanent damage to the environment, climate, and human health. In recent years, fluorocarbons and fluorocarbon derivatives, including PFAS, have received widespread bans due to their negative environmental, climate, and human health impacts. It is clear there is a significant desire for two phase cooling systems with less losses or leakage. It is also clear there is a significant desire for two phase cooling systems which are independent of or do not necessitate the use of fluorocarbons and fluorocarbon derivatives or PFAS.

There are abundant, low cost two phase fluids (which may also possess dielectric properties or may comprise a liquid dielectric), however these fluids are flammable. For example, some hydrocarbons, such as, including, but not limited to, n-butane, or iso-pentane, or n-pentane, or cyclopentane, or mixtures thereof, comprise high energy efficiency two phase fluids or refrigerants. Some of these fluids may also be non-toxic, not forever chemicals, and may possess ultra-low or no global warming potential. Employing some refrigerants may be ideal in two phase computer cooling, if, for example, highly effective systems and methods for preventing ignition or fire formation and leakage are developed.

2-phase fluid may refer to a fluid, which, when operated in a cooling system, may change reversibly from a liquid to a gas and/or from a gas to a liquid. In some embodiments, 2-phase fluids may be at more than one fluid state simultaneously, such as a gas and a liquid simultaneously. Referring to a fluid or chemical as a 2-phase fluid does not imply the fluid is necessarily at 2-phases simultaneously. For example, a fluid may be referred to as a 2-phase fluid, even if the 2-phase fluid mentioned in the system or process is entirely at a liquid phase, or entirely at a gas phase. For example, a fluid may be referred to as a 2-phase fluid, even if the 2-phase fluid mentioned in the specific location in a system or process is entirely at a liquid phase, or entirely at a gas phase.

Some embodiments of the present invention may pertain to systems and methods for 2-phase fluid cooling.

Some embodiments may comprise systems and methods for installing and/or removing 2-phase fluid from a heat transfer system, or cooling system, or heating system, or any combination thereof to inherently reduce or prevent potential release of 2-phase fluid vapor. Some embodiments may comprise a fluid displacement system or process which reduces potential contact of 2-phase fluid with air or gaseous fluids by enabling 2-phase fluid to be added or removed from a system, or to be installed or deinstalled from a system, or any combination thereof by displacement with a liquid-state fluid. In some embodiments, displacement of a 2-phase fluid with a liquid-state fluid may allow for the removal or deinstallation of the 2-phase fluid while preventing the evaporation into a gas or gas mixture due to the potential liquid-liquid interface with the liquid state fluid. In some embodiments, installing 2-phase fluid by transferring or pumping 2-phase fluid into a heat transfer system to displace a liquid-state fluid in the heat transfer system, may allow for the addition or installation of the 2-phase fluid while preventing the evaporation of 2-phase fluid into a gas or gas mixture due to the potential liquid-liquid interface with the liquid state fluid. It may be desirable to prevent evaporation of 2-phase fluid to, for example, reduce potential fire risk, or reduce potential emissions of 2-phase fluid into the environment, or reduce potential losses of 2-phase fluid, or economic cost of losses of 2-phase fluid, or any combination thereof. It may be desirable to enable the installation or deinstallation of 2-phase fluid in a manner which may reduce fluid losses, or prevent exposure to 2-phase fluid vapors, or prevent evaporation of 2-phase fluid, or prevent exposure of 2-phase fluid to air or oxygen within or near an electronic environment, or any combination thereof.

For example, in some embodiments, it may be desirable for the liquid-state fluid, which may displace the 2-phase fluid, to comprise a fluid which may be insoluble in or practically insoluble in or possesses very low solubility in the two phase fluid. For example, in some embodiments, it may be desirable for the liquid-state fluid, which may displace the 2-phase fluid, to comprise a fluid which has a solubility in the 2-phase fluid of less than 10 grams of liquid state fluid to 1,000 grams of 2-phase fluid, or 1 gram of liquid state fluid to 1,000 grams of 2-phase fluid, or 0.1 gram of liquid state fluid to 1,000 grams of 2-phase fluid, or any combination thereof. In some embodiments, it may be desirable for liquid-state fluid to comprise a fluid which has a boiling point temperature higher than the boiling point temperature of the 2-phase fluid, or a vapor pressure less than the vapor pressure of the 2-phase fluid at the same temperature, or any combination thereof. In some embodiments, it may be desirable for the liquid-state fluid to comprise a fluid with a boiling point temperature for example, including, but not limited to, greater than one or more or any combination of the following: 70 degrees Celsius, or 80 degrees Celsius, or 90 degrees Celsius, 95 degrees Celsius, or 99 degrees Celsius, or 100 degrees Celsius. In some embodiments, it may be desirable for a 2-phase fluid to comprise a fluid with a boiling point at the pressure in the heat transfer system to be near or about the same as the temperature range which cooling, or heating, or heat transfer, or any combination thereof is desired or required, plus or minus heat transfer or heat exchanger delta-T or approach or heat exchange temperature difference. In some embodiments, it may be desirable for systems or processes to operate at pressures near atmospheric pressure, or a total pressure, for example, less than, including, but not limited to, one or more or any combination of the following: 1 Bar, or 1.5 Bar, or 2 Bar, or 2.5 Bar, or 3 Bar, or 3.5 Bar, or 4 Bar, or 4.5 Bar, or 5 Bar. In some embodiments, it may be desirable for systems or processes to operate at a relatively low pressure or pressure near atmospheric pressure to, for example, reduce the potential cost, or improve safety, or reduce energy consumption, or any combination thereof. In some embodiments, it may be desirable for the 2-phase fluid to comprise a fluid which has a boiling point temperature lower than the boiling point temperature of the liquid-state fluid, or a vapor pressure greater than the vapor pressure of the liquid-state fluid at the same temperature, or any combination thereof. In some embodiments, it may be desirable for the two-phase fluid to comprise a fluid with a boiling point temperature for example, including, but not limited to, less than one or more or any combination of the following: −10 degrees Celsius, or 0 degrees Celsius, or 5 degrees Celsius, or 10 degrees Celsius, or 15 degrees Celsius, or 20 degrees Celsius, or 25 degrees Celsius, or 30 degrees Celsius, or 35 degrees Celsius, or 40 degrees Celsius, or 45 degrees Celsius, or 50 degrees Celsius, or 55 degrees Celsius, or 60 degrees Celsius, or 65 degrees Celsius, or 70 degrees Celsius, or 80 degrees Celsius, or 90 degrees Celsius, 95 degrees Celsius, or 99 degrees Celsius, or 100 degrees Celsius. In some embodiments, for example, a suitable 2-phase fluid may comprise, for example, Pentane, and a suitable liquid-state fluid with very low solubility or practically insolubility in the 2-phase fluid may comprise water. In some embodiments, for example, a suitable 2-phase fluid may comprise, for example, an inert fluorocarbon, and a suitable liquid-state fluid with very low solubility or practically insolubility in the 2-phase fluid may comprise water. In some embodiments, for example, a suitable 2-phase fluid may comprise, for example, methanol, and a suitable liquid-state fluid with very low solubility or practically insolubility in the 2-phase fluid may comprise a mineral oil or hydrocarbon oil. In some embodiments, for example, a suitable 2-phase fluid may comprise, for example, ammonia, and a suitable liquid-state fluid with very low solubility or practically insolubility in the 2-phase fluid may comprise mineral oil or hydrocarbon oil.

In some embodiments, it may be desirable for the 2-phase fluid and the liquid-state fluid to comprise fluids with different densities. For example, in some embodiments, it may be desirable for the 2-phase fluid and the liquid-state fluid to comprise fluids with different densities because, including, but not limited to, one or more or any combination of the following: to enable a defined liquid-liquid interface between the 2-phase fluid and the liquid-state fluid during fluid displacement, or to prevent or reduce potential mixing of the 2-phase fluid and the liquid-state fluid, or to enable gravitational separation of the 2-phase fluid and the liquid-state fluid if needed or desired, or to enable the use of density-driven or density sensitive check valves or flow valves, or to enable the displacement of one fluid with another fluid, or to enable the pumping or transfer of each fluid from difference directions or difference elevations, or to enable the transfer of each fluid from opposing or difference elevation directions (for example: a low density fluid displacing from a higher elevation to a lower elevation and a high density fluid being displaced from a higher elevation to a lower elevation, or a high density fluid displacing from a lower elevation to a higher elevation and a low density fluid being displaced from a lower elevation to a higher elevation), or any combination thereof. A low density fluid may comprise a fluid with a density less than a high density fluid. A high density fluid may comprise a fluid with a density greater than a low density fluid. For example, in some embodiments, a 2-phase fluid may have a density less than the density of a high density fluid and/or the 2-phase fluid may comprise a low density fluid. For example, in some embodiments, a liquid-state fluid may have a density less than the density of a high density fluid and/or the liquid-state fluid may comprise a low density fluid. For example, in some embodiments, a 2-phase fluid may have a density greater than the density of a low density fluid and/or the 2-phase fluid may comprise a high density fluid. For example, in some embodiments, a liquid-state fluid may have a density greater than the density of a low density fluid and/or the liquid-state fluid may comprise a high density fluid. In some embodiments, for example, a potentially suitable 2-phase fluid comprising a low density fluid may comprise pentane, and, for example, a potentially suitable liquid state fluid comprising a high density fluid may comprise water. In some embodiments, for example, a potentially suitable 2-phase fluid comprising a high density fluid may comprise a fluorocarbon, and, for example, a potentially suitable liquid state fluid comprising a low density fluid may comprise water.

Some embodiments may relate to systems and methods for safely removing 2-phase fluid from a heat transfer system. Some embodiments may relate to systems and methods for safely removing 2-phase fluid from a cooling system, such as a direct-to-chip or cold plate cooling system. Some embodiments may relate to systems and methods for safely removing 2-phase fluid from a cooling system, such as direct-to-chip or cold plate cooling system before, for example, maintenance, or inspection, or replacing, or any combination thereof. Some embodiments may relate to systems and methods for safely adding 2-phase fluid into a heat transfer system. Some embodiments may relate to systems and methods for safely adding 2-phase fluid from a cooling system, such as a direct-to-chip or cold plate cooling system. Some embodiments may relate to systems and methods for safely adding 2-phase fluid from a cooling system, such as direct-to-chip or cold plate cooling system before, for example, maintenance, or inspection, or replacing, or any combination thereof. Some embodiments may employ the displacement of a 2-phase fluid from a heat transfer system using a low solubility fluid, which may be non-flammable. Some embodiments may employ the displacement of a 2-phase fluid from a heat transfer system using a low solubility fluid, which may be non-flammable, such as, for example, water. Some embodiments may add or install a 2-phase fluid from in a heat transfer system by displacing a low solubility fluid in the heat transfer system with the 2-phase fluid. Some embodiments may add or install a 2-phase fluid from in a heat transfer system by displacing a low solubility fluid in the heat transfer system, such as water, with the 2-phase fluid. Some embodiments also enable the installation and deinstallation of fluorocarbon based dielectric two phase fluids without releasing vapors or exposing people to the vapors. Such fluorocarbon based dielectric two phase fluids include the GALDAN™ products available from Solvay and the NOVEC™ products available from 3M.

In some embodiments, removing a 2-phase fluid may comprise displacing the 2-phase fluid in a heat transfer system with an insoluble or low solubility liquid, such as water. In some embodiments, the low solubility or insoluble liquid, such as water, may be displaced by an inert gas. In some embodiments, displacing the 2-phase fluid with a low solubility or insoluble liquid, such as water, then displacing said low solubility or insoluble liquid with an inert gas may substantially prevent or reduce the potential presence of 2-phase fluid or 2-phase fluid vapor in the inert gas. In some embodiments, displacing the 2-phase fluid with a low solubility or insoluble liquid, such as water, then displacing said low solubility or insoluble liquid with an inert gas may substantially prevent or reduce the potential presence of 2-phase fluid or 2-phase fluid vapor in the inert gas, which may be beneficial during maintenance or other operations which may expose the computing system to oxygen.

In some embodiments, adding a 2-phase fluid may comprise displacing an inert gas with a low solubility or insoluble liquid, such as water, then displacing the low solubility or insoluble liquid, such as water, with the 2-phase fluid. In some embodiments, displacing the inert gas with a low solubility or insoluble liquid, such as water, then displacing said low solubility or insoluble liquid with 2-phase fluid may substantially prevent or reduce the potential presence of 2-phase fluid or 2-phase fluid vapor in the inert gas. In some embodiments, displacing the inert gas with a low solubility or insoluble liquid, such as water, then displacing said low solubility or insoluble liquid with 2-phase fluid may substantially prevent or reduce the potential presence of 2-phase fluid or 2-phase fluid vapor in the inert gas, which may be beneficial during maintenance or other operations which may expose the computing system to oxygen.

In some embodiments, an inert gas may comprise a gas in which a 2-phase fluid may not be prone to catching on fire or ignition. For example, some inert gases may include, but are not limited to, one or more or any combination of the following: diatomic nitrogen, or nitrogen gas, or argon, or helium, or neon, or carbon dioxide.

Some embodiments may relate to systems and methods for safe enclosures and operations of a 2-phase heat transfer system. Some embodiments may relate to systems and methods for safe enclosures and operations of a 2-phase heat transfer system, for example, wherein the 2-phase fluid may be flammable in the presence of oxygen or air. Some embodiments may relate to enclosures which may enable a low oxygen or substantially oxygen free atmosphere or an atmosphere comprising an inert gas, which may enable the safe operation of cooling systems with 2-phase fluids. Some embodiments may relate to enclosures with inert gas cooling and recirculation to cool, for example, other computer components, such as memory, and/or a 2-phase cold plate or direct to chip cooling system for cooling GPU or CPU. Some embodiments may relate to separate cooling of the GPU or CPU from the cooling of other computer components, such as, for example, cooling a GPU or CPU with a 2-phase fluid while cooling other computer components, such as computer memory, with an inert gas or an immersed inert gas. In some embodiments, if desired, the inert gas or recirculating inert gas may be cooled to a different temperature than the 2-phase fluid. In some embodiments, heat may be transferred from an enclosure using, for example, chilled water or other non-flammable and/or single phase cooling fluid. For example, in some embodiments, the 2-phase fluid may be cooled by heat exchange with chilled water or other non-flammable and/or single phase cooling fluid, and the inert gas or recirculating inert gas may be cooled by heat exchange with chilled water or other non-flammable and/or single phase cooling fluid. In some embodiments, the cooling of the 2-phase fluid may be conducted using a different heat exchanger than the cooling of the inert gas. In some embodiments, the cooling of the 2-phase fluid may be conducted using the same heat exchanger as the cooling of the inert gas.

Some embodiments may relate to immersion cooling systems comprising 2-phase fluids. Some embodiments may comprise immersion cooling systems wherein computers or computing systems are immersed in the liquid phase of a 2-phase fluid. In some embodiments, the computer and 2-phase fluid may be located within an enclosure, wherein the enclosure comprises a liquid phase bath comprising 2-phase fluid at a liquid phase and a gas headspace (which may be above the liquid phase bath) comprising 2-phase fluid at a gas phase. In some embodiments, as heat is generated by the computer, 2-phase fluid boils in the liquid bath, forming gas phase 2-phase fluid which transfers into the gas head space due to the density difference between gas phase and liquid phase, then at least a portion of the gas phase 2-phase fluid may be condensed into a liquid phase by cooling heat exchange with, for example, chilled water, and the condensed liquid phase 2-phase fluid may be transferred into the liquid bath. In some embodiments, the immersion cooling enclosure comprising 2-phase fluid may be in a room, wherein gas occupying the room may comprise an inert gas. For example, an immersion cooling enclosure may be located in a room occupied by inert gas. In some embodiments, the building or room may have a system to ensure the inert gas pressure inside the room is greater than the external or outdoor air pressure and/or to recirculate or purify inert gas to, for example, remove at least a portion of any contaminants, such as leaked two phase fluid vapor.

Some embodiments may relate to the transfer of computing equipment, or other equipment, or personnel, or any combination thereof into a room, or building, or enclosure, or any combination thereof storing or operating 2-phase fluid cooling or other heat transfer equipment.
Note: Design process in a manner to enable/facilitate the displacement of a low density fluid with a high density fluid
   Displaced fluid outlet
   Enable HDL to be added from lower elevation or from the bottom
   Enable LDL to be added from a higher elevation or from the bottom
Note: Density driven valve which prevents low density fluid from entering high density fluid storage and high density fluid from entering low density fluid storage. The valve may comprise a storage container with a mobile material or ball, wherein the mobile material or ball has a density greater than the low density fluid and less than the high density fluid. The valve configured to transfer low density fluid and block high density fluid, the material or ball will float on the high density fluid to plug/close fluid flow. The valve configured to transfer high density fluid and block low density fluid, the material or ball will sink in the low density fluid to plug/close fluid flow.
Note: In some embodiments, the heat transfer loop may operate with an internal pressure at least partially below the pressure of atmospheric pressure or the pressure of gases adjacent to the system. [Subambient pressure may prevent release of fluid during leaks or leaks onto electronics] [Subambient pressure may enable the use of methanol as a low density fluid by lowering the boiling point of the methanol to a boiling point near the desired cooling temperature by lowering the total pressure in the tubing or piping or heat exchanger or heat transfer loop.]
Note: In some embodiments, an inert gas, such as N₂(g), may be pumped or purged into the cooling system or piping or heat exchangers to dry or evaporate at least a portion of any residual water vapor, or any residual 2-phase fluid, or any combination thereof. In some embodiments, the gases exiting the system or exiting the gas purge may be analyzed, or measured using gas sensors, or any combination thereof to determine the concentration of any water vapor, or any 2-phase fluid vapors, or any combination thereof. In some embodiments, purging with an inert gas, such as N₂(g), may continue until the concentration of any gaseous water vapor, or any 2-phase fluid, or any combination thereof in the exiting purge gases may be less than a desired concentration threshold, or less than a detection limit, or any combination thereof.
Note: In some embodiments, a cabinet or storage container housing or containing at least a portion of low density fluid may comprise a pressurized container or housing. For example, in some embodiments, the internal pressure of the cabinet may be maintained at a pressure greater than ambient pressure, or atmospheric pressure, or 1 bar, or 1.1 Bar, or 1.2 Bar, or 1.5 Bar, or 2 Bar, or 2.5 Bar, or 3 Bar. In some embodiments, the internal gas pressure may comprise a safety feature, wherein the inherent greater pressure inside the rack may prevent the cabinet or enclosure from opening by personnel until depressurization occurs. In some embodiments, the gas pressurized may comprise an inert gas, such as nitrogen gas, or argon gas, or carbon dioxide gas. In some embodiments, a higher internal pressure than ambient pressure may enable leak prevention or inherent anti-leak system while enabling the use of higher fluid pressure drops or greater pump power, which may increase potential heat removal, or heat transfer, or rack density, or any combination thereof.
In some embodiments an inert gas chamber, or inert gas box, or an inert gas enclosure may be located inside a building. In some embodiments, each chamber or enclosure may be self contained, wherein 2-phase fluid may remain in the enclosure. For example, heat may be transferred from the enclosure by heat exchanging 2 phase fluid in the enclosure, or inert gas in the enclosure, or any combination thereof with chilled water. Cold chilled water supply may be transferred to the enclosure and warm chilled water return may be transferred from the enclosure to a cooling system or outside the facility or building for heat removal or chilling or cooling.
In some embodiments, if equipment needs to be maintained or replaced or inspected, in some embodiments, 2-phase fluid may be removed or displaced from the computer system using, for example, an insoluble liquid and/or an inert gas, or with a negative pressure or vacuum pressure system, and/or the 2-phase fluid may be stored in a sub-compartment or tank which may comprise a contained or safe or inert gas headspace. Power may be shutoff to the enclosure and electronics may be powered down. The enclosure may be opened, which may expose electronics and equipment to air or oxygen. When the work requiring opening the enclosure is complete or the computer operations may return, the enclosure may be closed, then oxygen or air or other gases may be vacuum extracted or purged with an inert gas or otherwise removed or any combination thereof, then the 2-phase fluid may displace insoluble liquid or inert gas from the cooling system.
In some embodiments:
   2-phase fluid may be evacuated or transferred from a direct to chip cooling system or pipe and heat exchanger network by transferring low solubility liquid, such as water, or deionized water, or glycol-water, or PG25, or glycerol-water, or any combination thereof, into the direct to chip cooling system. The transferring of low solubility liquid may result in the displacement of 2-phase fluid due to, for example, the low solubility or insolubility of the 2-phase fluid in water, and/or the potential significant difference in density between the 2-phase fluid and water. In some embodiments, it may be desirable for the insoluble liquid to be at a temperature less than the boiling point of the 2-phase fluid to enable the displacement of the 2-phase fluid as a liquid. In some embodiments, displaced 2-phase fluid may be transferred into a displaced 2-phase fluid holding tank, which may be in a sectioned off enclosure or in an inert gas environment or inert gas atmosphere to further reduce, for example, fire risk. In some embodiments, it may be desirable for the insoluble liquid, such as water, employed in the displacement to be deionized and/or deoxygenated and/or to possess a reduced or substantially lower concentration of dissolved oxygen than the concentration of dissolved oxygen in general municipal water.
   2-phase fluid may be added or installed into a direct to chip system or heat transfer system by pumping or transferring pentane into the direct to chip system, displacing water and/or transferring water into a water storage tank. Gas phase 2-phase fluid may be regenerated in the portion of the 2-phase system designed to be at gas phase by turning on the power and beginning process operations, or by providing heat, or both, which may result in the 2-phase fluid boiling, forming a 2-phase fluid gas, wherein the 2-phase fluid gas displaces at least a portion of the liquid 2-phase fluid present in the portions of the system designed to operate at gas phase, and/or the displaced portion of liquid 2-phase fluid may be transferred into the 2-phase fluid holding tank or storage tank or storage enclosure.
   In some embodiments, at least a portion of 2-phase fluid leaks may be detected by monitoring or measuring the concentration of 2-phase fluid vapor in the inert gas, or other headspace gas, in an enclosure.
In some embodiments, if a fire were to occur in an enclosure, the enclosure may be closed and/or an inert gas system or a fire suppression system in the enclosure may suppress the fire and/or isolate the first to the affected enclosure.
Example Pathway for Safely Removing and Installing 2-Phase Fluid in a Heat Transfer System
   Removing 2-Phase Fluid
      Insoluble liquid or low solubility liquid, such as water, is pumped or otherwise transferred into a cooling or heat transfer network or direct to chip cooling system, displacing the 2-phase fluid present. Displaced 2-phase fluid may transfer into a holding tank.
   Addition or Return of the 2-Phase Fluid
      2-Phase fluid is pumped or otherwise transferred into a cooling or heat transfer network or direct to chip cooling system, displacing the insoluble liquid or low solubility liquid, such as water. Displaced insoluble liquid or low solubility liquid may transfer into a holding tank.
      In some embodiments, 2-phase fluid may be heated, such as, for example, by restarting computing processes or by another heat source, which may result in the formation of at least a portion of 2-phase fluid gas phase or vapor, which may displace at least a portion of liquid phase 2-phase fluid in the portions of the system which may be designed to operate with gas phase 2-phase fluid. Displaced 2-phase fluid may transfer into a holding tank.
Example Pathway for Safely Removing and Installing 2-Phase Fluid in a Heat Transfer System
   Removing 2-Phase Fluid
      Insoluble liquid or low solubility liquid, such as water, is pumped or otherwise transferred into a cooling or heat transfer network or direct to chip cooling system, displacing the 2-phase fluid present. Displaced 2-phase fluid may transfer into a holding tank.
      An inert gas is transferred into the system, displacing the insoluble liquid or low solubility liquid, such as water.
         The present embodiment may enable liquids and flammable fluids to be substantially absent from the computer or computer cooling network or system during maintenance, or inspection, or replacement.
         In some embodiments, the inert gas may purge the system to dry or remove at least a portion of any residual water.
   Addition or Return of the 2-Phase Fluid
      2-Phase fluid is pumped or otherwise transferred into a cooling or heat transfer network or direct to chip cooling system, displacing the inert gas.
         Displaced inert gas, which may comprise at least a portion of 2-phase fluid vapor, may undergo further treatment or processing to separate or recover at least a portion of said 2-phase fluid vapor. For example, said displaced inert gas may be contacted with cryogenic liquids, or heat exchanged with cryogenic liquids, or may be compressed, or may be cooled.
      In some embodiments, 2-phase fluid may be heated, such as, for example, by restarting computing processes or by another heat source, which may result in the formation of at least a portion of 2-phase fluid gas phase or vapor, which may displace at least a portion of liquid phase 2-phase fluid in the portions of the system which may be designed to operate with gas phase 2-phase fluid. Displaced 2-phase fluid may transfer into a holding tank.
Example Pathway for Safely Removing and Installing 2-Phase Fluid in a Heat Transfer System
   Removing 2-Phase Fluid
      Insoluble liquid or low solubility liquid, such as water, is pumped or otherwise transferred into a cooling or heat transfer network or direct to chip cooling system, displacing the 2-phase fluid present. Displaced 2-phase fluid may transfer into a holding tank.
      An inert gas is transferred into the system, displacing the insoluble liquid or low solubility liquid, such as water.
         The present embodiment may enable liquids and flammable fluids to be substantially absent from the computer or computer cooling network or system during maintenance, or inspection, or replacement.
         In some embodiments, the inert gas may purge the system to dry or remove at least a portion of any residual water.
   Addition or Return of the 2-Phase Fluid
      Insoluble liquid or low solubility liquid, such as water, is pumped or otherwise transferred into a cooling or heat transfer network or direct to chip cooling system, displacing the inert gas.
      2-Phase fluid is pumped or otherwise transferred into a cooling or heat transfer network or direct to chip cooling system, displacing the insoluble liquid or low solubility liquid, such as water. Displaced insoluble liquid or low solubility liquid may transfer into a holding tank.
      In some embodiments, 2-phase fluid may be heated, such as, for example, by restarting computing processes or by another heat source, which may result in the formation of at least a portion of 2-phase fluid gas phase or vapor, which may displace at least a portion of liquid phase 2-phase fluid in the portions of the system which may be designed to operate with gas phase 2-phase fluid. Displaced 2-phase fluid may transfer into a holding tank.
In some embodiments, inert gas enclosures or chambers may be connected to a facility inert gas system. For example:
   Facility inert gas for input into enclosures may be available to the enclosures or piped to the enclosures at a pressure greater than atmospheric pressure or greater than the pressure of gas inside the enclosure.
   Inert gas removal or gas removal from the enclosures may be
   In some embodiments, gas removal comprising non-inert gases, or air, may be transferred through a separate pipe or to a separate pathway than gas removal comprising inert gas removal. In some embodiments, facility non-inert gas removal may comprise a pipe or network comprising a vacuum or a pressure lower than the gas pressure inside the enclosure or atmospheric pressure. In some embodiments, facility inert gas removal may comprise a pipe or network comprising a vacuum or a pressure lower than the gas pressure inside the enclosure or atmospheric pressure. Inert gas removal and/or non-inert gas removal may be treated to remove at least a portion of any contaminants, such as, for example, 2-phase fluid vapor.
   The flow rate of inert gas into and out of an enclosure may be controlled at a facility level, or at an enclosure level, or by an enclosure, or any combination thereof.
   When an enclosure contains oxygen and/or other non-inert gas above or near a threshold concentration, it may be desirable to purge the enclosure with inert gas and/or transfer purge gases or removed gases from the enclosure into the non-inert gas removal system or network. In some embodiments, non-inert gas may be vented from the facility using the non-inert gas removal system or network.
   In some embodiments, inert gas in an enclosure may be cooled to enable the cooling of, for example, electronic components or other computer components, such as computer memory or switches or power conversions. In some embodiments, inert gas cooling may be conducted at an individual enclosure level, wherein heat may be removed from the inert gas by, for example, heat exchange with facility cooling water.
   In some embodiments, the rate of inert gas circulation or cooling or flow rate of inert gas for cooling in each enclosure may be independent from or different from the rate of inert gas entering and/or exiting the enclosure.
   In some embodiments, facility inert gas system may remove at least a portion of contaminants and/or recover at least a portion of any 2-phase fluid vapor, if applicable, before, for example, recirculating the inert gas.
   In some embodiments, the inert gas system may be conducted entirely at an enclosure level.
   In some embodiments, an enclosure may comprise a bench-top unit, or a module, or a mobile unit, or a floor based unit, or a floor to ceiling unit, or a section of a room, or an entire room, or an entire floor, or an entire building.
   In some embodiments, the 2-phase fluid holding tank or storage tank may be stored or located in an enclosure or space which may comprise or may be occupied by an inert gas to, for example, minimize fire risk. In some embodiments, the 2-phase fluid holding tank may be closed off by emergency shutoff valves, or may employ an inert gas fire suppression system, or may employ other fire suppression systems, or may employ a fire wall, or any combination thereof.
Pentane, butane, isomers thereof, and other similar hydrocarbons may not be or may be less prone to biofouling scaling, corrosion or degradation, relative to, for example, water.
Inert gas atmosphere
   Concentration of oxygen, O2 maintain below threshold for flammability.
   Positive pressure room, which may comprise a total pressure in the room, greater than the external or outside, atmospheric air pressure
   Occupants may we're air things are circles are rebreather to enter, or operate in the room
      Other advantages include an extra layer of security (unsafe for people without appropriate equipment to enter facility)
      Another atmosphere, may also reduce corrosion in biofouling and prevent insect growth or mold growth within the facility, which may also enable the room to be at a higher temperature, if desired
In some embodiments, the inert gas may comprise an Airgas, such as nitrogen or argon or carbon dioxide. Air separation units supplying make up nitrogen or argon may be located on site or on a different location.
In some embodiments, nitrogen, or other Airgas may be recirculated. At least a portion of non-inert gases, such as oxygen or to phase fluid vapor may be recovered or removed.
Emergency measures
   In the event of a power outage, for example, liquid nitrogen tanks, or compressed nitrogen tanks, or compressed inert gas tanks, or liquid inert gas may store inert gas, which may be released or continuously supplied, which may be passive, to the enclosure, or the facility or both.
   In the event of a two phase fluid leak or release:
      Two phase fluid vapor may be recovered, at least partially, using a cryogenic liquid in heat exchange or direct fluid contact
      Venting of positive pressure with nitrogen or inert gas
      Retrieval or removal of the least portion of two phase fluid by displacement with an insoluble liquid, such as water
      Negative pressure or vacuum retrieval of at least a portion of two phase fluid
      Emergency shut off valve upon leak detection minimizing amount of two phase fluid potentially leaked.
In some embodiments, for systems or methods to be employed to minimize or reduce the dissolved oxygen concentration in the chilled water, or glycol-water, or propylene glycol-water, or PG25, or insoluble liquid, or low solubility liquid, or liquid with low solubility in the 2-phase fluid, or any combination thereof, to, for example, prevent the presence of oxygen or the transfer of oxygen into the computer environment or inert gas environment. In some embodiments, direct oxygen removal or direct dissolved oxygen removal systems, such as systems using catalysts and hydrogen oxidation, may be employed. In some embodiments, oxygen scavengers or oxygen scavenger salts may be employed. Dissolved oxygen concentration may be monitored. Coolant distribution unit.
In some embodiments, equipment entering an inert as environment may be purged with inert gas in a closed enclosure, or room, or may be exposed to vacuum or sub-ambient pressure, or placed in a sealed container, or any combination thereof. In some embodiments, equipment or people entering an inert gas environment may first pass through a decontamination room, which may purge or otherwise remove oxygen and/or other gases.
Exhaled gases may be recycled or recirculated in the suit (e.g. rebreather, or removing CO2 and recirculating gas) or may exit the suit through or snorkel or may be compressed into a separate tank comprising storage for exhaled gases.
Enclosures or boxed may cool memory or other electronics using inert gas in an enclosure or room, which may be cooled using a gas coil.
Inert gas fire suppression system
In some embodiments, an entire room or building may be occupied may inert gas or may comprise an inert gas structure or an inert gas enclosure.

### Notes

Note: In some embodiments, a heat transfer loop may be employed to remove heat or cool a computer chip, or a server, or a GPU, or a CPU, or memory, or a computing system, or a server rack, or a case, or any combination thereof. In some embodiments, some computing components may have limitations for operating temperature or desired operating temperature to ensure, for example, including, but not limited to, one or more or any combination of the following: proper or desired performance, or prevent degradation, or longevity, or any combination thereof. For example, in some embodiments, it may be desirable for a GPU or a CPU temperature to be less than or equal to, for example, including, but not limited to, one or more or any combination of the following: 200° C., or 175° C., or 150° C., or 140° C., or 130° C., or 120° C., or 110° C., or 100° C., or 90° C., or 80° C., or 70° C., or 60° C., or 50° C. For example, in some embodiments, it may be desirable for a case temperature to be a temperature less than or equal to, for example, including, but not limited to, one or more or any combination of the following: 200° C., or 175° C., or 150° C., or 140° C., or 130° C., or 120° C., or 110° C., or 100° C., or 90° C., or 80° C., or 70° C., or 60° C., or 50° C. In some embodiments, it may be desirable for the internal pressure in the heat transfer loop and/or the vapor pressure of the two phase fluid to be configured such that the two phase fluid boils or phase transitions from a liquid to a gas phase at a temperature or in a temperature range which may result in the case temperature being cooled to a temperature at or near or within a desired temperature range. For example, in some embodiments, a desired case temperature may be 80° C. and a heat transfer loop may be configured such that the phase transition temperature of a two phase fluid comprising n-Pentane of 62° C. may be required to achieve the desired case temperature, and/or the internal pressure in at least a portion of the heat transfer loop may comprise about 2.27 bar. For example, in some embodiments, a desired case temperature may be 70° C. and a heat transfer loop may be configured such that the phase transition temperature of a two phase fluid comprising n-Pentane of 36° C. may be required to achieve the desired case temperature, and/or the internal pressure in at least a portion of the heat transfer loop may comprise about 1.00 bar. For example, in some embodiments, a desired case temperature may be 50° C. and a heat transfer loop may be configured such that the phase transition temperature of a two phase fluid comprising sulfur dioxide of 30° C. may be required to achieve the desired case temperature, and/or the internal pressure in at least a portion of the heat transfer loop may comprise about 4.62 bar.
Note: In some embodiments, the term ‘at least partially insoluble fluid’ may be used interchangeably with the term ‘at least partially insoluble liquid’ and/or the term ‘at least partially insoluble liquid’ may be used interchangeably with the term ‘at least partially insoluble liquid’.
Heat Transfer Loop: In some embodiments, a heat transfer loop may comprise a system or method or facility comprising heat transfer, or cooling, or heating, or thermal storage, or any combination thereof. In some embodiments, a heat transfer loop may comprise a an system or method storing, or transferring, or any combination thereof a heat transfer fluid. In some embodiments, a heat transfer loop may comprise a heat source, or a heat sink, or any combination thereof. In some embodiments, a heat transfer loop may comprise a heat source, or a heat sink, or any combination thereof, wherein a fluid may be transferred between the heat source and heat sink and/or circulated between the heat source and heat sink. In some embodiments, a heat transfer loop may comprise a device or system wherein a fluid may be transferred, or stored, or pumped, or any combination thereof. In some embodiments, a heat transfer loop may comprise, including, but not limited to: a closed loop, or open loop, or hybrid loop, or any combination thereof. In some embodiments, a heat transfer loop may comprise including, but not limited to, one or more or any combination of the following: a cooling loop, or heating loop, or a ground loop, or a direct to chip loop, or a cold plate loop, or a facility water loop, or a data center cooling loop, or a cooling distribution unit heat transfer loop, or a cooling distribution loop, or a CDU loop, or a header, or a branch line, or a pipe, or an electronic component, or a photonic component, or a manifold, or a server rack, or a cold plate, or a heat exchanger, or a plate heat exchanger, or a pump, or pipe, or a conduit, or a channel, or GPU, or a CPU, or a CPU case, or a GPU case, or a chilling loop, or a data center cooling system, or a heat recovery system, or a heat removal system, or a geothermal loop, or a district cooling system, or a district heating system, or a HVAC system, or a plant cooling system, or a plant heating system, or a heating supply, or a cooling supply, or a thermal storage system, or a desalination system, or a solar thermal system, or chemical process cooling, or high power electronics cooling, or heating, or heat transfer, or high density cooling, or high density heating.
Note: In some embodiments, for example, an ‘At least partially insoluble fluid’ may comprise a fluid which may possess a relatively low solubility in, for example, a Two Phase Fluid. For example, in some embodiments, the ‘At least partially insoluble fluid’ may possess a solubility in the two phase fluid less than or equal to, including, but not limited to, one or more or any combination of the following: 0.001 g/kg, or 0.01 g/kg, or 0.05 g/kg, or 0.1 g/kg, or 0.25 g/kg, or 0.5 g/kg, or 0.75 g/kg, or 1 g/kg, or 2 g/kg, or 3 g/kg, or 4 g/kg, or 5 g/kg, or 6 g/kg, or 7 g/kg, or 8 g/kg, or 9 g/kg, or 10 g/kg, or 11 g/kg, or 12 g/kg, or 13 g/kg, or 14 g/kg, or 15 g/kg, or 16 g/kg, or 17 g/kg, or 18 g/kg, or 19 g/kg, or 20 g/kg, or 21 g/kg, or 22 g/kg, or 23 g/kg, or 24 g/kg, or 25 g/kg, or 26 g/kg, or 27 g/kg, or 28 g/kg, or 29 g/kg, or 30 g/kg, or 31 g/kg, or 32 g/kg, or 33 g/kg, or 34 g/kg, or 35 g/kg, or 36 g/kg, or 37 g/kg, or 38 g/kg, or 39 g/kg, or 40 g/kg, or 41 g/kg, or 42 g/kg, or 43 g/kg, or 44 g/kg, or 45 g/kg, or 46 g/kg, or 47 g/kg, or 48 g/kg, or 49 g/kg, or 50 g/kg, or 51 g/kg, or 52 g/kg, or 53 g/kg, or 54 g/kg, or 55 g/kg, or 56 g/kg, or 57 g/kg, or 58 g/kg, or 59 g/kg, or 60 g/kg, or 61 g/kg, or 62 g/kg, or 63 g/kg, or 64 g/kg, or 65 g/kg, or 66 g/kg, or 67 g/kg, or 68 g/kg, or 69 g/kg, or 70 g/kg, or 71 g/kg, or 72 g/kg, or 73 g/kg, or 74 g/kg, or 75 g/kg, or 76 g/kg, or 77 g/kg, or 78 g/kg, or 79 g/kg, or 80 g/kg, or 81 g/kg, or 82 g/kg, or 83 g/kg, or 84 g/kg, or 85 g/kg, or 86 g/kg, or 87 g/kg, or 88 g/kg, or 89 g/kg, or 90 g/kg, or 91 g/kg, or 92 g/kg, or 93 g/kg, or 94 g/kg, or 95 g/kg, or 96 g/kg, or 97 g/kg, or 98 g/kg, or 99 g/kg, or 100 g/kg, or 150 g/kg, or 200 g/kg, or 300 g/kg. For example, in some embodiments, the two phase fluid may exhibit a solubility in the ‘At least partially insoluble fluid’ of less than or equal to, including, but not limited to, one or more or any combination of the following: 0.001 g/kg, or 0.01 g/kg, or 0.05 g/kg, or 0.1 g/kg, or 0.25 g/kg, or 0.5 g/kg, or 0.75 g/kg, or 1 g/kg, or 2 g/kg, or 3 g/kg, or 4 g/kg, or 5 g/kg, or 6 g/kg, or 7 g/kg, or 8 g/kg, or 9 g/kg, or 10 g/kg, or 11 g/kg, or 12 g/kg, or 13 g/kg, or 14 g/kg, or 15 g/kg, or 16 g/kg, or 17 g/kg, or 18 g/kg, or 19 g/kg, or 20 g/kg, or 21 g/kg, or 22 g/kg, or 23 g/kg, or 24 g/kg, or 25 g/kg, or 26 g/kg, or 27 g/kg, or 28 g/kg, or 29 g/kg, or 30 g/kg, or 31 g/kg, or 32 g/kg, or 33 g/kg, or 34 g/kg, or 35 g/kg, or 36 g/kg, or 37 g/kg, or 38 g/kg, or 39 g/kg, or 40 g/kg, or 41 g/kg, or 42 g/kg, or 43 g/kg, or 44 g/kg, or 45 g/kg, or 46 g/kg, or 47 g/kg, or 48 g/kg, or 49 g/kg, or 50 g/kg, or 51 g/kg, or 52 g/kg, or 53 g/kg, or 54 g/kg, or 55 g/kg, or 56 g/kg, or 57 g/kg, or 58 g/kg, or 59 g/kg, or 60 g/kg, or 61 g/kg, or 62 g/kg, or 63 g/kg, or 64 g/kg, or 65 g/kg, or 66 g/kg, or 67 g/kg, or 68 g/kg, or 69 g/kg, or 70 g/kg, or 71 g/kg, or 72 g/kg, or 73 g/kg, or 74 g/kg, or 75 g/kg, or 76 g/kg, or 77 g/kg, or 78 g/kg, or 79 g/kg, or 80 g/kg, or 81 g/kg, or 82 g/kg, or 83 g/kg, or 84 g/kg, or 85 g/kg, or 86 g/kg, or 87 g/kg, or 88 g/kg, or 89 g/kg, or 90 g/kg, or 91 g/kg, or 92 g/kg, or 93 g/kg, or 94 g/kg, or 95 g/kg, or 96 g/kg, or 97 g/kg, or 98 g/kg, or 99 g/kg, or 100 g/kg, or 150 g/kg, or 200 g/kg, or 300 g/kg. In some embodiments, for example, it may be desirable for the at least partially insoluble fluid to have a boiling point greater than the two phase fluid at the same pressure. In some embodiments, for example, it may be desirable for the at least partially insoluble fluid to have a vapor pressure less than the vapor pressure of the two phase fluid at the same pressure. In some embodiments, it may be desirable for the at least partially soluble fluid to be at least partially non-flammable, or to possess a flashpoint greater than 100° C. In some embodiments, it may be desirable for the at least partially insoluble fluid to comprise at least a portion of a liquid phase at atmospheric pressure and room temperature, or for the at least partially insoluble fluid to possess a boiling point greater than 70° C., or 80° C., or 90° C., or 100° C., or any combination thereof. In some embodiments, for example, an at least partially insoluble fluid may comprise, including, but not limited to, one or more or any combination of the following: water, or, deionized water, or municipal water, or tap water, or an aqueous solution, or a brine, or an aqueous base, or an aqueous acid, or an acid, or a base, or a neutral solution, or an organic solvent, or an aqueous organic solvent, or glycol, or aqueous glycol, or alcohol, or aqueous alcohol, or methanol, or aqueous methanol, or an inorganic solvent, or an oil, or a lubricant, or a thermal oil, or a silicon oil, or a mineral oil, or a fluorocarbon fluid, or an halogenated solvent, or a solvent, or a liquid, or carbon dioxide, or sulfur dioxide, or a blend, or a fluid blend.
Note: In some embodiments, a two phase fluid may be at least partially removed from the heat transfer loop using a vacuum. In some embodiments, a two phase fluid may be at least partially removed from the heat transfer loop using a vacuum, then a fluid comprising inert gas, or a liquid, or an at least partially insoluble liquid, or any combination thereof may be transferred into the heat transfer loop.
Note: In some embodiments, for example, a Two Phase Fluid may comprise a fluid which may absorb, or release, or transfer, or any combination thereof at least a portion of heat by phase transitioning from a liquid phase to gaseous phase, or from a gaseous phase to a liquid phase, or any combination thereof. In some embodiments, for example, a Two Phase Fluid may comprise a fluid which may absorb, or release, or transfer, or any combination thereof at least a portion of heat by boiling, or condensing, or any combination thereof. In some embodiments, for example, a Two Phase Fluid may comprise a fluid which may absorb, or release, or transfer, or any combination thereof at least a portion of heat in a heat transfer loop by phase transitioning from a liquid phase to gaseous phase, or from a gaseous phase to a liquid phase, or any combination thereof. In some embodiments, a Two Phase Fluid may be at least partially insoluble in an at least partially insoluble fluid. In some embodiments, a Two Phase Fluid may have a vapor pressure greater than an at least partially insoluble fluid, or a boiling point less than an at least partially insoluble fluid, or any combination thereof. In some embodiments, a Two Phase Fluid may comprise a refrigerant. In some embodiments, in some heat transfer loops, a Two Phase Fluid may at least partially boil or transition from a liquid to a gas phase at a heat source and/or at least partially condense or transition from a gas to a liquid phase at a heat sink or cold source. In some embodiments, the boiling point of a two phase fluid may be tailored or customized to be in the temperature range of heat removed, or of a heat source, or heat sink, or cold source, or any combination thereof, for example, to enable at least a portion of heat transfer or heat transport by phase transitioning from a gas to a liquid, or a liquid to a gas, or any combination thereof. For example, in some embodiments, example two phase fluids may include, but are not limited to, one or more or any combination of the following: natural refrigerants, or refrigerants, or hydrocarbons, or hydrocarbon refrigerants, or hydrofluoroethers, or hydrofluorocarbons, or alkanes, or alkenes, or alkynes.
Note: In some embodiments, for example, a Recoverable Two Phase Fluid may comprise a two phase fluid which may exhibit chemical properties, or physical properties, or other properties, or any combination thereof which may facilitate or enable separation or recovery. In some embodiments, for example, a Recoverable Two Phase Fluid may comprise a two phase fluid which may exhibit chemical properties, or physical properties, or other properties, or any combination thereof which may facilitate or enable separation or recovery or removal of two phase fluid vapor, or may facilitate or enable separation or recovery or removal of two phase fluid vapor from an inert gas or air, or any combination thereof. For example, in some embodiments, a recoverable two phase fluid may possess properties, which may include, but are not limited to, one or more or any combination of the following: acidic pH, or basic pH, or solubility in water, or significantly different solubility than an inert gas or air, or a significantly different boiling point or vapor pressure than an inert gas or air, or difference in chemical reactivity, or reactivity with chemicals which an inert gas or air may be less or non-reactive, or chemical reaction, or significant different melting point, or significantly different deposition point. For example, in some embodiments, at least a portion of a recoverable two phase fluid may be removed from a gas stream comprising air or an inert gas by, for example, absorption in water, or reaction or contact with a basic solution, or reaction or contact with an acidic solution, or reaction or contact with a basic solid, or reaction or contact with an acidic solid, or any combination thereof. For example, in some embodiments, a recoverable two phase fluid comprising ammonia may be at least partially removed from a gas stream by including, but not limited to, one or more or any combination of the following: contact or absorption in water, or by contact or reaction with an aqueous acid, or by contact or reaction with acetic acid, or by contact or reaction with carbon dioxide, or by contact or reaction with sulfuric acid, or by contact or reaction with hydrochloric acid. For example, in some embodiments, a recoverable two phase fluid comprising sulfur dioxide may be at least partially removed from a gas stream by including, but not limited to, one or more or any combination of the following: contact or absorption in water, or by contact or reaction with an aqueous base, or by contact or reaction with a solid base, or by contact or reaction with calcium carbonate, or by contact or reaction with sodium carbonate, or by contact or reaction with a sulfur dioxide absorption solution, or by contact or reaction with an amine, or by contact or reaction with an acid gas absorption system, or by contact or reaction with a basic alkaline earth compound, or by contact or reaction with a basic alkali compound. For example, in some embodiments, example Recoverable Two Phase Fluids may include, but are not limited to, one or more or any combination of the following: sulfur dioxide, or ammonia, or carbon dioxide, or nitrogen dioxide, or dinitrogen tetroxide, or nitrous oxide, or formic acid, or ethyl acetate, or methanol, or ethanol, or acetone, or alcohols, or ethers, or esters, or aldehydes, or amines.
Note: In some embodiments, for example, ‘Lean’ may refer to a concentration or a relative concentration. In some embodiments, for example, ‘Lean’ may refer to a concentration or a relative concentration less than ‘Rich.’ For example, in some embodiments, a gas stream ‘Lean’ in two phase fluid vapor, or a two phase fluid vapor lean gas stream, or any combination thereof may comprise a gas stream with a lesser concentration or amount of two phase fluid vapor than a gas stream ‘Rich’ in two phase fluid vapor, or a two phase fluid vapor lean gas stream, or any combination thereof. For example, in some embodiments, a gas stream ‘Lean’ in at least partially insoluble fluid vapor, or a at least partially insoluble fluid vapor lean gas stream, or any combination thereof may comprise a gas stream with a lesser concentration or amount of at least partially insoluble fluid vapor than a gas stream ‘Rich’ in at least partially insoluble fluid vapor, or a at least partially insoluble fluid lean gas stream, or any combination thereof. For example, in some embodiments, ‘Lean’ and ‘Rich’ may be used to describe a gas stream or fluid stream before, or during, or after, or any combination thereof a separation or reaction or a change in concentration or an addition. For example, in some embodiments, ‘Lean’ and ‘Rich’ may be used to describe a gas stream or fluid stream before, or during, or after, or any combination thereof a separation or reaction or a change in concentration, or an addition, wherein a gas stream or fluid stream may comprise ‘Lean’ before the addition of a chemical or an increase in concentration, or after the removal of a chemical or separation of a chemical, or any combination thereof. For example, in some embodiments, ‘Lean’ and ‘Rich’ may be used to describe a gas stream or fluid stream before, or during, or after, or any combination thereof a separation or reaction or a change in concentration, or an addition, wherein a gas stream or fluid stream may comprise ‘Rich’ after the addition of a chemical or an increase in concentration, or before the removal of a chemical or separation of a chemical, or any combination thereof.
Note: In some embodiments, for example, ‘Rich’ may refer to a concentration or a relative concentration. In some embodiments, for example, ‘Rich’ may refer to a concentration or a relative concentration greater than ‘Lean.’ For example, in some embodiments, a gas stream ‘Ricj’ in two phase fluid vapor, or a two phase fluid vapor lean gas stream, or any combination thereof may comprise a gas stream with a greater concentration or amount of two phase fluid vapor than a gas stream ‘Rich’ in two phase fluid vapor, or a two phase fluid vapor lean gas stream, or any combination thereof. For example, in some embodiments, a gas stream ‘Rich’ in at least partially insoluble fluid vapor, or a at least partially insoluble fluid vapor lean gas stream, or any combination thereof may comprise a gas stream with a greater concentration or amount of at least partially insoluble fluid vapor than a gas stream ‘Rich’ in at least partially insoluble fluid vapor, or a at least partially insoluble fluid lean gas stream, or any combination thereof. For example, in some embodiments, ‘Lean’ and ‘Rich’ may be used to describe a gas stream or fluid stream before, or during, or after, or any combination thereof a separation or reaction or a change in concentration or an addition. For example, in some embodiments, ‘Lean’ and ‘Rich’ may be used to describe a gas stream or fluid stream before, or during, or after, or any combination thereof a separation or reaction or a change in concentration, or an addition, wherein a gas stream or fluid stream may comprise ‘Rich’ after the addition of a chemical or an increase in concentration, or before the removal of a chemical or separation of a chemical, or any combination thereof. For example, in some embodiments, ‘Lean’ and ‘Rich’ may be used to describe a gas stream or fluid stream before, or during, or after, or any combination thereof a separation or reaction or a change in concentration, or an addition, wherein a gas stream or fluid stream may comprise ‘Rich’ after the addition of a chemical or an increase in concentration, or before the removal of a chemical or separation of a chemical, or any combination thereof.
Note: In some embodiments, the term ‘practically insoluble’ and ‘partially insoluble’ may be employed interchangeably. In some embodiments, the term ‘practically insoluble’ may refer to a solubility sufficiently low in which it may be negligible or insignificant in typical system operations, or may be practically as if the fluids are insoluble under practical system conditions, or any combination thereof. For example, in some embodiments, the two phase fluid may be fully saturated with at least partially insoluble fluid, and/or the at least partially insoluble fluid may be fully saturated with two phase fluid, and/or when in operation, the transfer of two phase fluid into the at least partially insoluble fluid, or the transfer of at least partially insoluble fluid into the two phase fluid, or any combination thereof may be practically negligible or insignificant in typical system operation. In some embodiments, practically insoluble may refer to a solubility less than or equal to, including, but not limited to, one or more or any combination of the following: 0.0001 g/kg, or 0.001 g/kg, or 0.01 g/kg, or 0.05 g/kg, or 0.1 g/kg, or 0.25 g/kg, or 0.5 g/kg, or 0.75 g/kg, or 1 g/kg, or 2 g/kg, or 3 g/kg, or 4 g/kg, or 5 g/kg, or 6 g/kg, or 7 g/kg, or 8 g/kg, or 9 g/kg, or 10 g/kg, or 11 g/kg, or 12 g/kg, or 13 g/kg, or 14 g/kg, or 15 g/kg, or 16 g/kg, or 17 g/kg, or 18 g/kg, or 19 g/kg, or 20 g/kg, or 21 g/kg, or 22 g/kg, or 23 g/kg, or 24 g/kg, or 25 g/kg, or 26 g/kg, or 27 g/kg, or 28 g/kg, or 29 g/kg, or 30 g/kg, or 31 g/kg, or 32 g/kg, or 33 g/kg, or 34 g/kg, or 35 g/kg, or 36 g/kg, or 37 g/kg, or 38 g/kg, or 39 g/kg, or 40 g/kg, or 41 g/kg, or 42 g/kg, or 43 g/kg, or 44 g/kg, or 45 g/kg, or 46 g/kg, or 47 g/kg, or 48 g/kg, or 49 g/kg, or 50 g/kg.
Note: In some embodiments, a heat transfer loop may be occupied by a two-phase fluid at least partially comprising a liquid phase. In some embodiments, a heat transfer loop may be occupied by a two phase fluid comprising a liquid phase and/or at least a portion of the mass of two phase fluid may need to be transferred from or removed from the heat transfer loop to, for example enable operation as a pumped two phase fluid heat transfer loop, or to enable a liquid-gas phase transition heat transfer loop, or to enable or provide sufficient volume for the formation of sufficient two phase fluid gas phase. In some embodiments, a valve may be at least partially opened, or pressure release valve may be at least partially opened, or any combination thereof and/or at least a portion of the two phase fluid in the heat transfer loop may be allowed to boil or phase transition from a liquid to gas phase, which may enable or facilitate the displacement or removal or transfer of at least a portion of the two phase fluid from the heat transfer loop or the displacement or removal or transfer of a sufficient amount or proportion of the two phase fluid from the heat transfer loop. In some embodiments, it may be desirable to at facilitate boiling a portion of two phase fluid and/or displacing or removing a portion of two phase fluid from a heat transfer loop by, for example, including, but not limited to, one or more or any combination thereof: reducing the pressure of a portion of the heat transfer loop, or opening a valve, or applying heat, or transferring heat, or heating two phase fluid, or heating at least a portion of two phase fluid to a temperature such that the vapor pressure of at least a portion of the two phase fluid may be greater than the pressure in at least a portion of the heat transfer loop or the pressure required to transfer at least a portion of two phase fluid through a port or vale in the heat transfer loop, or any combination thereof.
Note: In some embodiments, the concentration of two phase fluid vapor in an inert gas, or in an inert gas comprising at least a portion of two phase fluid vapor, or an inert gas rich in two phase fluid vapor, or an inert gas lean in two phase fluid vapor, or any combination thereof may include, but is not limited to, less than, or equal to, or greater than one or more or any combination of the following: 0.005%, or 0.01%, or 0.05%, or 0.1%, or 0.25%, or 0.5%, or 0.75%, or 1%, or 2%, or 3%, or 4%, or 5%, or 6%, or 7%, or 8%, or 9%, or 10%, or 11%, or 12%, or 13%, or 14%, or 15%, or 16%, or 17%, or 18%, or 19%, or 20%, or 21%, or 22%, or 23%, or 24%, or 25%, or 26%, or 27%, or 28%, or 29%, or 30%, or 31%, or 32%, or 33%, or 34%, or 35%, or 36%, or 37%, or 38%, or 39%, or 40%, or 41%, or 42%, or 43%, or 44%, or 45%, or 46%, or 47%, or 48%, or 49%, or 50%, or 51%, or 52%, or 53%, or 54%, or 55%, or 56%, or 57%, or 58%, or 59%, or 60%, or 61%, or 62%, or 63%, or 64%, or 65%, or 66%, or 67%, or 68%, or 69%, or 70%, or 71%, or 72%, or 73%, or 74%, or 75%, or 76%, or 77%, or 78%, or 79%, or 80%, or 81%, or 82%, or 83%, or 84%, or 85%, or 86%, or 87%, or 88%, or 89%, or 90%, or 91%, or 92%, or 93%, or 94%, or 95%, or 96%, or 97%, or 98%, or 99%, or 99.5%, or 99.9%, or 100%.
Note: In some embodiments, the concentration of at least partially insoluble fluid vapor in an inert gas, or in an inert gas comprising at least a portion of at least partially insoluble fluid vapor, or an inert gas rich in at least partially insoluble fluid vapor, or an inert gas lean in at least partially insoluble fluid vapor, or any combination thereof may include, but is not limited to, less than, or equal to, or greater than one or more or any combination of the following: 0.005%, or 0.01%, or 0.05%, or 0.1%, or 0.25%, or 0.5%, or 0.75%, or 1%, or 2%, or 3%, or 4%, or 5%, or 6%, or 7%, or 8%, or 9%, or 10%, or 11%, or 12%, or 13%, or 14%, or 15%, or 16%, or 17%, or 18%, or 19%, or 20%, or 21%, or 22%, or 23%, or 24%, or 25%, or 26%, or 27%, or 28%, or 29%, or 30%, or 31%, or 32%, or 33%, or 34%, or 35%, or 36%, or 37%, or 38%, or 39%, or 40%, or 41%, or 42%, or 43%, or 44%, or 45%, or 46%, or 47%, or 48%, or 49%, or 50%, or 51%, or 52%, or 53%, or 54%, or 55%, or 56%, or 57%, or 58%, or 59%, or 60%, or 61%, or 62%, or 63%, or 64%, or 65%, or 66%, or 67%, or 68%, or 69%, or 70%, or 71%, or 72%, or 73%, or 74%, or 75%, or 76%, or 77%, or 78%, or 79%, or 80%, or 81%, or 82%, or 83%, or 84%, or 85%, or 86%, or 87%, or 88%, or 89%, or 90%, or 91%, or 92%, or 93%, or 94%, or 95%, or 96%, or 97%, or 98%, or 99%, or 99.5%, or 99.9%, or 100%.
Note: In some embodiments, a fluid vapor pressure may be less than, or equal to, or greater than, including, but not limited to, one or more or any combination of the following: 0.001 bar, or 0.01 bar, or 0.025 bar, 0.05 bar, or 0.075 bar, or 0.10 bar, or 0.15 bar, or 0.20 bar, or 0.25 bar, or 0.30 bar, or 0.35 bar, or 0.40 bar, or 0.45 bar, or 0.50 bar, or 0.55 bar, or 0.60 bar, or 0.65 bar, or 0.70 bar, or 0.75 bar, or 0.80 bar, or 0.85 bar, or 0.90 bar, or 0.95 bar, or 1 bar, or 1.25 bar, or 1.50 bar, or 1.75 bar, or 2.00 bar, or 2.25 bar, or 2.50 bar, or 2.75 bar, or 3.00 bar, or 3.25 bar, or 3.50 bar, or 3.75 bar, or 4.00 bar, or 4.25 bar, or 4.50 bar, or 4.75 bar, or 5 bar, or 6 bar, or 7 bar, or 8 bar, or 9 bar, or 10 bar, or 11 bar, or 12 bar, or 13 bar, or 14 bar, or 15 bar, or 16 bar, or 17 bar, or 18 bar, or 19 bar, or 20 bar, or 21 bar, or 22 bar, or 23 bar, or 24 bar, or 25 bar, or 26 bar, or 27 bar, or 28 bar, or 29 bar, or 30 bar.
Note: In some embodiments, the heat transfer loop may be at least partially occupied by the at least partially insoluble fluid. For example, in some embodiments, the heat transfer loop may be filled at least partially with, or may be occupied with, or may comprise the at least partially insoluble fluid. For example, in some embodiments, the heat transfer loop may be filled at least partially with, or may be occupied with, or may comprise the at least partially insoluble fluid during or after the displacement, or flushing, or removal, or recovery, or any combination thereof of the two-phase fluid.
Note: In some embodiments, air may be present in a heat transfer loop. In some embodiments, a gas comprising air may occupy at least a portion of a heat transfer loop. In some embodiments, an inert gas may be transferred into a heat transfer loop to purge, or dilute, or displace, or any combination thereof at least a portion of the gas comprising air, or comprising oxygen, or any combination thereof which may be present in the heat transfer loop. In some embodiments, it may be desirable to purge a gas comprising air from a heat transfer loop with an inert gas. For example, in some embodiments, it may be desirable to purge a heat transfer loop with nitrogen gas or argon gas. For example, in some embodiments, it may be desirable to purge a heat transfer loop with nitrogen gas or argon gas to lower the concentration of diatomic oxygen in the heat transfer loop.
Note: In some embodiments, it may be desirable for a heat transfer loop to be designed to resist or be compatible with the vapor pressure of the two phase fluid at the heat transfer operating temperature.
Note: In some embodiments, the vapor pressure of some two-phase fluids comprising n-Pentane may comprise, at the following temperatures, for example, the following: less than 1 bar at 5° C., or less than 1 bar at 10° C., or less than 1 bar at 20° C., or less than 1 bar at 25° C., or less than 1 bar at 30° C., or about 1 bar at 36° C., or 2.27 bar at 62° C., or 3.41 bar at 77° C.
Note: In some embodiments, the vapor pressure of some two-phase fluids comprising sulfur dioxide may comprise, at the following temperatures, for example, the following: 2.3 bar at 10° C., or 3.30 bar at 20° C., or 4.62 bar at 30° C., or 6.30 bar at 40° C.
Note: In some embodiments, the vapor pressure of some two-phase fluids comprising ammonia may comprise, at the following temperatures, for example, the following: 5.05 bar at 5° C.; 6.15 bar at 10° C., or 8.88 bar at 20° C., or 10 bar at 25° C., or 15.3 bar at 40° C.
Note: In some embodiments, the vapor pressure of the two phase fluid at a temperature may influence the concentration or partial pressure of two phase fluid in, for example, an inert gas, or an inert gas rich in two phase fluid, or any combination thereof.
Note: In some embodiments, the inert gas may comprise air, or a gas comprising oxygen, or any combination thereof.
Note: In some embodiments, it may be desirable to cool the two phase fluid in a heat transfer loop to a temperature less than or significantly less than the two phase fluid's boiling point at the pressure in the heat transfer loop to facilitate the condensing of any gas phase two phase fluid. In some embodiments, for example, before deinstallation or removal, or as a step in deinstallation or removal, it may be desirable to cool the two phase fluid in a heat transfer loop to a temperature less than or significantly less than the two phase fluid's boiling point at the pressure in the heat transfer loop to facilitate the condensing of any gas phase two phase fluid. It may be desirable for the two phase fluid to be at a liquid phase before deinstallation, or displacement with an at least partially insoluble fluid, or any combination thereof to, for example, prevent or reduce the potential release of gas phase two phase fluid.
Note: In some embodiments, it may be desirable pump or transfer additional two phase fluid in a heat transfer loop at least partially occupied by two phase fluid to increase the pressure in the heat transfer loop and/or to force or facilitate or enable the condensing of at least a portion of any gas phase two phase fluid to a liquid phase. In some embodiments, for example, before deinstallation or removal, or as a step in deinstallation or removal, it may be desirable pump or transfer additional two phase fluid in a heat transfer loop at least partially occupied by two phase fluid to increase the pressure in the heat transfer loop and/or to force or facilitate or enable the condensing of at least a portion of any gas phase two phase fluid to a liquid phase. It may be desirable for the two phase fluid to be at a liquid phase before deinstallation, or displacement with an at least partially insoluble fluid, or any combination thereof to, for example, prevent or reduce the potential release of gas phase two phase fluid.
Note: In some embodiments, it may be desirable to cool the two phase fluid in a heat transfer loop to a temperature less than or significantly less than the two phase fluid's boiling point at the pressure in the heat transfer loop to facilitate the condensing of any gas phase two phase fluid to liquid phase two phase fluid and/or to pump or otherwise transfer two phase fluid into the heat transfer loop to, for example, provide liquid volume to makeup for the volume lost or volume reduction resulting from the condensing of the two phase fluid. In some embodiments, for example, before deinstallation or removal, or as a step in deinstallation or removal, it may be desirable to cool the two phase fluid in a heat transfer loop to a temperature less than or significantly less than the two phase fluid's boiling point at the pressure in the heat transfer loop to facilitate the condensing of any gas phase two phase fluid to liquid phase two phase fluid and/or to pump or otherwise transfer two phase fluid into the heat transfer loop to, for example, provide liquid volume to makeup for the volume lost or volume reduction resulting from the condensing of the two phase fluid.
Note: In some embodiments, oxygen may be present in the gas. In some embodiments, it may be desirable to at least partially deoxygenate or remove dissolved from the at least partially insoluble fluid. For example, in some embodiments, it may be desirable to remove at least a portion of dissolved oxygen from the at least partially insoluble fluid before, or during, or after, or any combination thereof transfer or circulation of the at least partially insoluble fluid in the heat transfer loop. In some embodiments, for example, systems and/or methods for removing dissolved oxygen may be employed. In some embodiments, for example, at least a portion of dissolved oxygen may be removed by purging, or sparging, or contacting with an inert gas. In some embodiments, for example, at least a portion of dissolved oxygen may be removed by a chemical reaction. In some embodiments, for example, at least a portion of dissolved oxygen may be removed by catalytic oxidation. In some embodiments, for example, at least a portion of dissolved oxygen may be removed by a chemical reaction. In some embodiments, for example, at least a portion of dissolved oxygen may be removed by reaction with a reducing agent. In some embodiments, for example, at least a portion of dissolved oxygen may be removed by a chemical reaction. In some embodiments, for example, at least a portion of dissolved oxygen may be removed by reaction with an oxygen scavenger, or an antioxidant, or any combination thereof. In some embodiments, for example, at least a portion of oxygen scavenger or antioxidant, or spent or expended or reacted oxygen scavenger or antioxidant, or any combination thereof may be removed or separated by, for example, reverse osmosis, or nanofiltration, or electrodialysis, or forward osmosis, or a membrane-based process. In some embodiments, for example, an oxygen scavenger may be present in the at least partially insoluble fluid to prevent or reduce potential future presence of dissolved oxygen. In some embodiments, dissolved oxygen removal may be continuous, or batch, or semi-batch, or during operation, or during installation, or during removal, or any combination thereof.
Note: In some embodiments, the inert gas may comprise air, or a gas comprising oxygen, or any combination thereof. For example, in some embodiments, it may be desirable for the inert gas to comprise air, for example, if the two phase fluid is non-flammable, or if a system operator can be confident in the low presence or minimal presence of flammable two phase fluid in the presence of the oxygen, or any combination thereof.
Note: In some embodiments, the inert gas may comprise air, or a gas comprising oxygen, or any combination thereof. For example, in some embodiments, it may be desirable for the inert gas to comprise air and the two phase fluid to be flammable, for example, to enable direct oxidation or catalytic oxidation of residual two phase fluid vapors, for example, wherein the oxidation of residual two phase fluid vapors may prevent or reduce potential volatile organic carbon emissions, or VOC emissions, or ozone, or air pollution, or any combination thereof.
Note: In some embodiments, at least a portion of any aerosol fluids or misted or suspended fluids may be recovered by a demisting device or process or equipment, which may include, but are not limited to, one or more or any combination thereof: demister pad, or knitted wire mesh, or electrostatic system, or vortex system, or centrifugal system, or surface tension system, or wettability system, or filter, or condenser.
Note: In some embodiments, gas-liquid mixtures may be at least partially separated by systems or methods for separating gases and liquids, or systems or methods for separating gas-liquid mixtures, or any combination thereof, which may include, but are not limited to, gas-liquid separation systems or methods known in the art. For example, gas-liquid separators or liquid-gas separators may include, but are not limited to, one or more or any combination of the following: automatic gas remover, or automatic gas vent, or demister, or demister pad, or decanter, or centrifuge, or coalescer, or clarifier, or defoamer, or electrostatic separation, or any combination thereof.
Note: In some embodiments, it may be desirable for the at least partially insoluble fluid to be at a liquid state. For example, in some embodiments, it may be desirable for the at least partially insoluble fluid to be at a liquid state because it, for example, including, but not limited to, one or more or any combination of the following: may enable removal of gas, or prevent mixing with gas, or may reduce the formation of gas-gas mixtures, or may reduce the formation of difficult to separate gas-gas mixtures, or may enable a system to occupied by liquid, or may prevent or reduce the potential the formation of two phase fluid vapor, or may prevent or reduce the potential the formation of two phase fluid vapor during installation or removal, or may prevent evaporation or release or losses of two phase fluid vapor, or may prevent evaporation or release or losses of two phase fluid vapor into the at least partially insoluble fluid, or prevent or reduce potential loss of at least partially insoluble fluid into the inert gas or gas, or prevent or reduce the potential vaporization of at least partially insoluble fluid into the inert gas or gas.
Note: In some embodiments, the heat transfer loop may be safe to modify, or safe for human exposure, or may provide for or enable two phase fluid loss-free maintenance, or any combination thereof when, for example, the system, such as the heat transfer loop, is at least partially filled with or occupied by the inert gas.
Note: In some embodiments, liquid-liquid mixtures may be at least partially separated by systems or methods for separating liquid-liquid mixtures, or systems or methods for separating emulsions or suspensions, or any combination thereof, which may include, but are not limited to, systems or methods known in the art. For example, liquid-liquid or liquid-solid separation systems or methods may include, but are not limited to, one or more or any combination of the following: coalescer, or centrifuge, or clarifier, or decanter, or electrostatic separation, or de-emulsifier, or chemical de-emulsifier, or surface tension modifier, or agitation, or ultrasound.
Note: Systems or methods for measuring or monitoring the concentration of a gas, or concentration of a vapor, or mass flow rate of a vapor, or any combination thereof may include, but are not limited to, one or more or any combination of the following: concentration sensor, or gas analyzer, or O₂ analyzer, or oxygen analyzer, or gas chromatograph, or spectroscopy, or infrared gas analyzer, or VOC gas analyzer, or Tunable/Enhanced Laser Diode Spectroscopy (TLDS/ELDS) Industrial Gas Analyzer, or Point/Non-Dispersive Infrared (PIR/NDIR) Industrial Gas Analyzer, or Electrochemical (EC) Industrial Gas Analyzers, or reactive gas analyzer, or pH gas analyzer, or membrane gas analyzer, or thermal gas analyzer, or density based analyzer, or solubility based analyzer, or gas sensor, or vapor sensor, or fluid sensor, or sensor, or detector.
Note: In some embodiments, the concentration of oxygen in the server rack or computer rack enclosure, or two phase fluid, or rack, or server room, or inert gas exiting a system, or inert gas entering a system, or gas exiting a system, or gas entering a system, or any combination thereof may be measured and/or monitored.
Note: In some embodiments, in the substantial absence of water, ammonia may be compatible with copper.
Note: In some embodiments, for example, the inert gas may comprise an oxygen concentration less than a threshold or minimum concentration of oxygen required for combustion, or for fire, or oxidation, or partial combustion, or any combination thereof.
Note: In some embodiments, after installation of the two phase fluid, the two phase fluid may operate with the boiling or the phase transition from a liquid to a gas in the presence of heat or increasing temperature to at or above the boiling at point at a given pressure, and/or the condensing or the phase transition from a gas to liquid in the presence of a heat sink or cooling to a temperature at or below the boiling point or condensing point at a given pressure. In some embodiments, the boiling of the two phase fluid or the substantial formation of a gas phase of the two phase fluid may result in an increase in volume or an expansion in volume, which may result in the displacement of at least a portion of the two phase fluid from the heat transfer loop. In some embodiments, the system or heat transfer loop may be configured such that two phase fluid displaced by, for example, the increase in volume due to the formation of a gas phase may be, for example, transferred into two phase fluid storage, or a separator, or any combination thereof.
Note: Example two phase fluids may include, but are not limited to, one or more or any combination of the following: natural refrigerants, or refrigerants, or gas-liquid phase transition fluids, or liquid-gas phase transition fluids, or fluids with a boiling point less than 100 degrees Celsius, or fluids with a boiling point less than 90 degrees Celsius, or fluids with a boiling point less than 80 degrees Celsius, or fluids with a boiling point less than 70 degrees Celsius, or fluids with a boiling point less than 60 degrees Celsius, or fluids with a boiling point less than 50 degrees Celsius, or fluids with a boiling point less than 40 degrees Celsius, or a fluid with a boiling point less than the boiling point of the at least partially insoluble fluid, or a fluid at least partially insoluble in an at least partially insoluble fluid, or a fluid with a boiling point which may be adjusted by changing pressure, or a fluid which may change phase or physical state with temperature in the operating temperature range or design temperature range of a heat transfer loop, or a hydrocarbon, or a fluorocarbon, or an oxide, or sulfur dioxide, or carbon dioxide, or ammonia, or an ammonia derivative, or an amine, or an organic solvent, or a volatile organic solvent, or an alkane, or an alkene, or an alkyne.
Note: In some embodiments, for example, it may be desirable for the at least partially insoluble fluid to have significantly different density than the two phase fluid. For example, it may be desirable for the at least partially insoluble fluid to have significantly different density than the two phase fluid to facilitate separation, or density driven separation, or centrifugal separation, or decanting separation, or other separation, or any combination thereof.
   For example, it may be desirable for the at least partially insoluble fluid to have a density greater than the density of the two phase fluid by greater than or equal to one or more or any combination of the following: 0.01 g/mL, or 0.03 g/mL, or 0.05 g/mL, or 0.07 g/mL, or 0.09 g/mL, or 0.11 g/mL, or 0.13 g/mL, or 0.15 g/mL, or 0.17 g/mL, or 0.19 g/mL, or 0.21 g/mL, or 0.23 g/mL, or 0.25 g/mL, or 0.27 g/mL, or 0.29 g/mL, or 0.31 g/mL, or 0.33 g/mL, or 0.35 g/mL, or 0.37 g/mL, or 0.39 g/mL, or 0.41 g/mL, or 0.43 g/mL, or 0.45 g/mL, or 0.47 g/mL, or 0.49 g/mL, or 0.51 g/mL, or 0.53 g/mL, or 0.55 g/mL, or 0.57 g/mL, or 0.59 g/mL, or 0.61 g/mL, or 0.63 g/mL, or 0.65 g/mL, or 0.67 g/mL, or 0.69 g/mL, or 0.71 g/mL, or 0.73 g/mL, or 0.75 g/mL, or 0.77 g/mL, or 0.79 g/mL, or 0.81 g/mL, or 0.83 g/mL, or 0.85 g/mL, or 0.87 g/mL, or 0.89 g/mL, or 0.91 g/mL, or 0.93 g/mL, or 0.95 g/mL, or 0.97 g/mL, or 0.99 g/mL, or 1.01 g/mL, or 1.03 g/mL, or 1.05 g/mL, or 1.07 g/mL, or 1.09 g/mL, or 1.11 g/mL, or 1.13 g/mL, or 1.15 g/mL, or 1.17 g/mL, or 1.19 g/mL, or 1.21 g/mL, or 1.23 g/mL, or 1.25 g/mL, or 1.27 g/mL, or 1.29 g/mL, or 1.31 g/mL, or 1.33 g/mL, or 1.35 g/mL, or 1.37 g/mL, or 1.39 g/mL, or 1.41 g/mL, or 1.43 g/mL, or 1.45 g/mL, or 1.47 g/mL, or 1.49 g/mL.
   For example, it may be desirable for the at least partially insoluble fluid to have a density less than the density of the two phase fluid by less than or equal to one or more or any combination of the following: 0.01 g/mL, or 0.03 g/mL, or 0.05 g/mL, or 0.07 g/mL, or 0.09 g/mL, or 0.11 g/mL, or 0.13 g/mL, or 0.15 g/mL, or 0.17 g/mL, or 0.19 g/mL, or 0.21 g/mL, or 0.23 g/mL, or 0.25 g/mL, or 0.27 g/mL, or 0.29 g/mL, or 0.31 g/mL, or 0.33 g/mL, or 0.35 g/mL, or 0.37 g/mL, or 0.39 g/mL, or 0.41 g/mL, or 0.43 g/mL, or 0.45 g/mL, or 0.47 g/mL, or 0.49 g/mL, or 0.51 g/mL, or 0.53 g/mL, or 0.55 g/mL, or 0.57 g/mL, or 0.59 g/mL, or 0.61 g/mL, or 0.63 g/mL, or 0.65 g/mL, or 0.67 g/mL, or 0.69 g/mL, or 0.71 g/mL, or 0.73 g/mL, or 0.75 g/mL, or 0.77 g/mL, or 0.79 g/mL, or 0.81 g/mL, or 0.83 g/mL, or 0.85 g/mL, or 0.87 g/mL, or 0.89 g/mL, or 0.91 g/mL, or 0.93 g/mL, or 0.95 g/mL, or 0.97 g/mL, or 0.99 g/mL, or 1.01 g/mL, or 1.03 g/mL, or 1.05 g/mL, or 1.07 g/mL, or 1.09 g/mL, or 1.11 g/mL, or 1.13 g/mL, or 1.15 g/mL, or 1.17 g/mL, or 1.19 g/mL, or 1.21 g/mL, or 1.23 g/mL, or 1.25 g/mL, or 1.27 g/mL, or 1.29 g/mL, or 1.31 g/mL, or 1.33 g/mL, or 1.35 g/mL, or 1.37 g/mL, or 1.39 g/mL, or 1.41 g/mL, or 1.43 g/mL, or 1.45 g/mL, or 1.47 g/mL, or 1.49 g/mL.
Note: It may be desirable for materials of the systems and/or methods to be compatible with fluids, which may include, for example, two phase fluid, or at least partially insoluble fluid, or inert gas, or air, or other fluids, or any combination thereof. Materials may include, but are not limited to, one or more or any combination of the following: polyethylene, or polypropylene, or PTFE, or PVDF, or PVC, or CPVC, or HDPE, or MDPE, or LDPE, or ETFE, or PEX, or polyurethane, or polycarbonate, or acetal, or PET, or ABS, or thermoplastic, or stainless steel, or steel, or aluminum, or copper, or brass, or bronze, or wood, or paper, or Inconel, or Hastelloy, or alloy, or composite, or ceramic, or iron, or nickel, or monel, or EPDM, or Viton, or silicone, or ULDPE, or PP homopolymer, or PP copolymer, or Provista, or ABS, or PC, or Polysulfone, or PPS, or Acrylic, or Butyrate, or Butanoate, or Propionate, or titanium, or neoprene, or chloroprene, or fluorosilicone, or nitrile, or butyl rubber, or buna, or PLA, or Kalrez, or Chemraz, or FFKM, or fiberglass, or carbon fiber, or carbon ceramic, or silicon ceramic, or silicon carbide, or carbon, or graphite, or magnesium, or fibrous material, or tungsten, or molybdenum.

What is claimed:

1. A process for installing a two phase fluid into a heat transfer loop comprising:
adding an at least partially insoluble fluid into the heat transfer loop to displace at least a portion of a gas from the heat transfer loop;
adding a two phase fluid into the heat transfer loop to displace at least a portion of the partially insoluble fluid from the heat transfer loop; and
separating at least a portion of the displaced at least partially insoluble fluid from the two phase fluid;
wherein the at least partially insoluble fluid is at least partially insoluble in the two phase fluid.

2. The process of claim 1 wherein the two phase fluid comprises a hydrocarbon, a fluorocarbon, propane, butane, pentane, hexane, dimethyl ether, methyl formate, ethylene, propylene, butylene, a natural refrigerant, or any mixture thereof.

3. The process of claim 1 wherein the at least partially insoluble fluid comprises water.

4. The process of claim 1 wherein the at least partially insoluble fluid comprises a liquid.

5. The process of claim 1 wherein the gas comprises an inert gas.

6. The process of claim 1 wherein the gas comprises air.

7. The process of claim 1 wherein at least a portion of the two phase fluid comprises a liquid.

8. The process of claim 1 wherein the heat transfer loop comprises a direct to chip cooling system.

9. The process of claim 1 which further comprises treating at least a portion of the at least partially insoluble fluid to prevent or reduce biofouling, corrosion, scalant formation, scaling, degradation, residue formation, dissolved oxygen formation, dissolved gas formation ion formation, or any combination thereof.

10. The process of claim 1 wherein the two phase fluid comprises sulfur dioxide, ammonia, an amine, nitrogen dioxide, dinitrogen tetroxide, nitrous oxide, or any mixture thereof.

11. The process of claim 1 wherein at least a portion of the two phase fluid comprises a liquid phase when displacing at least a portion of the at least partially insoluble fluid.

12. The process of claim 1 wherein said separating comprises employing a density-based liquid-liquid separation, a surface tension based liquid-liquid separation, or any combination thereof.

13. A process for installing a two phase fluid into a heat transfer loop comprising:
adding at least a portion of a fluid comprising an at least a partially insoluble fluid into the heat transfer loop to displace a least a portion of a fluid comprising a two phase fluid from the heat transfer loop wherein at least a portion of the two phase fluid comprises a liquid phase or liquid state; and
separating at least a portion of the displaced two phase fluid from the at least partially insoluble fluid;
wherein the at least partially insoluble fluid is at least partially insoluble in the two phase fluid.

14. The process of claim 13 wherein the two phase fluid comprises a hydrocarbon, a fluorocarbon, propane, butane, pentane, hexane, dimethyl ether, methyl formate, propylene, butylene, a natural refrigerant, or any mixture thereof.

15. The process of claim 13 wherein the at least partially insoluble fluid comprises water.

16. The process of claim 13 further comprising adding at least a portion of an inert gas into the heat transfer loop to displace at least a portion of the at least partially insoluble fluid from the heat transfer loop.

17. The process of claim 16 wherein the inert gas comprises nitrogen, argon, carbon dioxide, helium, neon, a noble gas, or any mixture thereof.

18. The process of claim 16 wherein the inert gas comprises a gas with a concentration of diatomic oxygen of less than about 5% by volume.

19. The process of claim 16 which further comprises purging at least a portion of the at least partially insoluble fluid from the heat transfer loop with an inert gas.

20. The process of claim 19 which further comprises pausing said purging when a concentration of at least partially insoluble fluid vapor within, or exiting the heat transfer loop is less than about 1,000 PPM.

21. The process of claim 16 wherein the concentration of the two phase fluid vapor in the inert gas within, or exiting the heat transfer loop in the fluid comprising the inert gas is less than about 100 PPM.
